(19) United States
(12) Patent Application Publication
(10) Pub. No.: US 2024/0243155 A1
(43) Pub. Date: Jul. 18, 2024

(54) IMAGING ELEMENT AND METHOD OF MANUFACTURING IMAGING ELEMENT

(71) Applicant: SONY SEMICONDUCTOR SOLUTIONS CORPORATION, KANAGAWA (JP)

(72) Inventors: IKUE MITSUHASHI, KANAGAWA (JP); MASAKI HANEDA, KANAGAWA (JP)

(21) Appl. No.: 18/559,444

(22) PCT Filed: Feb. 22, 2022
(86) PCT No.: PCT/JP2022/007407

§ 371 Date: Nov. 7, 2023

(30) Foreign Application Priority Data
May 26, 2021 (JP) 2021-088786

(51) Int. Cl. H01L 27/146

(52) U.S. Cl. CPC H01L 27/14636; H01L 27/14634; H01L 27/14683

(57) ABSTRACT

An imaging element according to an embodiment of the present disclosure includes: a wiring layer including a plurality of wiring lines extending in one direction; a first barrier film stacked on the wiring layer and having a first edge surface above any wiring line of the plurality of wiring lines; a first insulating film stacked on the wiring layer and the first barrier film; a first air gap provided between the wiring layer and the first insulating film, and provided between the plurality of wiring lines adjacent to each other; and a second air gap provided above the wiring line above which the first edge surface is provided, the second air gap being provided near the first edge surface.

### TECHNICAL FIELD

The present disclosure relates to an imaging element having an air gap between wiring lines, for example, and a method of manufacturing the imaging element.

### BACKGROUND ART

As a semiconductor integrated circuit element becomes more miniaturized in a semiconductor device, an interval has become narrower between wiring lines each coupling elements and between wiring lines inside an element. Under such circumstances, for example, PTL 1 discloses a semiconductor device in which capacitance between wiring lines is reduced by forming an air gap (air gap) between the wiring lines.

### CITATION LIST

### Patent Literature

PTL 1: Japanese Unexamined Patent Application Publication No. 2008-193104

### SUMMARY OF THE INVENTION

Incidentally, in recent years, a stacked image sensor has become more common, and a reduction in wiring capacitance has been requested.

It is desirable to provide an imaging element that makes it possible to reduce wiring capacitance and a method of manufacturing the imaging device.

An imaging element according to an embodiment of the present disclosure includes: a wiring layer including a plurality of wiring lines extending in one direction; a first barrier film stacked on the wiring layer and having a first edge surface above any wiring line of the plurality of wiring lines; a first insulating film stacked on the wiring layer and the first barrier film; a first air gap provided between the wiring layer and the first insulating film, and provided between the plurality of wiring lines adjacent to each other; and a second air gap provided above the wiring line above which the first edge surface is provided, the second air gap being provided near the first edge surface.

A method of manufacturing an imaging element according to an embodiment of the present disclosure includes: forming a wiring layer including a plurality of wiring lines extending in one direction; forming a first barrier film on the wiring layer; forming a first opening in the first barrier film and between the plurality of wiring lines adjacent to each other in a predetermined region of the wiring layer; and forming a first air gap between the plurality of wiring lines adjacent to each other and a second air gap near a first edge surface formed by the first opening of the first barrier film, by forming a first insulating film.

In the imaging element according to an embodiment of the present disclosure and the method of manufacturing the imaging element according to an embodiment of the present disclosure, a first barrier film having a first edge surface above any wiring line of a plurality of wiring lines is formed on a wiring layer including the plurality of wiring lines extending in one direction. Further, a first insulating film covering the wiring layer and the first barrier film is formed. A first air gap is provided between the wiring lines adjacent to each other, and a second air gap is provided above the wiring line above which the first edge surface of the first barrier film is provided and near the first edge surface. This allows for a reduction in capacitance between the wiring lines extending in one direction.

### BRIEF DESCRIPTION OF THE DRAWINGS

FIG. 1 is a schematic view of an example of a cross-sectional configuration of a wiring structure according to an embodiment of the present disclosure in a vertical direction.

FIG. 2 is a schematic view of an example of a cross-sectional configuration of the wiring structure illustrated in FIG. 1 in a horizontal direction.

FIG. 3 is a schematic view of an example of a cross-sectional configuration of the wiring structure illustrated in FIG. 1 in the vertical direction, along a line II-II illustrated in FIG. 2.

FIG. 4A is a schematic cross-sectional view of an example of a manufacturing process of the wiring structure illustrated in FIG. 1.

FIG. 4B is a schematic cross-sectional view of an example of a manufacturing process subsequent to FIG. 4A.

FIG. 4C is a schematic cross-sectional view of an example of a manufacturing process subsequent to FIG. 4B.

FIG. 4D is a schematic cross-sectional view of an example of a manufacturing process subsequent to FIG. 4C.

FIG. 4E is a schematic cross-sectional view of an example of a manufacturing process subsequent to FIG. 4D.

FIG. 4F is a schematic cross-sectional view of an example of a manufacturing process subsequent to FIG. 4E.

FIG. 4G is a schematic cross-sectional view of an example of a manufacturing process subsequent to FIG. 4F.

FIG. 5 is a diagram illustrating an example of a cross-sectional configuration of an imaging element according to an embodiment of the present disclosure in the vertical direction.

FIG. 6 is a diagram illustrating an example of a schematic configuration of the imaging element illustrated in FIG. 5.

FIG. 7 is a diagram of the imaging element illustrated in FIG. 5 to which the wiring structure illustrated in FIG. 1 is applied.

FIG. 8 is a diagram illustrating an example of a sensor pixel and a readout circuit illustrated in FIG. 6.

FIG. 9 is a diagram illustrating an example of the sensor pixel and the readout circuit illustrated in FIG. 6.

FIG. 10 is a diagram illustrating an example of the sensor pixel and the readout circuit illustrated in FIG. 6.

FIG. 11 is a diagram illustrating an example of the sensor pixel and the readout circuit illustrated in FIG. 6.

FIG. 12 is a diagram illustrating an example of a coupling mode between a plurality of readout circuits and a plurality of vertical signal lines.

FIG. 13 is a diagram illustrating an example of a cross-sectional configuration of the imaging element illustrated in FIG. 5 in the horizontal direction.

FIG. 14 is a diagram illustrating an example of a cross-sectional configuration of the imaging element illustrated in FIG. 5 in the horizontal direction.

FIG. 15 is a diagram illustrating an example of a wiring layout of the imaging element illustrated in FIG. 5 within a horizontal plane.

FIG. 16 is a diagram illustrating an example of the wiring layout of the imaging element illustrated in FIG. 5 within the horizontal plane.

FIG. 17 is a diagram illustrating an example of the wiring layout of the imaging element illustrated in FIG. 5 within the horizontal plane.

FIG. 18 is a diagram illustrating an example of the wiring layout of the imaging element illustrated in FIG. 5 within the horizontal plane.

FIG. 19A is a diagram illustrating an example of a manufacturing process of the imaging element illustrated in FIG. 5.

FIG. 19B is a diagram illustrating an example of a manufacturing process subsequent to FIG. 19A.

FIG. 19C is a diagram illustrating an example of a manufacturing process subsequent to FIG. 19B.

FIG. 19D is a diagram illustrating an example of a manufacturing process subsequent to FIG. 19C.

FIG. 19E is a diagram illustrating an example of a manufacturing process subsequent to FIG. 19D.

FIG. 19F is a diagram illustrating an example of a manufacturing process subsequent to FIG. 19E.

FIG. 19G is a diagram illustrating an example of a manufacturing process subsequent to FIG. 19F.

FIG. 20 is a schematic view of an example of a cross-sectional configuration of a wiring structure according to Modification Example 1 of the present disclosure in the vertical direction.

FIG. 21 is a schematic view of an example of a cross-sectional configuration of a wiring structure according to Modification Example 2 of the present disclosure in the vertical direction.

FIG. 22A is a schematic cross-sectional view of an example of a manufacturing process of the wiring structure according to Modification Example 2 of the present disclosure.

FIG. 22B is a schematic cross-sectional view of an example of a manufacturing process subsequent to FIG. 22A.

FIG. 22C is a schematic cross-sectional view of an example of a manufacturing process subsequent to FIG. 22B.

FIG. 22D is a schematic cross-sectional view of an example of a manufacturing process subsequent to FIG. 22C.

FIG. 22E is a schematic cross-sectional view of an example of a manufacturing process subsequent to FIG. 22D.

FIG. 23A is a schematic view of an example of a cross-sectional configuration of a wiring structure according to Modification Example 3 of the present disclosure in the vertical direction.

FIG. 23B is a schematic view of another example of the cross-sectional configuration of the wiring structure according to Modification Example 3 of the present disclosure in the vertical direction.

FIG. 24 is an explanatory schematic view of a shape of an air gap.

FIG. 25 is a schematic view of another example of the cross-sectional configuration of the wiring structure according to Modification Example 3 of the present disclosure in the vertical direction.

FIG. 26 is a schematic view of another example of the cross-sectional configuration of the wiring structure according to Modification Example 3 of the present disclosure in the vertical direction.

FIG. 27 is a schematic view of an example of a cross-sectional configuration of a wiring structure according to Modification Example 4 of the present disclosure in the vertical direction.

FIG. 28A is a schematic cross-sectional view of an example of a manufacturing process of the wiring structure illustrated in FIG. 27.

FIG. 28B is a schematic cross-sectional view of an example of a manufacturing process subsequent to FIG. 28A.

FIG. 28C is a schematic cross-sectional view of an example of a manufacturing process subsequent to FIG. 28B.

FIG. 28D is a schematic cross-sectional view of an example of a manufacturing process subsequent to FIG. 28C.

FIG. 28E is a schematic cross-sectional view of an example of a manufacturing process subsequent to FIG. 28D.

FIG. 29 is a schematic view of another example of the cross-sectional configuration of the wiring structure according to Modification Example 4 of the present disclosure in the vertical direction.

FIG. 30 is a schematic view of another example of the cross-sectional configuration of the wiring structure according to Modification Example 4 of the present disclosure in the vertical direction.

FIG. 31 is a schematic view of another example of the cross-sectional configuration of the wiring structure according to Modification Example 4 of the present disclosure in the vertical direction.

FIG. 32 is a schematic view of an example of the cross-sectional configuration of the wiring structure according to Modification Example 4 of the present disclosure in the vertical direction.

FIG. 33 is a schematic view of another example of the cross-sectional configuration of the wiring structure according to Modification Example 4 of the present disclosure in the vertical direction.

FIG. 34 is a schematic view of another example of a cross-sectional configuration of a wiring structure according to Modification Example 5 of the present disclosure in the vertical direction.

FIG. 35A is a schematic cross-sectional view of an example of a manufacturing process of the wiring structure illustrated in FIG. 34.

FIG. 35B is a schematic cross-sectional view of an example of a manufacturing process subsequent to FIG. 35A.

FIG. 35C is a schematic cross-sectional view of an example of a manufacturing process subsequent to FIG. 35B.

FIG. 35D is a schematic cross-sectional view of an example of a manufacturing process subsequent to FIG. 35C.

FIG. 35E is a schematic cross-sectional view of an example of a manufacturing process subsequent to FIG. 35D.

FIG. 35F is a schematic cross-sectional view of an example of a manufacturing process subsequent to FIG. 35E.

FIG. 35G is a schematic cross-sectional view of an example of a manufacturing process subsequent to FIG. 35F.

FIG. 35H is a schematic cross-sectional view of an example of a manufacturing process subsequent to FIG. 35G.

FIG. 35I is a schematic cross-sectional view of an example of a manufacturing process subsequent to FIG. 35E.

FIG. 36 is a diagram illustrating an example of a cross-sectional configuration of an imaging element according to Modification Example 6 of the present disclosure in the vertical direction.

FIG. 37 is a diagram illustrating an example of a cross-sectional configuration of an imaging element according to Modification Example 7 of the present disclosure in the vertical direction.

FIG. 38 is a diagram illustrating an example of a cross-sectional configuration of an imaging element according to Modification Example 8 of the present disclosure in the horizontal direction.

FIG. 39 is a diagram illustrating another example of the cross-sectional configuration of the imaging element according to Modification Example 8 of the present disclosure in the horizontal direction.

FIG. 40 is a diagram illustrating an example of a cross-sectional configuration of an imaging element according to Modification Example 9 of the present disclosure in the horizontal direction.

FIG. 41 is a diagram illustrating an example of a cross-sectional configuration of an imaging element according to Modification Example 10 of the present disclosure in the horizontal direction.

FIG. 42 is a diagram illustrating an example of a cross-sectional configuration of an imaging element according to Modification Example 11 of the present disclosure in the horizontal direction.

FIG. 43 is a diagram illustrating another example of the cross-sectional configuration of the imaging element according to Modification Example 11 of the present disclosure in the horizontal direction.

FIG. 44 is a diagram illustrating another example of the cross-sectional configuration of the imaging element according to Modification Example 11 of the present disclosure in the horizontal direction.

FIG. 45 is a diagram illustrating an example of a circuit configuration of an imaging element according to Modification Example 12 of the present disclosure.

FIG. 46 is a diagram illustrating an example of a configuration of the imaging element in FIG. 45 according to Modification Example 13 of the present disclosure, in which three substrates are stacked.

FIG. 47 is a diagram illustrating an example of formation of a logic circuit according to Modification Example 14 of the present disclosure, in which a substrate provided with a sensor pixel and a substrate provided with a readout circuit are separated.

FIG. 48 is a diagram illustrating an example of formation of a logic circuit according to Modification Example 15 of the present disclosure in a third substrate.

FIG. 49 is a diagram illustrating an example of a schematic configuration of an imaging system including the imaging element according to any of the above-described embodiment and modification examples thereof.

FIG. 50 is a diagram illustrating an example of an imaging procedure in the imaging system in FIG. 49.

FIG. 51 is a diagram illustrating an overview of configuration examples of a non-stacked solid-state imaging element and a stacked solid-state imaging element to which the technology according to the present disclosure is applicable.

FIG. 52 is a cross-sectional view of a first configuration example of the stacked solid-state imaging element.

FIG. 53 is a cross-sectional view of a second configuration example of the stacked solid-state imaging element.

FIG. 54 is a cross-sectional view of a third configuration example of the stacked solid-state imaging element.

FIG. 55 is a cross-sectional view of another configuration example of the stacked solid-state imaging element to which the technology according to the present disclosure is applicable.

FIG. 56 is a block diagram depicting an example of schematic configuration of a vehicle control system.

FIG. 57 is a diagram of assistance in explaining an example of installation positions of an outside-vehicle information detecting section and an imaging section.

FIG. 58 is a view depicting an example of a schematic configuration of an endoscopic surgery system.

FIG. 59 is a block diagram depicting an example of a functional configuration of a camera head and a camera control unit (CCU).

### MODES FOR CARRYING OUT THE INVENTION

Hereinafter, a description is given in detail of an embodiment of the present disclosure with reference to the drawings. The following description is merely a specific example of the present disclosure, and the present disclosure should not be limited to the following aspects. Moreover, the present disclosure is not limited to arrangements, dimensions, dimensional ratios, and the like of each component illustrated in the drawings. It is to be noted that the description is given in the following order.
1. First Embodiment (An example of a wiring structure having air gaps at respective locations between wiring lines adjacent to each other and extending in one direction and near edge surfaces of a barrier film provided on the wiring lines)
1-1. Configuration of Wiring Structure
1-2. Method of Manufacturing Wiring Structure
1-3. Configuration of Imaging Element
1-4. Method of Manufacturing Imaging Element
1-5. Workings and Effects
2. Modification Examples
2-1. Modification Example 1 (Another example of a wiring structure)
2-2. Modification Example 2 (Another example of a wiring structure)
2-3. Modification Example 3 (Another example of a wiring structure)
2-4. Modification Example 4 (Another example of a wiring structure)
2-5. Modification Example 5 (Another example of a wiring structure)
2-6. Modification Example 6 (An example of using a planar TG)
2-7. Modification Example 7 (An example of using Cu—Cu bonding at a panel outer edge)
2-8. Modification Example 8 (An example in which an offset is provided between a sensor pixel and a readout circuit)
2-9. Modification Example 9 (An example in which a silicon substrate provided with a readout circuit has an island shape)
2-10. Modification Example 10 (An example in which a silicon substrate provided with a readout circuit has an island shape)
2-11. Modification Example 11 (An example in which an FD is shared by eight sensor pixels)
2-12. Modification Example 12 (An example in which a column signal processing circuit is configured by a typical column ADC circuit)
2-13. Modification Example 13 (An example in which an imaging device is configured by stacking seven substrates)
2-14. Modification Example 14 (An example in which with a logic circuit is provided in a first substrate and a second substrate)
2-15. Modification Example 15 (An example in which a logic circuit is provided in a seventh substrate)
3. Application example
4. Practical Application Examples

### 1. First Embodiment

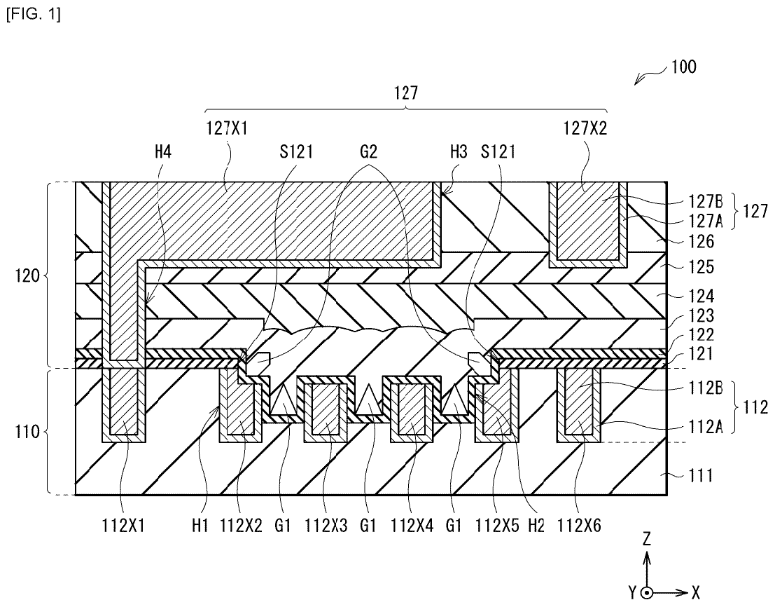

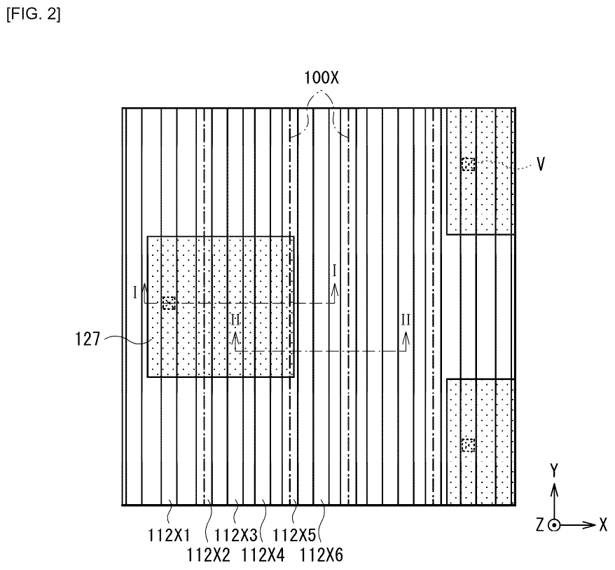

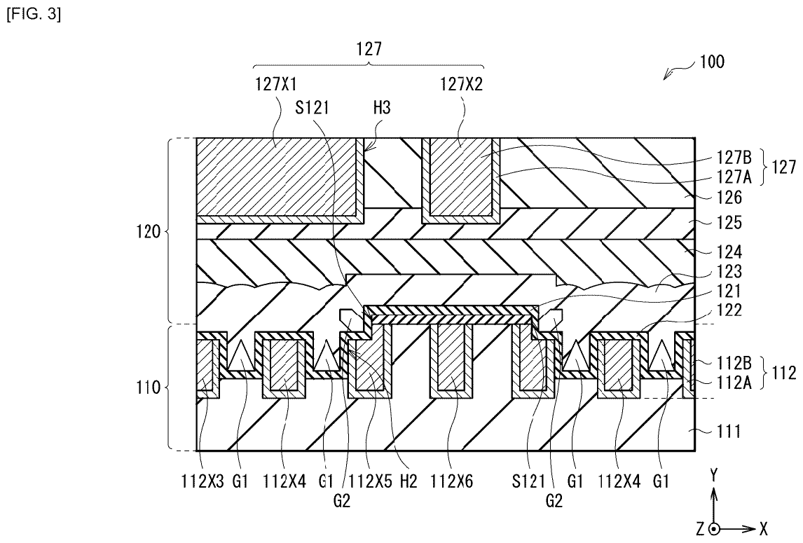

FIG. 1 schematically illustrates an example of a cross-sectional configuration of a wiring structure (a wiring structure 100) according to an embodiment of the present disclosure in a vertical direction. FIG. 2 schematically illustrates an example of a cross-sectional configuration of the wiring structure 100 illustrated in FIG. 1 in a horizontal direction. FIG. 1 corresponds to a cross-section along a line I-I illustrated in FIG. 2. FIG. 3 schematically illustrates an example of a cross-sectional configuration of the wiring structure 100 illustrated in FIG. 1, along a line II-II illustrated in FIG. 2, for example. The wiring structure 100 has, for example, a multilayer wiring structure in which a plurality of wiring layers are stacked, and is applicable to an imaging element 1 described later, for example.

The wiring structure 100 includes a wiring layer 112 including a plurality of wiring lines (e.g., a wiring line 112X1 to a wiring line 112X6) extending in one direction (e.g., a Y-axis direction), and a barrier film 121 and an insulating film 123 which are stacked in order on the wiring layer 112. The barrier film 121 extends, for example, on the wiring layer 112, and includes an edge surface S121 on each of the wiring line 112X2 and the wiring line 112X5, for example. The insulating film 123 is stacked above the barrier film 121, and is provided to fill an opening H2 provided between adjacent wiring lines (e.g., between the wiring line 112X2 and the wiring line 112X3 adjacent to each other, between the wiring line 112X3 and the wiring line 112X4 adjacent to each other, and between the wiring line 112X4 and the wiring line 112X5 adjacent to each other). In the present embodiment, an air gap G1 is provided at each of locations between the wiring line 112X2 and the wiring line 112X3 adjacent to each other, between the wiring line 112X3 and the wiring line 112X4 adjacent to each other, and between the wiring line 112X4 and between the wiring line 112X5 adjacent to each other, inside the above-described opening H2. Further, an air gap G2 is provided at locations above the wiring line 112X2 and the wiring line 112X5, at which the edge surfaces S121 of the barrier film 121 are formed, and near the edge surfaces S121. The plurality of wiring line 112X1 to wiring line 112X6 and the wiring layer 112 correspond, respectively, to specific examples of a “first wiring line” and a “first wiring layer” of the present disclosure. The barrier film 121 corresponds to a specific example of a “first barrier film” of the present disclosure, and the insulating film 123 corresponds to a specific example of a “first insulating film” of the present disclosure. The air gap G1 corresponds to a specific example of a “first air gap” of the present disclosure, and the air gap G2 corresponds to a specific example of a “second air gap” of the present disclosure.

### 1-1. Configuration of Wiring Structure

The wiring structure 100 has a configuration in which a first layer 110 and a second layer 120 are stacked in this order on a silicon substrate (unillustrated) or the like, for example.

In the first layer 110, a plurality of wiring lines (e.g., wiring line 112X1 to wiring line 112X6) are embedded and formed in an insulating film 111.

The insulating film 111 is formed by using, for example, a low-permittivity material (Low-k material) having a relative permittivity (k) of 3.0 or less. Specifically, examples of a material of the insulating film 111 include organic macromolecules such as carbon-containing silicon oxide (SiOC), SiOCH, porous silica, fluorine-doped silicon oxide (SiOF), inorganic SOG, organic SOG, and polyallyl ether.

The wiring layer 112 includes, for example, a plurality of wiring lines extending in one direction, and includes, for example, the wiring line 112X1 to the wiring line 112X6 extending in the Y-axis direction. The wiring line 112X1 to the wiring line 112X6 are formed in parallel, for example, at Line (L)/Space (S)=40 nm to 200 nm/40 nm to 200 nm. The wiring line 112X1 to the wiring line 112X6 are embedded and formed in an opening H1 provided in the insulating film 111, for example. The wiring line 112X1 to the wiring line 112X6 are configured by, for example, a barrier metal 112A formed on a side surface and a bottom surface of the opening H1, and a metal film 112B that fills the opening H1. Examples of a material of the barrier metal 112A include a simple substance of Ti (titanium) or Ta (tantalum), or a nitride, alloy, or the like thereof. Examples of a material of the metal film 112B include a metal material mainly including a low-resistance metal such as Cu (copper), W (tungsten), or aluminum (Al).

The first layer 110 is further provided with the opening H2 in the insulating film 111 between adjacent wiring lines, specifically, for example, between the wiring line 112X2 and the wiring line 112X3, between the wiring line 112X3 and the wiring line 112X4, and between a wiring line 112V4 and the wiring line 112X5.

In the second layer 120, the barrier film 121 and a plurality of insulating films (insulating films 122 to 126) are stacked, and an electrically-conductive film 127 is embedded and formed in the insulating film 126 of the top layer, for example. Specifically, the barrier film 121, the insulating film 122, the insulating film 123, the insulating film 124, the insulating film 125, and the insulating film 126 are stacked in order from a side of the first layer 110. The above-described opening H2 provided each of locations between the wiring line 112X2 and the wiring line 112X3, between the wiring line 112X3 and the wiring line 112X4, and between the wiring line 112V4 and the wiring line 112X5 is closed by the insulating film 123 constituting the second layer 120. This allows for formation of the air gap G1, which lowers capacitance between wiring lines running parallel to each other, at each of locations between the wiring line 112X2 and the wiring line 112X3. between the wiring line 112X3 and the wiring line 112X4, and between the wiring line 112V4 and the wiring line 112X5. The air gap G1 is formed at a partial region or the entirety of locations between the wiring line 112X2 and the wiring line 112X3, between the wiring line 112X3 and the wiring line 112X4, and between the wiring line 112V4 and the wiring line 112X5, for example, as illustrated in FIG. 2. This is not limitative; the air gap G1 can also be formed between other wiring lines extending in the Y-axis direction together with the wiring line 112X1 to the wiring line 112X6 (an air gap formation region 100X), in addition to the locations between the wiring line 112X2 and the wiring line 112X3, between the wiring line 112X3 and the wiring line 112X4, and between the wiring line 112V4 and the wiring line 112X5, as illustrated in FIG. 2.

The barrier film 121 is to prevent diffusion of copper (Cu) and infiltration of moisture, for example, in a case where the wiring line 112X1 to the wiring line 112X6 are formed using copper (Cu). The barrier film 121 extends on the wiring layer 112 except a portion of the wiring layer 112. Specifically, the barrier film 121 is provided to cover, except the opening H2, the insulating film 111, the wiring line 112X1 and the wiring line 112X6 that are embedded and formed, and a portion of each of the wiring line 112X2 and the wiring line 112X5 between which the opening H2 is provided. In other words, the barrier film 121 is formed outside the opening H2, and has the edge surface S121 above each of the wiring line 112X2 and the wiring line 112X5. Thus, a step difference including each top surface of the wiring line 112X2 and the wiring line 112X5, and the edge surface S121 and a top surface of the barrier film 121 is formed above each of the wiring line 112X2 and the wiring line 112X5. Upon covering the step difference with the insulating film 123, the air gap G2, which lowers the capacitance near the wiring line running parallel thereto, is formed in a self-aligned manner near the step difference, particularly, above the wiring line 112X2 and the wiring line 112X5 and near the edge surfaces S121. The barrier film 121 is formed using, for example, silicon oxide (SiOₓ), silicon nitride (SiNₓ), SiC_{X}N_{y}, silicon carbide (SiC), silicon oxynitride (SiON, SiNO), aluminum oxynitride (AlNO), aluminum nitride (AlN), or the like.

In the same manner as the barrier film 121, the insulating film 122 is to prevent diffusion of copper (Cu) and infiltration of moisture, for example, in a case where the wiring line 112X1 to the wiring line 112X6 are formed using copper (Cu). The insulating film 122 corresponds to a specific example of a “second insulating film” of the present disclosure, and is provided on the barrier film 121 and formed in an extending manner to cover a side surface and a bottom surface of the opening H2. As described above, the insulating film 122 is formed from an insulating material that prevents the diffusion of copper (Cu) and the infiltration of moisture, by using a manufacturing method with low step coverage, for example. Specifically, the insulating film 122 is formed from, for example, silicon oxide (SiOₓ), silicon nitride (SiNₓ), silicon oxynitride (SiON, SiNO), SiC_{X}N_{y}, or the like by using a CVD method, a coating method by means of, for example, a spin coater, for example.

The insulating film 123 is provided on the insulating film 122, and is to form the air gaps G1 and G2 at respective locations between the wiring lines (specifically, between the wiring line 112X2 and the wiring line 112X3, between the wiring line 112X3 and the wiring line 112X4, and between the wiring line 112V4 and the wiring line 112X5) inside the opening H2, and above the wiring line 112X2 and the wiring line 112X5 and near the edge surfaces S121 of the barrier film 121. The insulating film 123 is formed using a Low-k material of low coverage having a relative permittivity (k) of 3.0 or less, for example. Specifically, examples of a material of the insulating film 123 include organic macromolecules such as carbon-containing silicon oxide (SiOC), SiOCH, porous silica, fluorine-doped silicon oxide (SiOF), inorganic SOG, organic SOG, and polyallyl ether.

The insulating film 124 corresponds to a specific example of a “third insulating film” of the present disclosure. The insulating film 124 is provided on the insulating film 123, and is to fill irregularities of the insulating film 123 above the air gaps G1 and G2G and to form, above the air gaps G1 and G2G, a planar surface on which devices can be stacked using hybrid bonding such as Cu—Cu bonding, which is described later in detail. It is preferable to use, as a material of the insulating film 124, a material having, for example, a polishing rate higher than that of the insulating film 123 and having, for example, a relative permittivity (k) of about 4.0. Examples of such a material include silicon oxide (SiOₓ), carbon-containing silicon oxide (SiOC), fluorine-doped silicon oxide (SiOF), and silicon oxynitride (SiON). It is to be noted that the insulating film 124 may be a single-layer film including any one of the above materials, or may be formed as a stacked film including two or more of the materials.

The insulating film 125 is to reduce warpage caused by stress generated upon formation of the electrically-conductive film 127 described later. The insulating film 125 is formed by, for example, a CVD (Chemical vapor deposition) method, and can be formed using, for example, silicon oxide (SiOₓ), silicon nitride (SiNₓ), or the like, in which relative permittivity (k) is 7.0 or more.

The insulating film 126 is provided on the insulating film 125, and is to form, for example, a bonded surface between a second substrate 20 and a third substrate 30 of the imaging element 1 described later. It is preferable to use, as a material of the insulating film 126, a material having, for example, a polishing rate higher than that of the insulating film 123 and having, for example, a relative permittivity (k) of about 4.0 to enable planarization of the bonded surface. Examples of such a material include silicon oxide (SiOₓ), SiOC, SiOF, and SiON. It is to be noted that the insulating film 126 may be a single-layer film including any one of the above materials, or may be formed as a stacked film including two or more of the materials.

The electrically-conductive film 127 corresponds to a “first electrically-conductive film” of the present disclosure. The electrically-conductive film 127 is, for example, a wiring layer provided immediately above the wiring layer 112 including the wiring line 112X1 to the wiring line 112X6 extending in one direction, and is embedded and formed in an opening H3 provided in a portion of the insulating film 126 and the insulating film 125, for example, to form the same plane as the insulating film 126. The electrically-conductive film 127 includes a plurality of electrically-conductive films (e.g., electrically-conductive films 127X1 and 127X2), and at least a portion of the electrically-conductive film 127 is provided to extend in one direction and is squarely opposed to at least a portion of the wiring line 112X1 to the wiring line 112X6. As an example, in FIG. 1, the electrically-conductive film 127X1 is formed to extend in the Y-axis direction, for example, in the same manner as the wiring line 112X2 and the wiring line 112X3, for example, at a position squarely opposed to the wiring line 112X2, the wiring line 112X3, and the wiring line 112X4 having the air gap G1 therebetween. An opening H4 penetrating the barrier film 121 to the insulating film 125 to reach the wiring line 112X1 is provided in the opening H3. The electrically-conductive film 127X1 is also embedded in the opening H4, and is electrically coupled to the wiring line 112X1. It is to be noted that the electrically-conductive film 127 may be formed above a wiring line (e.g., the wiring line 112X6) with no air gap G1 being formed between wiring lines, as in the electrically-conductive film 127X2 (unillustrated in FIG. 2) illustrated in FIGS. 1 and 3.

The electrically-conductive film 127 is configured by a barrier metal 127A formed on side surfaces and bottom surfaces of the opening H3 and the opening H4, and a metal film 127B in which the opening H3 and the opening H4 are embedded. Examples of a material of the barrier metal 127A include a simple substance of Ti (titanium) or Ta (tantalum), or a nitride, alloy, or the like thereof. Examples of a material of the metal film 127B include a metal material mainly including a low-resistance metal such as Cu (copper), W (tungsten), or aluminum (Al).

### 1-2. Method of Manufacturing Wiring Structure

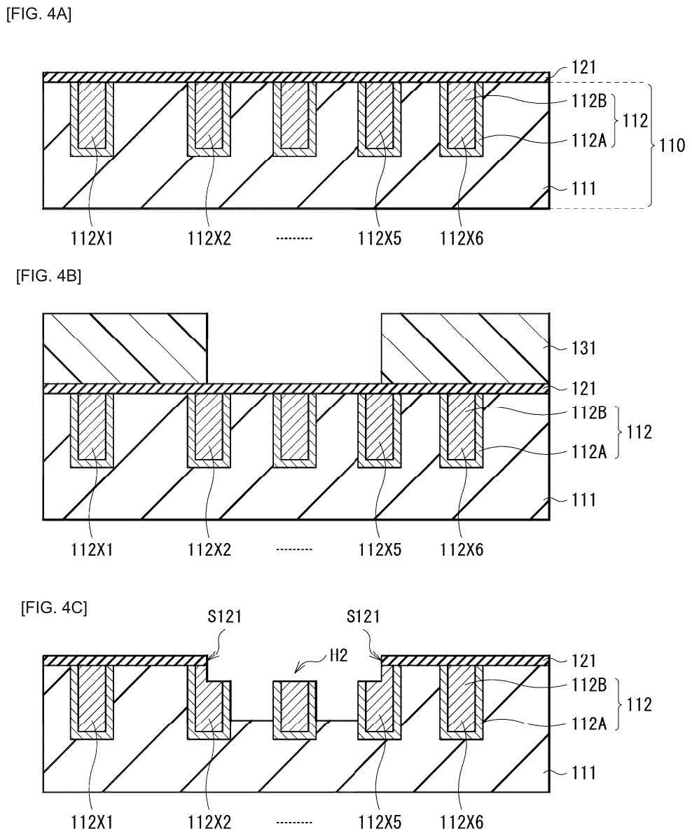

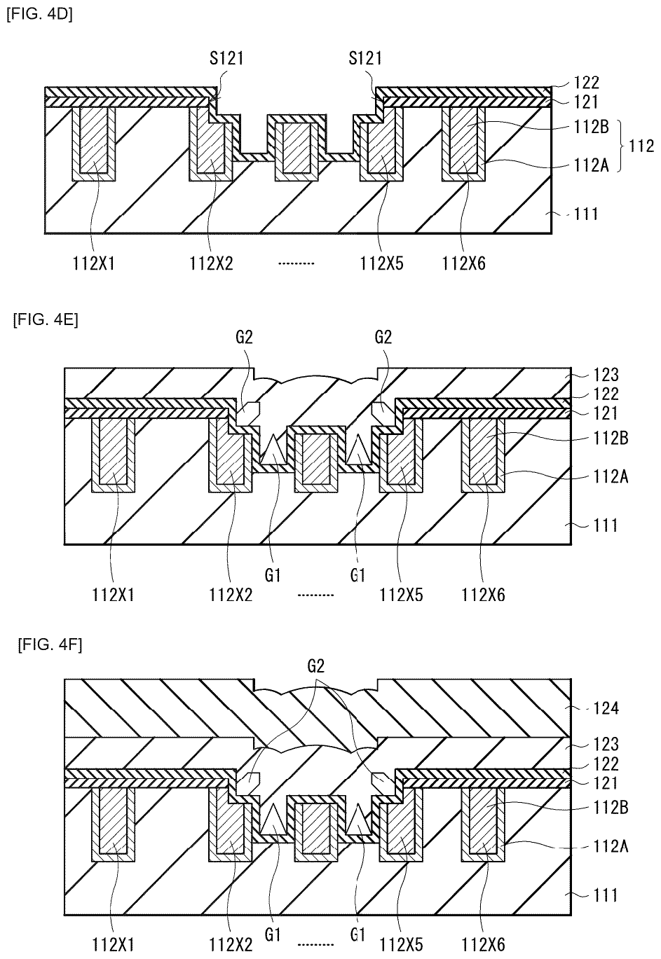

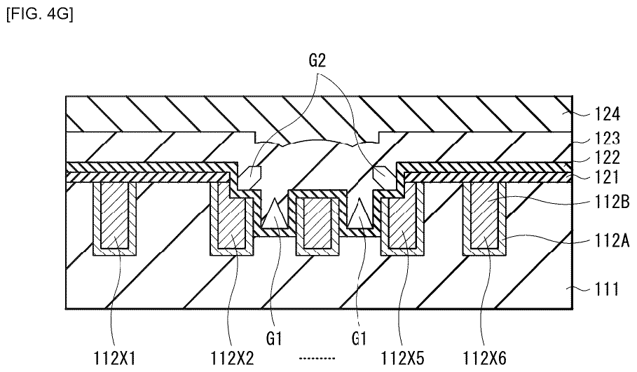

First, the wiring layer 112 including the wiring line 112X1 to the wiring line 112X6 is embedded and formed in the insulating film 111, and then a surface thereof is polished by, for example, a CMP (Chemical Mechanical Polishing) method to form the first layer 110. Subsequently, as illustrated in FIG. 4A, on the first layer 110, the barrier film 121 is formed to have a thickness of 10 nm to 50 nm using, for example, a PVD (Physical Vapor Deposition) method or a CVD (Chemical Vapor Deposition) method, for example.

Next, as illustrated in FIG. 4B, a resist film 131 having an opening at a position corresponding to the wiring line 121X2 to the wiring line 112X5 is patterned on the barrier film 121 using a photolithography technique. Subsequently, as illustrated in FIG. 4C, the barrier film 121, a portion of the wiring line 112X2 to the wiring line 112X5, and the insulating film 111 exposed from the resist film 131 are dry-etched, for example, to form the opening H2.

It is to be noted that, at that time, it is preferable to work the edge surface S121 of the barrier film 121 formed by the opening H2 not to have a forward tapered shape in which an edge surface upper part is inclined outwardly from the opening H2. Specifically, the edge surface S121 of the barrier film 121 is preferably worked to be perpendicular to a surface of the wiring layer 112, for example. As for such a working condition, for example, in dry etching, a reaction product generated during the etching adheres to a side wall to thereby tend to cause formation of a tapered shape; thus, a pressure and a process gas are adjusted to accelerate desorption of the reaction product. This allows the edge surface S121 of the barrier film 121 to be worked into a desired shape (vertical shape), thus enabling the air gap G2 to be formed near the edge surface S121 of the barrier film 121, upon formation of the insulating film 123 described later.

Next, the resist film 131 is removed, and then the insulating film 122 coating the top of the barrier film 121 and the side surface and the bottom surface of the opening H2 is formed, for example, to have a thickness of 5 nm to 50 nm using, for example, a CVD method, as illustrated in FIG. 4D. Subsequently, as illustrated in FIG. 4E, the insulating film 123 including, for example, SiOC or silicon nitride and having a film thickness of, for example, 100 nm to 500 nm is formed using a CVD method, for example. This allows the opening H2 to be closed, and allows for formation of the air gaps G1 and G2 at respective locations between the wiring line 112X2 and the wiring line 112X3, between the wiring line 112X3 and the wiring line 112X4, and between the wiring line 112X4 and a wiring line 112V5, and above the wiring line 112X2 and the wiring line 112X5 and near the edge surfaces S121 of the barrier film 121.

Next, as illustrated in FIG. 4F, the insulating film 124 including, for example, SiOₓ and having a film thickness of 200 nm to 300 nm is formed on the insulating film 123 using a CVD method, for example. Subsequently, as illustrated in FIG. 4G, the insulating film 124 is polished using a CMP method, for example, to planarize a surface thereof.

Next, for example, the insulating film 125 is formed to have a thickness of, for example, 50 nm to 500 nm on the insulating film 124 using a CVD method, for example, and then the insulating film 126 is formed to have a thickness of, for example, 100 nm to 2 μm on the insulating film 125 by a CVD method, for example. Subsequently, a portion of the insulating film 126 and the insulating film 125 is dry-etched, for example, to form the opening H3 using a method similar to that for the opening H2, and then the opening H4 penetrating the barrier film 121 to the insulating film 125 to reach the wiring line 112X1 is formed in the opening H3. Thereafter, the barrier metal 127A is formed on the side surfaces and the bottom surfaces of the opening H3 and the opening H4 using sputtering, for example, and then the metal film 127B is formed in the opening H3 and the opening H4 using plating, for example. Finally, the barrier metal 127A and the metal film 127B formed on the insulating film 126 are polished and removed to form a planar surface in which the insulating film 126 and the electrically-conductive film 127 constitute the same plane. The above-described steps allow the wiring structure 100 illustrated in FIG. 1 to be completed.

### 1-3. Configuration of Imaging Element

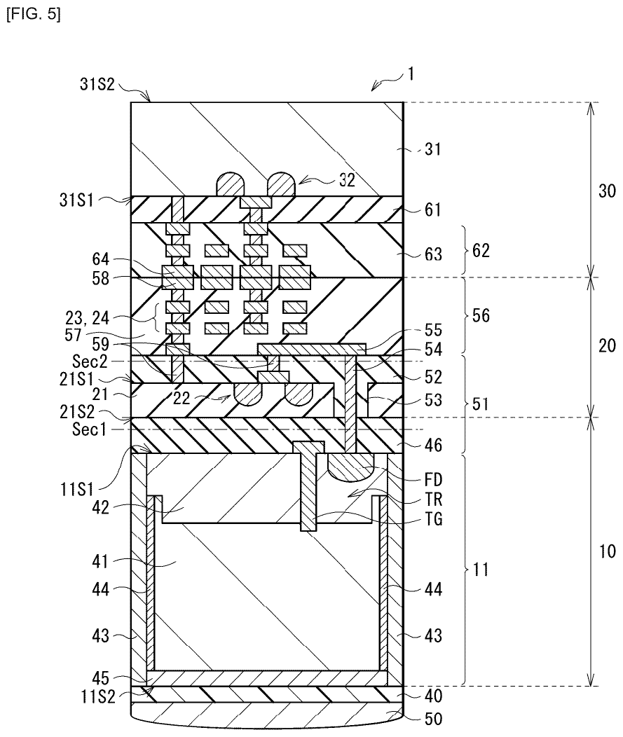

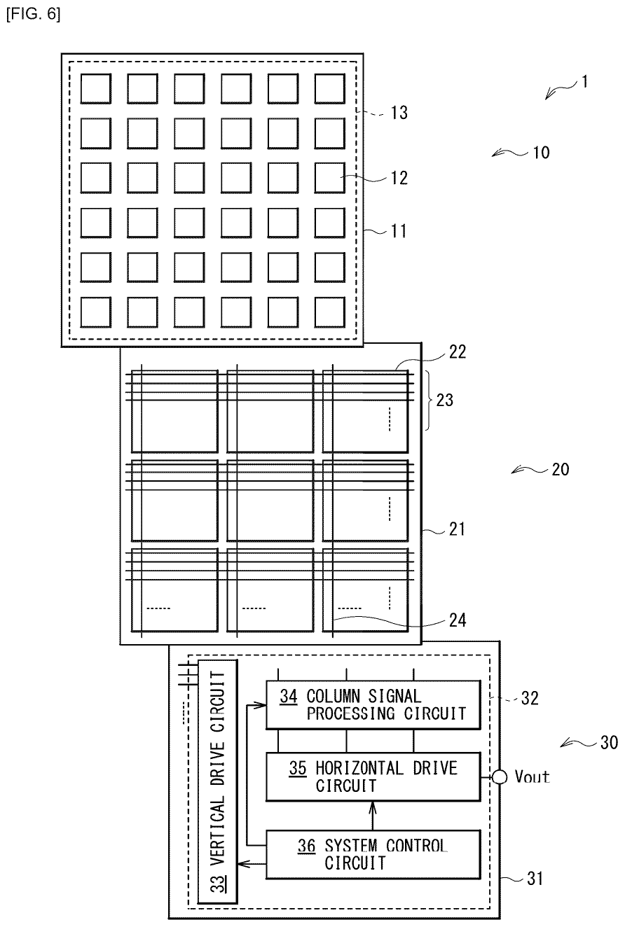

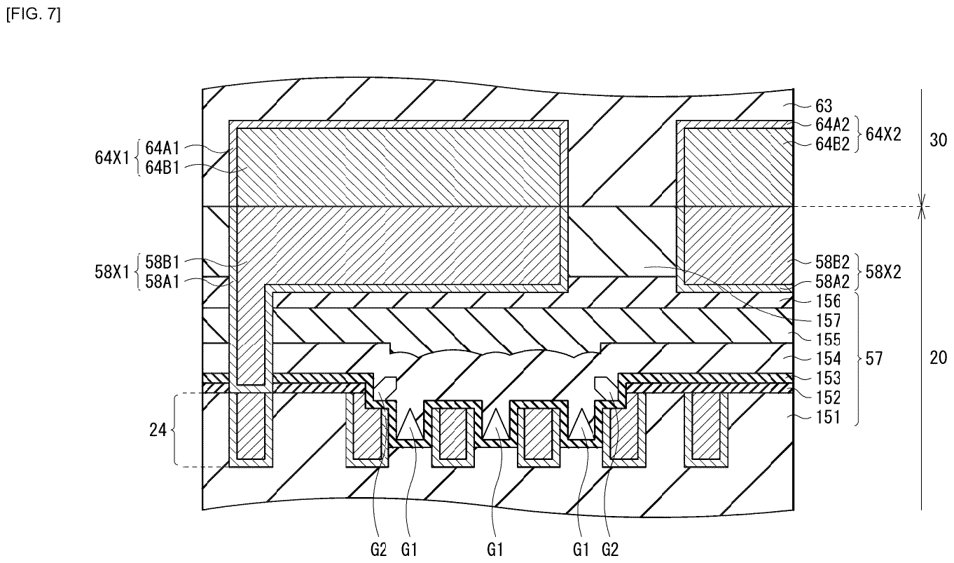

FIG. 5 illustrates an example of a cross-sectional configuration of an imaging element (imaging element 1) according to an embodiment of the present disclosure in the vertical direction. FIG. 6 illustrates an example of a schematic configuration of the imaging element 1 illustrated in FIG. 5. The imaging element 1 is an imaging element having a three-dimensional structure, in which a first substrate 10, which includes a sensor pixel 12 that performs photoelectric conversion in a semiconductor substrate 11, the second substrate 20, which includes a readout circuit 22 that outputs an image signal based on electric charge outputted from the sensor pixel 12 in a semiconductor substrate 21, and the third substrate 30, which includes a logic circuit 32 that processes a pixel signal in a semiconductor substrate 31, are stacked. As illustrated in FIG. 7, the above-described wiring structure 100 is applied to, for example, a wiring structure near a bonded surface of the second substrate 20 to be bonded to the third substrate 30.

As described above, the first substrate 10 includes, in the semiconductor substrate 11, a plurality of sensor pixels 12 performing photoelectric conversion. The plurality of sensor pixels 12 are provided in matrix inside a pixel region 13 in the first substrate 10. The second substrate 20 includes, in the semiconductor substrate 21, readout circuits 22, which each output a pixel signal based on electric charge outputted from the sensor pixels 12, with each one provided for every four sensor pixels 12. The second substrate 20 includes a plurality of pixel drive lines 23 extending in a row direction and a plurality of vertical signal lines 24 extending in a column direction. The third substrate 30 includes, in the semiconductor substrate 31, a logic circuit 32 that processes the pixel signal. The logic circuit 32 includes, for example, a vertical drive circuit 33, a column signal processing circuit 34, a horizontal drive circuit 35, and a system control circuit 36. The logic circuit 32 (specifically, the horizontal drive circuit 35) outputs an output voltage Vout for each sensor pixel 12 to the outside. In the logic circuit 32, for example, a low-resistance region including silicide formed using Salicide (Self Aligned Silicide) process such as CoSi₂ and NiSi may be formed on a surface of an impurity diffusion region in contact with a source electrode and a drain electrode. In the present embodiment, the semiconductor substrate 11 corresponds to a specific example of a “first semiconductor substrate” of the present disclosure, and the first substrate 10 corresponds to a specific example of a “first substrate” of the present disclosure. The semiconductor substrate 31 corresponds to a specific example of a “second semiconductor substrate” of the present disclosure, and the third substrate 30 corresponds to a specific example of a “second substrate” of the present disclosure. It is to be noted that the second substrate 20 including the semiconductor substrate 21 can be regarded as being included in a side of the “first substrate” and a side of the “second substrate” of the present disclosure.

The vertical drive circuit 33 sequentially selects, for example, the plurality of sensor pixels 12 in a unit of row. The column signal processing circuit 34 performs, for example, correlated double sampling (Correlated Double Sampling: CDS) processing on a pixel signal outputted from each sensor pixel 12 of a row selected by the vertical drive circuit 33. The column signal processing circuit 34 performs, for example, the CDS processing to thereby extract a signal level of the pixel signal and to hold pixel data corresponding to a received light amount of each sensor pixel 12. The horizontal drive circuit 35 sequentially outputs, for example, the pixel data held in the column signal processing circuit 34 to the outside. The system control circuit 36 controls, for example, driving of each of the blocks (the vertical drive circuit 33, the column signal processing circuit 34, and the horizontal drive circuit 35) inside the logic circuit 32.

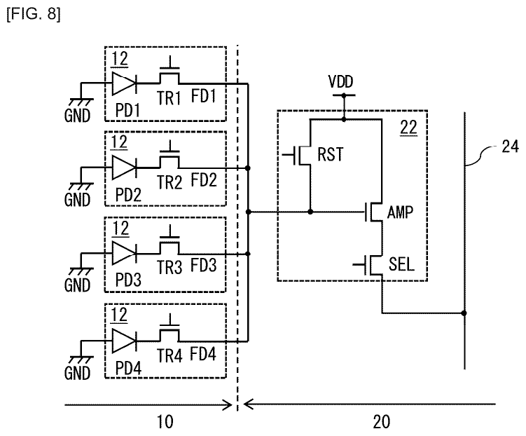

FIG. 8 illustrates an example of the sensor pixel 12 and the readout circuit 22. Hereinafter, a description is given of a case where four sensor pixels 12 share one readout circuit 22 as illustrated in FIG. 8. Here, the “share” refers to outputs of the four sensor pixels 12 being inputted to the common readout circuit 22.

Each sensor pixel 12 includes mutually common components. In FIG. 8, in order to distinguish components of the sensor pixels 12 from one another, an identification number (1, 2, 3, or 4) is assigned at the end of a symbol of the component of each sensor pixel 12. Hereinafter, in a case where the components of the respective sensor pixels 12 need to be distinguished from one another, the identification number is assigned to the end of the symbol of the component of each sensor pixel 12; however, in a case where the components of the respective sensor pixels 12 do not need to be distinguished from one another, the identification number at the end of the symbol of the component of each sensor pixel 12 is omitted.

Each sensor pixel 12 includes, for example, a photodiode PD, a transfer transistor TR electrically coupled to the photodiode PD, and a floating diffusion FD that temporarily holds electric charge outputted from the photodiode PD via the transfer transistor TR. The photodiode PD performs photoelectric conversion to generate electric charge corresponding to a received light amount. A cathode of the photodiode PD is electrically coupled to a source of the transfer transistor TR, and an anode of the photodiode PD is electrically coupled to a reference potential line (e.g., ground). A drain of the transfer transistor TR is electrically coupled to the floating diffusion FD, and a gate of the transfer transistor TR is electrically coupled to the pixel drive line 23. The transfer transistor TR is, for example, a CMOS (Complementary Metal Oxide Semiconductor) transistor.

The floating diffusions FD of the respective sensor pixels 12 sharing the one readout circuit 22 are electrically coupled to one another and are electrically coupled to an input end of the common readout circuit 22. The readout circuit 22 includes, for example, a reset transistor RST, a selection transistor SEL, and an amplification transistor AMP. It is to be noted that the selection transistor SEL may be omitted as needed. A source of the reset transistor RST (an input end of the readout circuit 22) is electrically coupled to the floating diffusion FD, and a drain of the reset transistor RST is electrically coupled to a power supply line VDD and a drain of the amplification transistor AMP. A gate of the reset transistor RST is electrically coupled to the pixel drive line 23. A source of the amplification transistor AMP is electrically coupled to a drain of the selection transistor SEL, and a gate of the amplification transistor AMP is electrically coupled to the source of the reset transistor RST. A source of the selection transistor SEL (an output end of the readout circuit 22) is electrically coupled to the vertical signal line 24, and a gate of the selection transistor SEL is electrically coupled to the pixel drive line 23.

When the transfer transistor TR is brought into an ON state, the transfer transistor TR transfers electric charge of the photodiode PD to the floating diffusion FD. The gate (a transfer gate TG) of the transfer transistor TR extends to penetrate a p-well layer 42 from a front surface of the semiconductor substrate 11 to such a depth as to reach a PD 41, for example, as illustrated in FIG. 5. The reset transistor RST resets a potential of the floating diffusion FD to a predetermined potential. When the reset transistor RST is brought into an ON state, the potential of the floating diffusion FD is reset to a potential of the power supply line VDD. The selection transistor SEL controls an output timing of the pixel signal from the readout circuit 22. The amplification transistor AMP generates, as a pixel signal, a signal of a voltage corresponding to a level of electric charge held in the floating diffusion FD. The amplification transistor AMP constitutes a source-follower type amplifier, and outputs a pixel signal of a voltage corresponding to a level of electric charge generated in the photodiode PD. When the selection transistor SEL is brought into an ON state, the amplification transistor AMP amplifies a potential of the floating diffusion FD, and outputs a voltage corresponding to the potential to the column signal processing circuit 34 via the vertical signal line 24. The reset transistor RST, the amplification transistor AMP, and the selection transistor SEL are each, for example, a CMOS transistor.

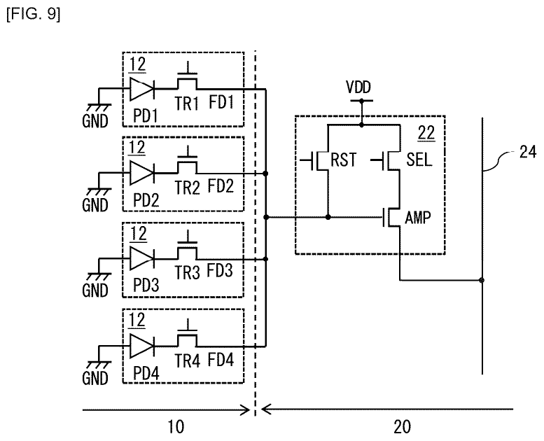

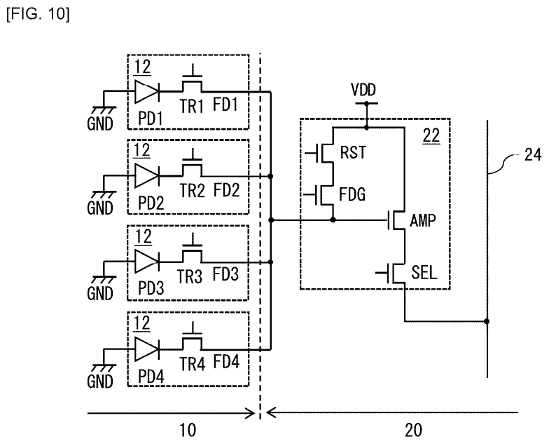

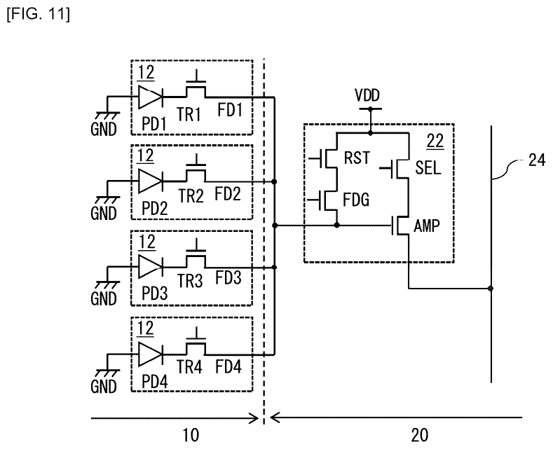

It is to be noted that, as illustrated in FIG. 9, the selection transistor SEL may be provided between the power supply line VDD and the amplification transistor AMP. In this case, the drain of the reset transistor RST is electrically coupled to the power supply line VDD and the drain of the selection transistor SEL. The source of the selection transistor SEL is electrically coupled to the drain of the amplification transistor AMP, and the gate of the selection transistor SEL is electrically coupled to the pixel drive line 23. The source of the amplification transistor AMP (an output end of the readout circuit 22) is electrically coupled to the vertical signal line 24, and the gate of the amplification transistor AMP is electrically coupled to the source of the reset transistor RST. In addition, as illustrated in FIGS. 10 and 11, an FD transfer transistor FDG may be provided between the source of the reset transistor RST and the gate of the amplification transistor AMP.

The FD transfer transistor FDG is used when switching conversion efficiency. In general, a pixel signal is small when shooting in a dark place. When performing charge-voltage conversion on a basis of Q=CV, larger capacity of the floating diffusion FD (FD capacitance C) causes the value V to be smaller upon conversion to a voltage at the amplification transistor AMP. Meanwhile, the pixel signal becomes large in a bright place; it is therefore not possible, for the floating diffusion FD, to receive the electric charge of the photodiode PD unless the FD capacitance C is large. Further, the FD capacitance C needs to be large to allow the value V not to be too large (in other words, to be small) upon the conversion to a voltage at the amplification transistor AMP. Taking these into account, when the FD transfer transistor FDG is turned ON, a gate capacitance for the FD transfer transistor FDG is increased, thus causing the entire FD capacitance C to be large. Meanwhile, when the FD transfer transistor FDG is turned OFF, the entire FD capacitance C becomes small. In this manner, performing ON/OFF switching of the FD transfer transistor FDG enables the FD capacitance C to be variable, thus making it possible to switch the conversion efficiency.

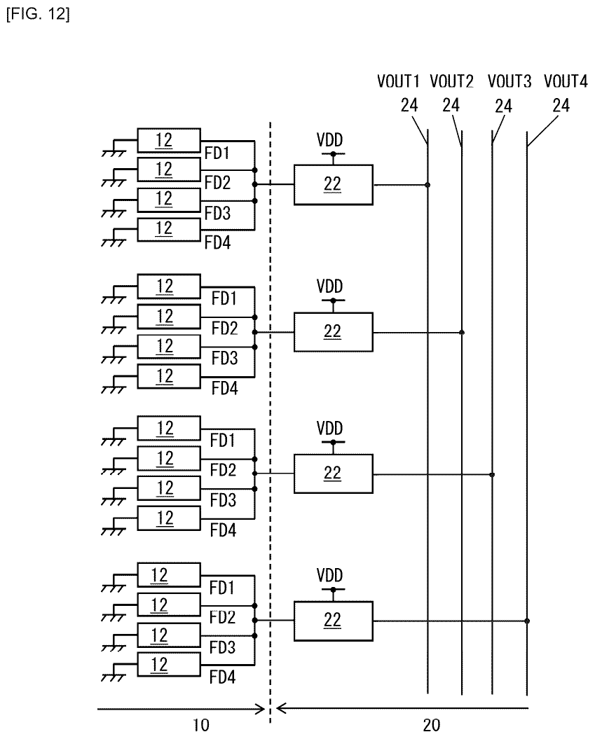

FIG. 12 illustrates an example of a coupling mode between a plurality of readout circuits 22 and the plurality of vertical signal lines 24. In a case where the plurality of readout circuits 22 are arranged side by side in a direction in which the vertical signal lines 24 extend (e.g., column direction), the plurality of vertical signal lines 24 may be assigned one by one for the respective readout circuits 22. For example, as illustrated in FIG. 12, in a case where four readout circuits 22 are arranged side by side in the direction in which the vertical signal lines 24 extend (e.g., column direction), four vertical signal lines 24 may be assigned one by one for the respective readout circuits 22. It is to be noted that, in FIG. 12, in order to distinguish the vertical signal lines 24, the identification number (1, 2, 3, or 4) is assigned to the end of the symbol of each vertical signal line 24.

Next, a description is given, with reference to FIG. 5, of a cross-sectional configuration of the imaging element 1 in the vertical direction. As described above, the imaging element 1 has a configuration, in which the first substrate 10, the second substrate 20, and the third substrate 30 are stacked in this order, and further includes a color filter 40 and a light-receiving lens 50 on a side of a back surface (light incident surface) of the first substrate 10. The color filter 40 and the light-receiving lens 50 are each provided one by one for each sensor pixel 12, for example. That is, the imaging element 1 is a back-illuminated imaging element.

The first substrate 10 has a configuration in which an insulating layer 46 is stacked on a front surface (a surface 11S1) of the semiconductor substrate 11. The first substrate 10 includes the insulating layer 46 as a portion of an interlayer insulating film 51. The insulating layer 46 is provided between the semiconductor substrate 11 and the semiconductor substrate 21 described later. The semiconductor substrate 11 is configured by a silicon substrate. The semiconductor substrate 11 includes, for example, the p-well layer 42 in a portion of the front surface and in the vicinity thereof, and includes the PD 41 of an electric conductivity type different from that of the p-well layer 42 in another region (a region deeper than the p-well layer 42). The p-well layer 42 is configured by a p-type semiconductor region. The PD 41 is configured by a semiconductor region of an electric conductivity type (specifically, n-type) different from that of the p-well layer 42. The semiconductor substrate 11 includes, inside the p-well layer 42, the floating diffusion FD as the semiconductor region of an electric conductivity type (specifically, n-type) different from that of the p-well layer 42.

The first substrate 10 includes, for each sensor pixel 12, the photodiode PD, the transfer transistor TR, and the floating diffusion FD. The first substrate 10 has a configuration in which the transfer transistor TR and the floating diffusion FD are provided in a portion of the semiconductor substrate 11 on a side of the surface 11S1 (on a side of the second substrate 20 on a side opposite to the light incident surface). The first substrate 10 includes an element separation section 43 that separates the sensor pixels 12 from each other. The element separation section 43 is formed to extend in a normal direction of the semiconductor substrate 11 (a direction perpendicular to the front surface of the semiconductor substrate 11). The element separation section 43 is provided between two sensor pixels 12 adjacent to each other. The element separation section 43 electrically separates the adjacent sensor pixels 12 from each other. The element separation section 43 is configured by, for example, silicon oxide. The element separation section 43 penetrates the semiconductor substrate 11, for example. The first substrate 10 further includes, for example, a p-well layer 44, which is a side surface of the element separation section 43 and is in contact with a surface on a side of the photodiode PD. The p-well layer 44 is configured by a semiconductor region of an electric conductivity type (specifically, p-type) different from that of the photodiode PD. The first substrate 10 further includes, for example, a fixed-charge film 45 in contact with a back surface (a surface 11S2, the other surface) of the semiconductor substrate 11. The fixed-charge film 45 has negative fixed electric charge in order to suppress generation of a dark current due to an interface state of the semiconductor substrate 11 on a side of a light-receiving surface. The fixed-charge film 45 is formed by, for example, an insulating film having negative fixed electric charge. Examples of a material of such an insulating film include hafnium oxide, zircon oxide, aluminum oxide, titanium oxide, and tantalum oxide. An electric field induced by the fixed-charge film 45 forms a hole accumulation layer at an interface of the semiconductor substrate 11 on the side of the light-receiving surface. This hole accumulation layer suppresses generation of electrons from the interface. The color filter 40 is provided on the side of the back surface of the semiconductor substrate 11. The color filter 40 is provided in contact with the fixed-charge film 45, for example, and is provided at a position opposed to the sensor pixel 12 with the fixed-charge film 45 interposed therebetween. The light-receiving lens 50 is provided in contact with the color filter 40, for example, and is provided at a position opposed to the sensor pixel 12 with the color filter 40 and the fixed-charge film 45 interposed therebetween.

The second substrate 20 has a configuration in which an insulating layer 52 is stacked on the semiconductor substrate 21. As for the insulating layer 52, the second substrate 20 includes the insulating layer 52 as a portion of the interlayer insulating film 51. The insulating layer 52 is provided between the semiconductor substrate 21 and the semiconductor substrate 31. The semiconductor substrate 21 is configured by a silicon substrate. The second substrate 20 includes one readout circuit 22 for every four sensor pixels 12. The second substrate 20 has a configuration in which the readout circuit 22 is provided in a portion of the semiconductor substrate 21 on a side of a front surface (a surface 21S1 opposed to the third substrate 30, one surface). The second substrate 20 is attached to the first substrate 10, with a back surface (a surface 21S2) of the semiconductor substrate 21 being opposed to the front surface (the surface 11S1) of the semiconductor substrate 11. That is, the second substrate 20 is attached to the first substrate 10 in a face-to-back manner. The second substrate 20 further includes an insulating layer 53 that penetrates the semiconductor substrate 21, in the same layer as the semiconductor substrate 21. The second substrate 20 includes the insulating layer 53 as a portion of the interlayer insulating film 51. The insulating layer 53 is provided to cover a side surface of a through-wiring line 54 described later.

A stacked body including the first substrate 10 and the second substrate 20 includes the interlayer insulating film 51 and the through-wiring line 54 provided inside the interlayer insulating film 51. The stacked body includes one through-wiring line 54 for each sensor pixel 12. The through-wiring line 54 extends in a normal direction of the semiconductor substrate 21, and is provided to penetrate a location, of the interlayer insulating film 51, including the insulating layer 53. The first substrate 10 and the second substrate 20 are electrically coupled to each other by the through-wiring line 54. Specifically, the through-wiring line 54 is electrically coupled to the floating diffusion FD and a coupling wiring line 55 described later.

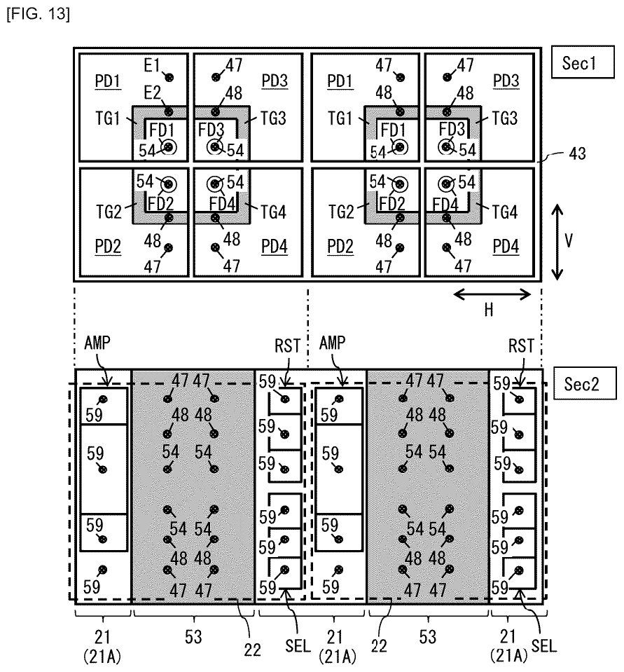

The stacked body including the first substrate 10 and the second substrate 20 further includes through-wiring lines 47 and 48 (see FIG. 13 described later) provided inside the interlayer insulating film 51. The stacked body includes one through-wiring line 47 and one through-wiring line 48 for each sensor pixel 12. Each of the through-wiring lines 47 and 48 extends in the normal direction of the semiconductor substrate 21, and is provided to penetrate a location, of the interlayer insulating film 51, including the insulating layer 53. The first substrate 10 and the second substrate 20 are electrically coupled to each other by the through-wiring lines 47 and 48. Specifically, the through-wiring line 47 is electrically coupled to the p-well layer 42 of the semiconductor substrate 11 and to a wiring line inside the second substrate 20. The through-wiring line 48 is electrically coupled to the transfer gate TG and to the pixel drive line 23.

The second substrate 20 includes, for example, inside the insulating layer 52, a plurality of coupling sections 59 electrically coupled to the readout circuit 22 and the semiconductor substrate 21. The second substrate 20 further includes, for example, a wiring layer 56 on the insulating layer 52. The wiring layer 56 includes, for example, an insulating layer 57, and the plurality of pixel drive lines 23 and the plurality of vertical signal lines 24 provided inside the insulating layer 57. The wiring layer 56 further includes, inside the insulating layer 57, for example, a plurality of coupling wiring lines 55, with each one provided for every four sensor pixels 12. The coupling wiring line 55 electrically couples respective through-wiring lines 54 electrically coupled to the floating diffusions FD included in the four sensor pixels 12 sharing the readout circuit 22. Here, the total number of the through-wiring lines 54 and 48 is more than the total number of the sensor pixels 12 included in the first substrate 10, and is twice the total number of the sensor pixels 12 included in the first substrate 10. In addition, the total number of the through-wiring lines 54, 48, and 47 is more than the total number of the sensor pixels 12 included in the first substrate 10, and is three times the total number of the sensor pixels 12 included in the first substrate 10.

The wiring layer 56 further includes, for example, a plurality of pad electrodes 58 inside the insulating layer 57. Each of the pad electrodes 58 is formed by a metal such as Cu (copper), tungsten (W), and Al (aluminum), for example. Each of the pad electrodes 58 is exposed to a surface of the wiring layer 56. Each of the pad electrodes 58 is used for electric coupling between the second substrate 20 and the third substrate 30 as well as for attaching the second substrate 20 and the third substrate 30 together. The plurality of pad electrodes 58 are provided one by one for the respective pixel drive lines 23 and the respective vertical signal lines 24, for example. Here, the total number of the pad electrodes 58 (or the total number of bondings between the pad electrode 58 and a pad electrode 64 (described later) is less than the total number of the sensor pixels 12 included in the first substrate 10, for example.

FIG. 7 schematically illustrates a cross-sectional configuration of the above-described wiring structure 100 applied to the imaging element 1. In the present embodiment, for example, the plurality of vertical signal lines 24 correspond to the wiring line 112X3 and the wiring line 112X4 in the above-described wiring structure 100, and a power supply line VSS corresponds to the wiring line 112X2 and the wiring line 112X5 in the above-described wiring structure 100. Although not illustrated in FIG. 5, the insulating layer 57 includes a plurality of insulating films 151 to 157 including a barrier film 152, as illustrated in FIG. 7. The insulating film 154 of those allows for formation of the air gaps G1 and G2 at respective locations between the power supply line VSS and the vertical signal line 24 running parallel to each other and between wiring lines of the plurality of vertical signal lines 24, and above the vertical signal lines 24 and near edge surfaces of the barrier film 152. The pad electrodes 58 exposed on the surface of the wiring layer 56 correspond to the electrically-conductive film 127X1 and the electrically-conductive film 127X2 in the above-described wiring structure 100.

A portion (a pad electrode 58X1) of the pad electrode 58 is electrically coupled to a ground line (wiring line 112X1). Although not illustrated, the ground line is coupled to, for example, a ground (GND) or a p-well of the semiconductor substrate 11. This enables the pad electrode 58X1 to be used as a shielded wiring line for a stacking direction of the vertical signal line 24, thus making it possible to reduce generation of noises in the vertical signal line 24.

Further, the pad electrode 58X1 functioning as a shielded wiring line is bonded to a pad electrode 64X1 on a side of the third substrate 30 described later. This enables impedance of the shielded wiring line to be reduced, as compared with a case where the shielded wiring line is formed by the pad electrode 58X1 alone. In addition, in the same manner as the vertical signal line 24, for example, the pad electrode 58X1 functioning as a shielded wiring line is provided to traverse the pixel region 13 longitudinally, and terminates near a peripheral edge beyond a region end of the pixel region 13.

The third substrate 30 has a configuration in which an interlayer insulating film 61 is stacked on the semiconductor substrate 31, for example. It is to be noted that, as described later, the third substrate 30 is attached to the second substrate 20 by the surfaces on the sides of front surfaces; therefore, in describing the configurations inside the third substrate 30, a vertical relationship to be described is opposite to the vertical direction in the drawing. The semiconductor substrate 31 is configured by a silicon substrate. The third substrate 30 has a configuration in which the logic circuit 32 is provided in a portion of the semiconductor substrate 31 on a side of a front surface (a surface 31S1). The third substrate 30 further includes, for example, a wiring layer 62 on the interlayer insulating film 61. The wiring layer 62 includes, for example, an insulating layer 63 and a plurality of pad electrodes 64 (e.g., the pad electrode 64X1 and a pad electrode 64X2) provided inside the insulating layer 63. The plurality of pad electrodes 64 is electrically coupled to the logic circuit 32. Each of the pad electrodes 64 is formed by Cu (copper), for example. Each of the pad electrodes 64 is exposed to a surface of the wiring layer 62. Each of the pad electrodes 64 is used for electric coupling between the second substrate 20 and the third substrate 30 as well as for attaching the second substrate 20 and the third substrate 30 together. In addition, the pad electrode 64 need not necessarily be a plurality of pad electrodes; even one pad electrode is able to be electrically coupled to the logic circuit 32. The second substrate 20 and the third substrate 30 are electrically coupled to each other by bondings between the pad electrodes 58 and 64. That is, the gate (transfer gate TG) of the transfer transistor TR is electrically coupled to the logic circuit 32 via the through-wiring line 54 and the pad electrodes 58 and 64. The third substrate 30 is attached to the second substrate 20, with the front surface (surface 31S1) of the semiconductor substrate 31 being opposed to a side of the front surface (surface 21S1) of the semiconductor substrate 21. That is, the third substrate 30 is attached to the second substrate 20 in a face-to-face manner.

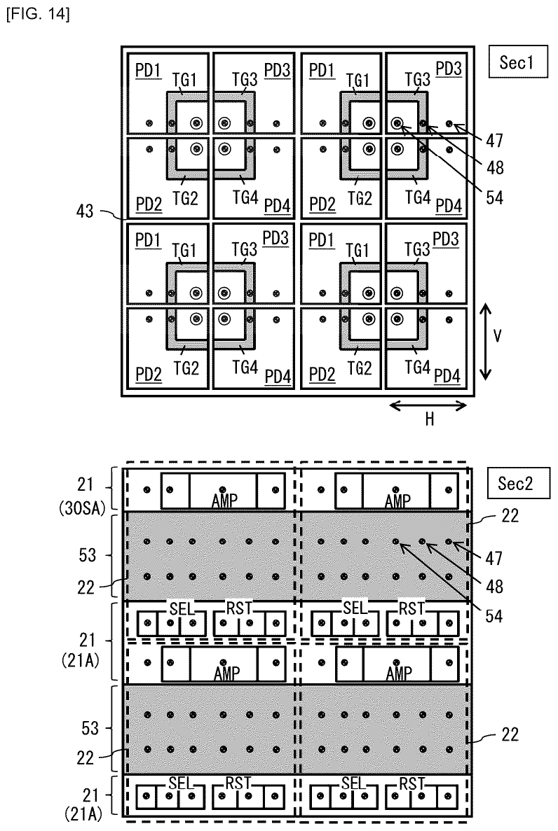

FIGS. 13 and 14 each illustrate an example of a cross-sectional configuration of the imaging element 1 in a horizontal direction. Each diagram on an upper side of FIGS. 13 and 14 illustrates an example of a cross-sectional configuration along a cross-section Sec1 in FIG. 1, and each diagram on a lower side of FIGS. 13 and 14 illustrates an example of a cross-sectional configuration along a cross-section Sec2 in FIG. 1. FIG. 13 exemplifies a configuration in which two sets of four sensor pixels 12 of 2×2 are arranged in a second direction H, and FIG. 14 exemplifies a configuration in which four sets of four sensor pixels 12 of 2×2 are arranged in a first direction V and the second direction H. It is to be noted that, in each cross-sectional view on the upper side of FIGS. 13 and 14, a diagram illustrating an example of the front surface configuration of the semiconductor substrate 11 is superimposed on a diagram illustrating the example of the cross-sectional configuration along the cross-section Sec1 in FIG. 1, with the insulating layer 46 being omitted. In addition, in each cross-sectional view on the lower side of FIGS. 13 and 14, a diagram illustrating an example of the front surface configuration of the semiconductor substrate 21 is superimposed on a diagram illustrating the example of the cross-sectional configuration along the cross-section Sec2 in FIG. 1.

As illustrated in FIGS. 13 and 14, a plurality of through-wiring lines 54, a plurality of through-wiring lines 48, and a plurality of through-wiring lines 47 are arranged side by side in a strip shape in the first direction V (vertical direction in FIG. 13, horizontal direction in FIG. 14) within the plane of the first substrate 10. It is to be noted that FIGS. 13 and 14 each exemplify the case where the plurality of through-wiring lines 54, the plurality of through-wiring lines 48, and the plurality of through-wiring lines 47 are arranged side by side in two rows in the first direction V. The first direction V is parallel to one arrangement direction (e.g., column direction) of two arrangement directions (e.g., row direction and column direction) of the plurality of sensor pixels 12 arranged in matrix. In the four sensor pixels 12 sharing the readout circuit 22, four floating diffusions FD are arranged close to each other, for example, with the element separation section 43 interposed therebetween. In the four sensor pixels 12 sharing the readout circuit 22, four transfer gates TG are arranged to surround the four floating diffusions FD, and the four transfer gates TG form an annular shape, for example.

The insulating layer 53 is configured by a plurality of blocks extending in the first direction V. The semiconductor substrate 21 extends in the first direction V, and is configured by a plurality of island-shaped blocks 21A arranged side by side in the second direction H orthogonal to the first direction V, with the insulating layer 53 interposed therebetween. Each block 21A is provided with, for example, a plurality of sets of the reset transistors RST, the amplification transistors AMP, and the selection transistors SEL. The one readout circuit 22 shared by the four sensor pixels 12 is configured by, for example, the reset transistor RST, the amplification transistor AMP, and the selection transistor SEL in a region facing the four sensor pixels 12. The one readout circuit 22 shared by the four sensor pixels 12 is configured by, for example, the amplification transistor AMP inside the left adjacent block 21A of the insulating layer 53, and the reset transistor RST and the selection transistor SEL inside the right adjacent block 21A of the insulating layer 53.

FIGS. 15, 16, 17, and 18 each illustrate an example of a wiring line layout in a horizontal plane of the imaging element 1. FIGS. 15 to 18 each exemplify the case where the one readout circuit 22 shared by the four sensor pixels 12 is provided inside a region facing the four sensor pixels 12. The wiring lines illustrated in FIGS. 15 to 18 are provided, for example, inside mutually different layers in the wiring layer 56.

Four through-wiring lines 54 adjacent to one another are electrically coupled to the coupling wiring line 55, for example, as illustrated in FIG. 15. The four through-wiring lines 54 adjacent to one another are further electrically coupled to the gate of the amplification transistor AMP included in the left adjacent block 21A of the insulating layer 53 and to the gate of the reset transistor RST included in the right adjacent block 21A of the insulating layer 53 via the coupling wiring line 55 and the coupling section 59, for example, as illustrated in FIG. 15.

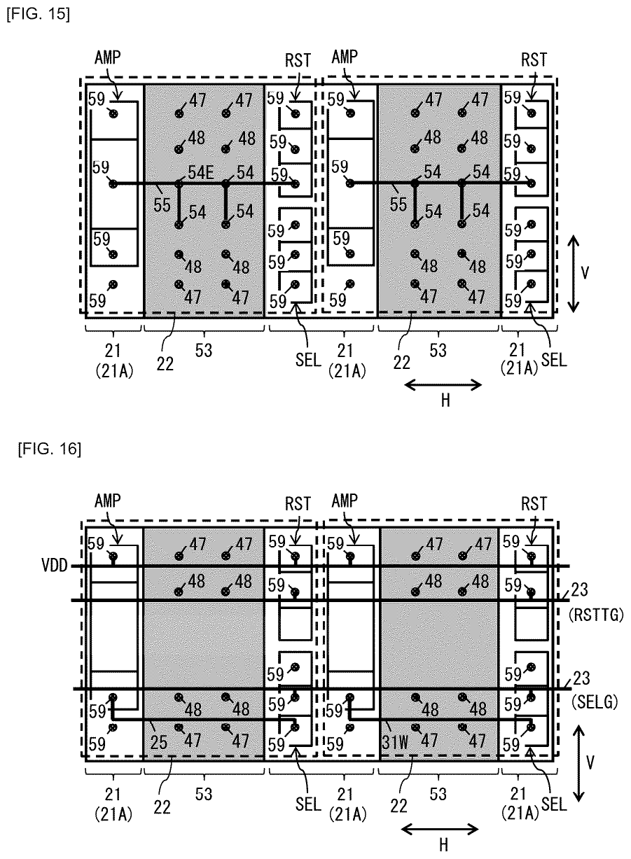

The power supply line VDD is arranged at positions facing the readout circuits 22 arranged side by side in the second direction H, for example, as illustrated in FIG. 16. The power supply line VDD is electrically coupled to the drain of the amplification transistor AMP and the drain of the reset transistor RST of each of the readout circuits 22 arranged side by side in the second direction H via the coupling section 59, for example, as illustrated in FIG. 16. Two pixel drive lines 23 are arranged at positions facing the readout circuits 22 arranged side by side in the second direction H, for example, as illustrated in FIG. 16. One pixel drive line 23 (a second control line) is a wiring line RSTG electrically coupled to the gate of the reset transistor RST of each of the readout circuits 22 arranged side by side in the second direction H, for example, as illustrated in FIG. 16. The other pixel drive line 23 (a third control line) is a wiring line SELG electrically coupled to the gate of the selection transistor SEL of each of the readout circuits 22 arranged side by side in the second direction H, for example, as illustrated in FIG. 16. In each of the readout circuits 22, the source of the amplification transistor AMP and the drain of the selection transistor SEL are electrically coupled to each other via a wiring line 25, for example, as illustrated in FIG. 16.

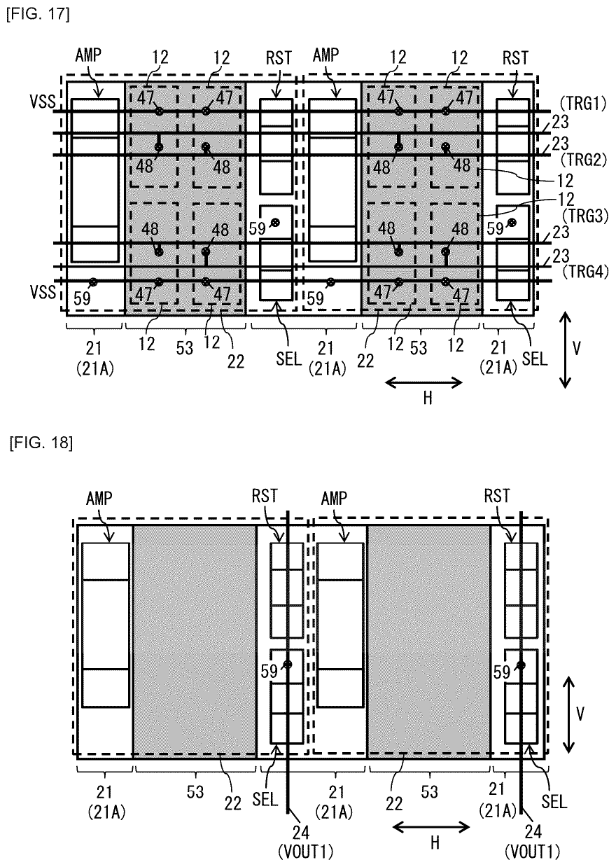

Two power supply lines VSS are arranged at positions facing the readout circuits 22 arranged side by side in the second direction H, for example, as illustrated in FIG. 17. Each of the power supply lines VSS is electrically coupled to the plurality of through-wiring lines 47 at positions facing the respective sensor pixels 12 arranged side by side in the second direction H, for example, as illustrated in FIG. 17. Four pixel drive lines 23 are each arranged at positions facing the readout circuits 22 arranged side by side in the second direction H, for example, as illustrated in FIG. 17. Each of the four pixel drive lines 23 is a wiring line TRG electrically coupled to the through-wiring line 48 of one sensor pixel 12 of the four sensor pixels 12 corresponding to each of the readout circuits 22 arranged side by side in the second direction H, for example, as illustrated in FIG. 17. That is, the four pixel drive lines 23 (first control lines) are each electrically coupled to the gate (transfer gate TG) of the transfer transistor TR of each of the sensor pixels 12 arranged side by side in the second direction H. In FIG. 17, in order to distinguish the wiring lines TRG from one another, an identifier (1, 2, 3, or 4) is assigned to the end of each wiring line TRG.

The vertical signal line 24 is arranged at positions facing the readout circuits 22 arranged side by side in the first direction V, for example, as illustrated in FIG. 18. The vertical signal line 24 (an output line) is electrically coupled to an output end (the source of the amplification transistor AMP) of each of the readout circuits 22 arranged side by side in the first direction V, for example, as illustrated in FIG. 18.

### 1-4. Method of Manufacturing Imaging Element

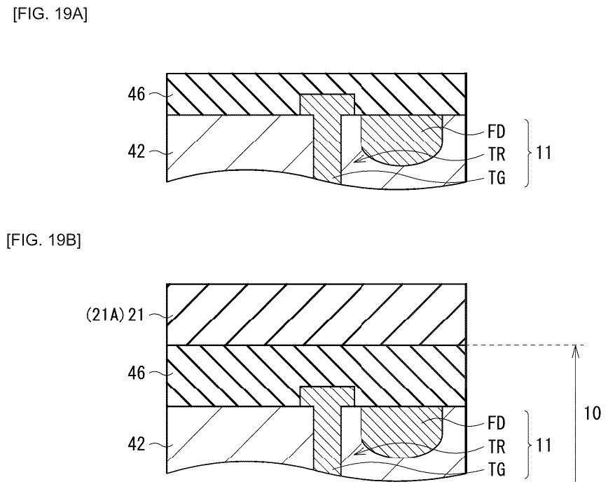

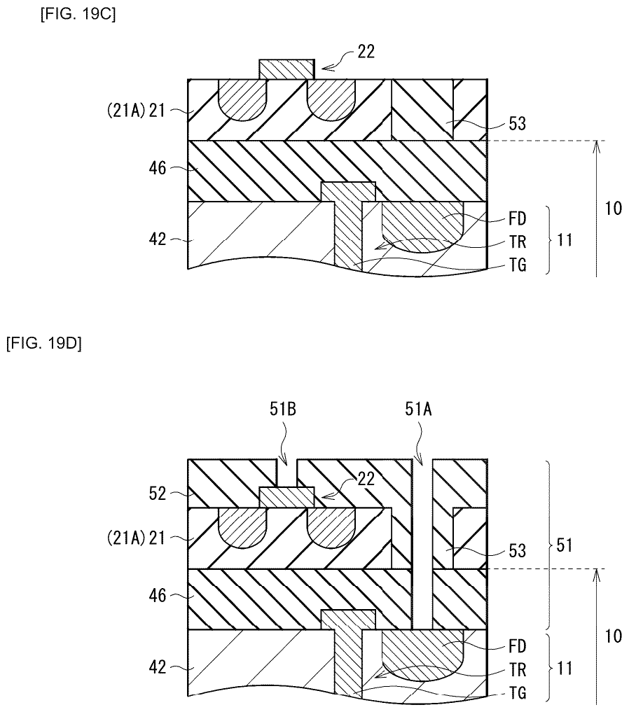

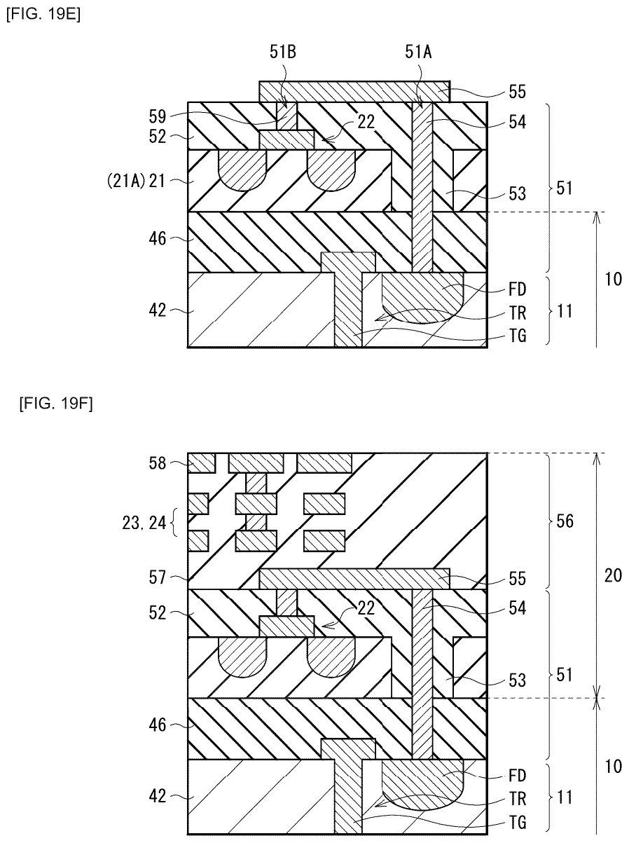

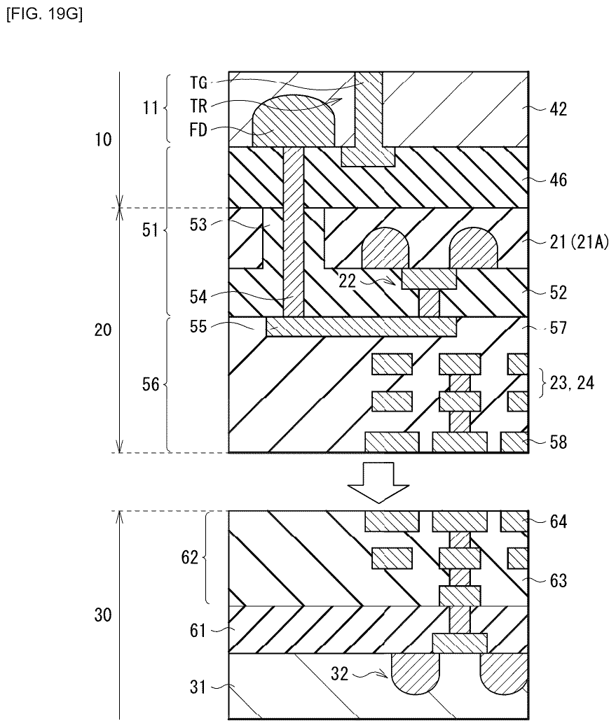

Next, a description is given of a method of manufacturing the imaging element 1. FIGS. 19A to 19G each illustrate an example of a manufacturing process of the imaging element 1.

First, the p-well layer 42, the element separation section 43, and the p-well layer 44 are formed in the semiconductor substrate 11. Next, the photodiode PD, the transfer transistor TR, and the floating diffusion FD are formed in the semiconductor substrate 11 (FIG. 19A). This allows for formation of the sensor pixel 12 in the semiconductor substrate 11. At this time, it is preferable not to use, as an electrode material to be used for the sensor pixel 12, a material having low heat resistance such as CoSi₂ and NiSi by Salicide process. Rather, it is preferable to use, as the electrode material to be used for the sensor pixel 12, a material having high heat resistance. Examples of the material having high heat resistance include polysilicon. Thereafter, the insulating layer 46 is formed on the semiconductor substrate 11 (FIG. 19A). In this manner, the first substrate 10 is formed.

Next, the semiconductor substrate 21 is attached onto the first substrate 10 (an insulating layer 46B) (FIG. 19B). Thereafter, the semiconductor substrate 21 is thinned, as needed. In this occasion, the thickness of the semiconductor substrate 21 is set to a film thickness necessary for formation of the readout circuit 22. The thickness of the semiconductor substrate 21 is typically about several hundred nm. However, an FD (Fully Depletion) type is also available depending on the concept of the readout circuit 22; in such a case, a range from several nm to several m may be employed as the thickness of the semiconductor substrate 21.

Subsequently, the insulating layer 53 is formed inside the same layer as the semiconductor substrate 21 (FIG. 19C). The insulating layer 53 is formed, for example, at a location facing the floating diffusion FD. For example, a slit (an opening 21H) penetrating the semiconductor substrate 21 is formed in the semiconductor substrate 21 to separate the semiconductor substrate 21 into the plurality of blocks 21A. Thereafter, the insulating layer 53 is formed to fill the slit. Thereafter, the readout circuit 22 including the amplification transistor AMP, and the like is formed in each of the blocks 21A of the semiconductor substrate 21 (FIG. 19C). At this time, in a case where a metal material having high heat resistance is used as the electrode material of the sensor pixel 12, it is possible to form a gate insulating film of the readout circuit 22 by thermal oxidation.

Next, the insulating layer 52 is formed on the semiconductor substrate 21. In this manner, the interlayer insulating film 51 including the insulating layers 46, 52, and 53 is formed. Subsequently, through-holes 51A and 51B are formed in the interlayer insulating film 51 (FIG. 19D). Specifically, the through-hole 51B penetrating the insulating layer 52 is formed at a location, of the insulating layer 52, facing the readout circuit 22. In addition, the through-hole 51A penetrating the interlayer insulating film 51 is formed at a location, of the interlayer insulating film 51, facing the floating diffusion FD (i.e., a location facing the insulating layer 53).

Subsequently, embedding an electrically-conductive material in the through-holes 51A and 51B allows for formation of the through-wiring line 54 inside the through-hole 51A as well as formation of the coupling section 59 inside the through-hole 51B (FIG. 19E). Further, the coupling wiring line 55 electrically coupling the through-wiring line 54 and the coupling section 59 to each other is formed on the insulating layer 52 (FIG. 19E). Thereafter, the wiring layer 56 is formed on the insulating layer 52 (FIG. 19F). In this manner, the second substrate 20 is formed.

Next, the second substrate 20 is attached to the third substrate 30 in which the logic circuit 32 and the wiring layer 62 are formed, with the front surface of the semiconductor substrate 21 being opposed to a side of a front surface of the semiconductor substrate 31 (FIG. 19G). At this time, the pad electrode 58 of the second substrate 20 and the pad electrode 64 of the third substrate 30 are bonded to each other, thereby electrically coupling the second substrate 20 and the third substrate 30 to each other. In this manner, the imaging element 1 is manufactured.

### 1-5. Workings and Effects

In the wiring structure 100 of the present embodiment and the imaging element 1 to which the wiring structure 100 is applied, the air gaps G1 and G2 are provided at locations between a plurality of wiring lines extending in one direction (e.g., Y-axis direction) and near a portion of the wiring lines. For example, among the wiring line 112X1 to the wiring line 112X6 extending in the Y-axis direction which are filled with the insulating film 123, the air gap G1 is formed between the wiring line 112X2 and the wiring line 112X3 adjacent to each other, between the wiring line 112X3 and the wiring line 112X4 adjacent to each other, and between the wiring line 112X4 and the wiring line 112X5 adjacent to each other. The air gap G2 is formed near the edge surfaces S121, of the barrier film 121 extending on the wiring layer 112 including the wiring line 112X1 to the wiring line 112X6, formed above the wiring line 112X2 and the wiring line 112X5. This allows for a reduction in capacitance between wiring lines extending in one direction. This is described below.

As described above, as a semiconductor integrated circuit element becomes more miniaturized in a semiconductor device, in recent years, an interval has become narrower between wiring lines each coupling elements and between wiring lines inside an element, thus causing capacitance (parasitic capacitance) between wiring lines to tend to be increased. The increased capacitance between the wiring lines causes a wiring signal to be delayed, thus resulting in a lowered operation speed of a device, which is an issue. Therefore, in a typical semiconductor device, a Low-k material is used to electrically insulate wiring lines from each other in the stacking direction, and an air gap is provided between wiring lines running parallel to each other, thereby achieving a reduction in the parasitic capacitance between the wiring lines.

In the semiconductor device as described above, in a case where a via is formed to couple wiring lines, between which an air gap is formed, to upper layer wiring lines, there is a limitation that no air gap is formed next to a wiring line for which the via is formed, in order to prevent occurrence of an unintended short circuit due to the air gap. Therefore, there is an issue that it is not possible to sufficiently reduce the capacitance of the entire wiring layer.

In addition, in a case where a wiring line is formed using copper (Cu), a barrier film having a value of high relative permittivity (k) is typically stacked on the Cu wiring line. Therefore, there is an issue that a wiring line part with no air gap being formed causes the capacitance in the stacking direction to be higher.

In contrast, in the present embodiment, for example, a film forming method with low step coverage is used to form the insulating film 123 between the plurality of wiring lines (e.g., between the wiring line 112X2 and the wiring line 112X3 adjacent to each other, between the wiring line 112X3 and the wiring line 112X4 adjacent to each other, and between the wiring line 112X4 and the wiring line 112X5 adjacent to each other) exposed by the opening H2 and extending in the Y-axis direction, and on the peripheral insulating film thereof (e.g., insulating film 122). This allows for formation of the air gaps G1 and G2 at respective locations between the wiring line 112X2 and the wiring line 112X3 adjacent to each other, between the wiring line 112X3 and the wiring line 112X4 adjacent to each other and between the wiring line 112X4 and the wiring line 112X5 adjacent to each other, and near the edge surfaces S121, of the barrier film 121 extending on the wiring layer 112, formed above the wiring line 112X2 and the wiring line 112X5, for example. This allows for a reduction in the capacitance between and near the wiring lines, as compared with a case where an air gap is formed only between wiring lines.

As described above, it is possible for the wiring structure 100 of the present embodiment to reduce wiring capacitance of the entire structure. In addition, it is possible for the imaging element 1 to which the wiring structure 100 of the present embodiment is applied, for example, to reduce the wiring capacitance between and near the wiring lines of the plurality of vertical signal lines 24 that traverse the pixel region 13 longitudinally.

In addition, in the present embodiment, the insulating film 122 formed on the barrier film 121 to coat the edge surfaces S121 of the barrier film 121, the top surfaces and the side surfaces of the wiring line 112X2, the wiring line 112X3, the wiring line 112X4 and the wiring line 112X5 which extend in the Y-axis direction and the bottom surface of the opening H2 is formed using a film forming method with low step coverage. This causes the step coverage by the insulating film 123 to be deteriorated, thus making it possible to accelerate closure of the opening H2. Thus, it is possible to form the air gaps G1 and G2 which are larger.

Descriptions are given below of Modification Examples 1 to 15. It is to be noted that, in the following description, the same components as those of the foregoing embodiment are denoted by the same reference numerals, and the descriptions thereof are omitted as appropriate.

### 2. Modification Examples

### 2-1. Modification Example 1

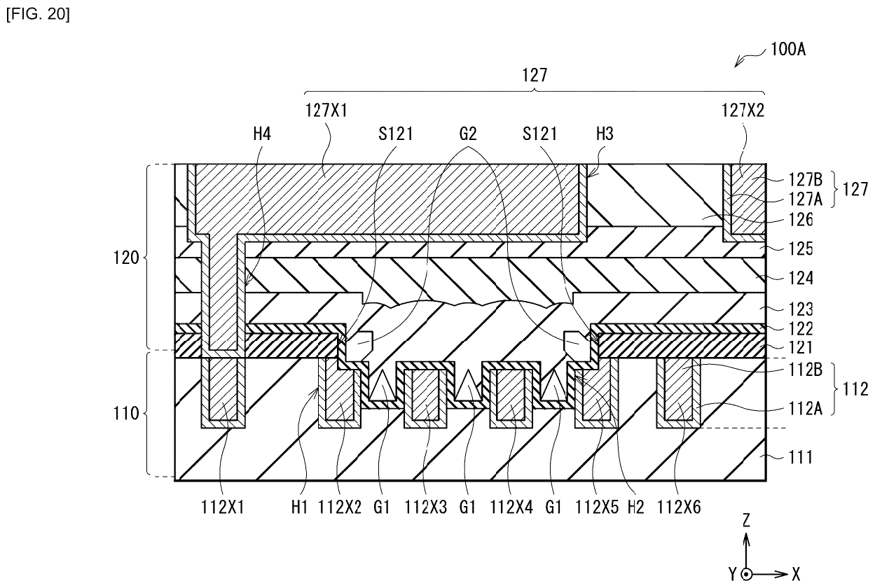

FIG. 20 schematically illustrates an example of a cross-sectional configuration of a wiring structure (a wiring structure 100A) according to a modification example (Modification Example 1) of the present disclosure in the vertical direction. The wiring structure 100A of the present modification example differs from the foregoing embodiment in that the barrier film 121 is formed to have a thickness of 50 nm to 150 nm, for example.

As described above, forming the barrier film 121 to have a large thickness allows a step difference including the top surface of the wiring line 112X2 or 112X5, and the edge surface S121 and the top surface of the barrier film 121 to be larger, thus making it possible to form the air gap G2 formed above the wiring line 112X2 and the wiring line 112X5 and near the edge surfaces S121 to be larger. It is therefore possible for the wiring structure 100A of the present modification example to further reduce the wiring capacitance between and near the wiring lines, as compared with the wiring structure 100 of the foregoing embodiment.

### 2-2. Modification Example 2

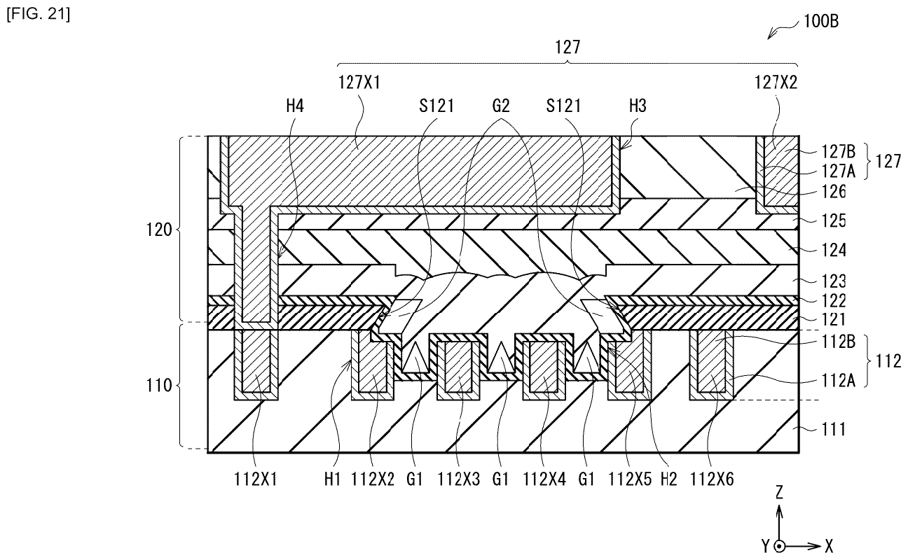

FIG. 21 schematically illustrates an example of a cross-sectional configuration of a wiring structure (a wiring structure 100B) according to a modification example (Modification Example 2) of the present disclosure in the vertical direction. The wiring structure 100B of the present modification example differs from the foregoing Modification Example 1 in that the edge surface S121 of the barrier film 121 has a so-called reverse tapered shape in which an end on a side of an undersurface (a side of the wiring line) is retracted to the outside of the opening H2 than an end on a side of the top surface.

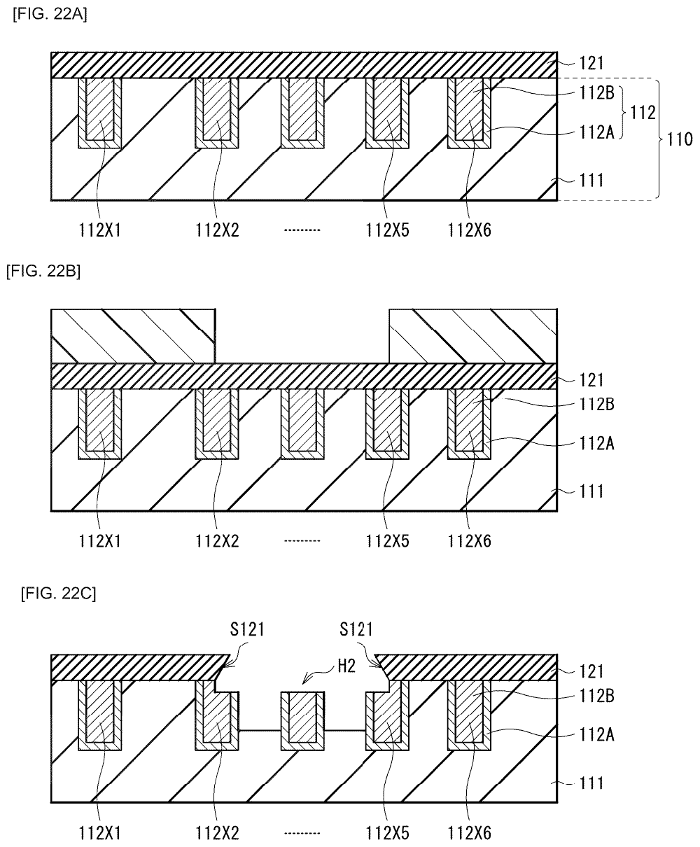

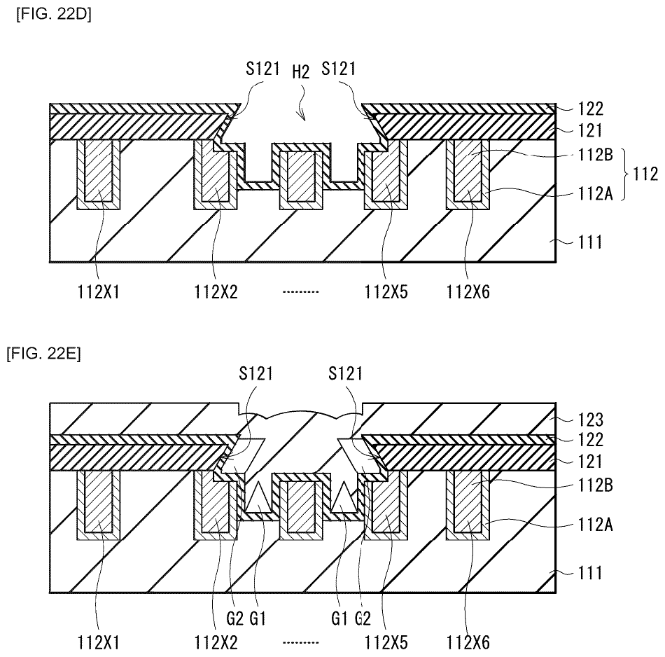

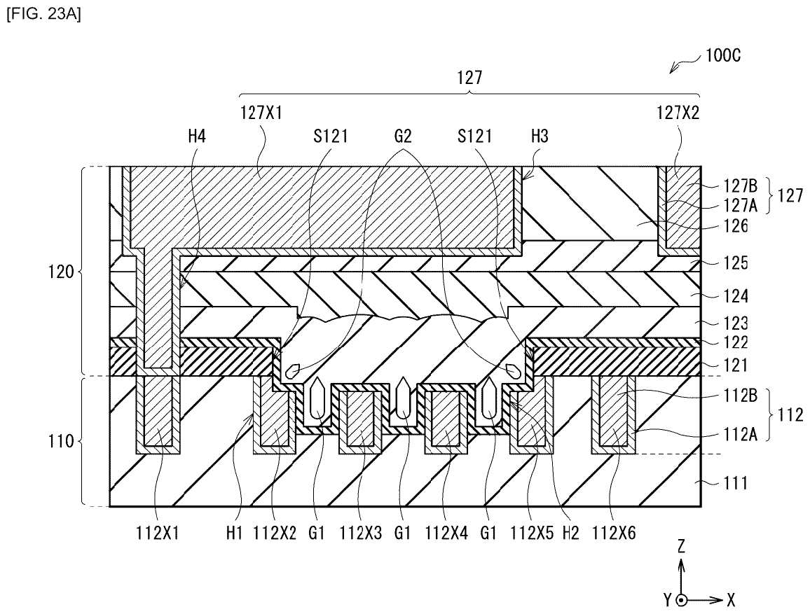

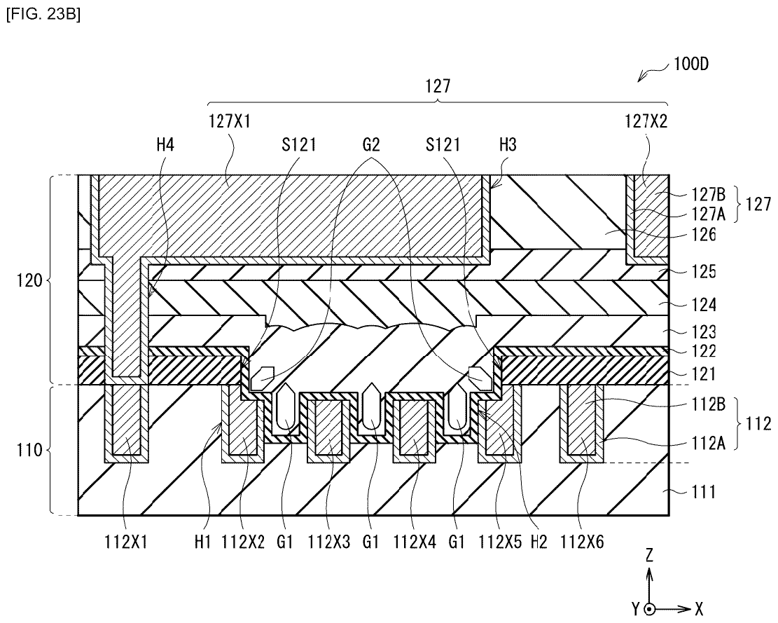

FIGS. 22A to 22E each illustrate an example of a manufacturing step of the wiring structure 100B illustrated in FIG. 21.

First, components up to the first layer 110 are formed in the same manner as the foregoing embodiment, and thereafter, as illustrated in FIG. 22A, the barrier film 121 is formed to have a thickness of, for example, 50 nm to 150 nm on the first layer 110 using, for example, a PVD method or a CVD method. Next, as illustrated in FIG. 22B, the resist film 131 having an opening at a position corresponding to the wiring line 121X2 to the wiring line 112X5 is patterned on the barrier film 121 using a photolithography technique.

Subsequently, as illustrated in FIG. 22C, the barrier film 121, a portion of the wiring line 112X2 to the wiring line 112X5, and the insulating film 111 exposed from the resist film 131 are dry-etched, for example, to form the opening H2. At that time, by devising the process, in terms of a pressure during the etching or addition of an oxygen (O₂) gas as a process gas, or the like, for example, the edge surface S121 of the barrier film 121 is worked into a reverse tapered shape as illustrated in FIG. 22C.

Next, after removal of the resist film 131, the insulating film 122 to coat the top of the barrier film 121 and the side surface and the bottom surface of the opening H2 is formed to have a thickness of, for example, 5 nm to 50 nm using, for example, a CVD method, as illustrated in FIG. 22D. Subsequently, as illustrated in FIG. 22E, the insulating film 123 having a film thickness of, for example, 100 nm to 500 nm including, for example, SiOC or silicon nitride is formed using, for example, a CVD method. This allows the opening H2 to be closed, and allows for formation of the air gaps G1 and G2 at respective locations between the wiring line 112X2 and the wiring line 112X3, between the wiring line 112X3 and the wiring line 112X4 and between the wiring line 112X4 and the wiring line 112V5, and above the wiring line 112X2 and the wiring line 112X5 and near the edge surfaces S121 of the barrier film 121.

Thereafter, the insulating films 124, 125 and 126 and the electrically-conductive film 127 are sequentially formed in the same manner as the foregoing embodiment. The above-described steps allow the wiring structure 100B illustrated in FIG. 21 to be completed.

As described above, in the present modification example, for example, the edge surfaces S121 of the barrier film 121 formed above the wiring line 112X2 and the wiring line 112X5 are formed to have a reverse tapered shape. Thus, for example, when forming the insulating film 123 using a method of forming a film having lower step coverage, such as a CVD method, the insulating film 123 is unable to follow the edge surface S121 of the barrier film 121. This further accelerates the closure of the opening H2, thus making it possible to form the air gaps G1 and G2 which are larger.

### 2-3. Modification Example 3

FIG. 23A schematically illustrates an example of a cross-sectional configuration of a wiring structure (a wiring structure 100C) according to a modification example (Modification Example 3) of the present disclosure in the vertical direction. FIG. 23B schematically illustrates another example of a cross-sectional configuration of a wiring structure (a wiring structure 100D) according to Modification Example 3 of the present disclosure in the vertical direction. The shapes of the air gaps G1 and G2 can also be controlled, for example, by changing the materials of the insulating films 122 and 123.

For example, in a case where phosphosilicate glass (PSG), which is generally considered to be excellent in step coverage, is used as the material of the insulating film 123, the air gaps G1 and G2 each have a rounded shape, as illustrated in FIG. 23A. Meanwhile, when silicon nitride or SiOC having low step coverage is used as in the foregoing embodiment, the actual air gaps G1 and G2 each have a shape as illustrated in FIG. 23B.

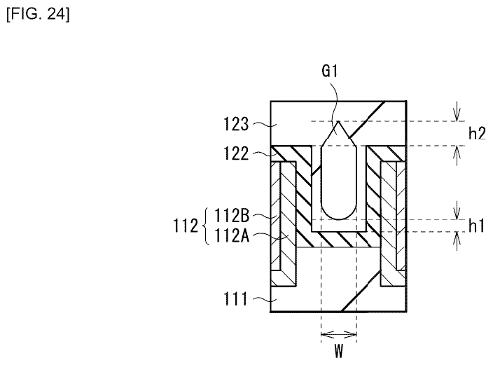

For example, as illustrated in FIG. 24, a distance h1 between the bottom surface of the opening H2 and the air gap G1 of the wiring structure 100D is narrower than that of the wiring structure 00C, and a height h2 of a closed part of the air gap G1 and a width W of the air gap G1 of the wiring structure 100D are longer (wider) than those of the wiring structure OOC.

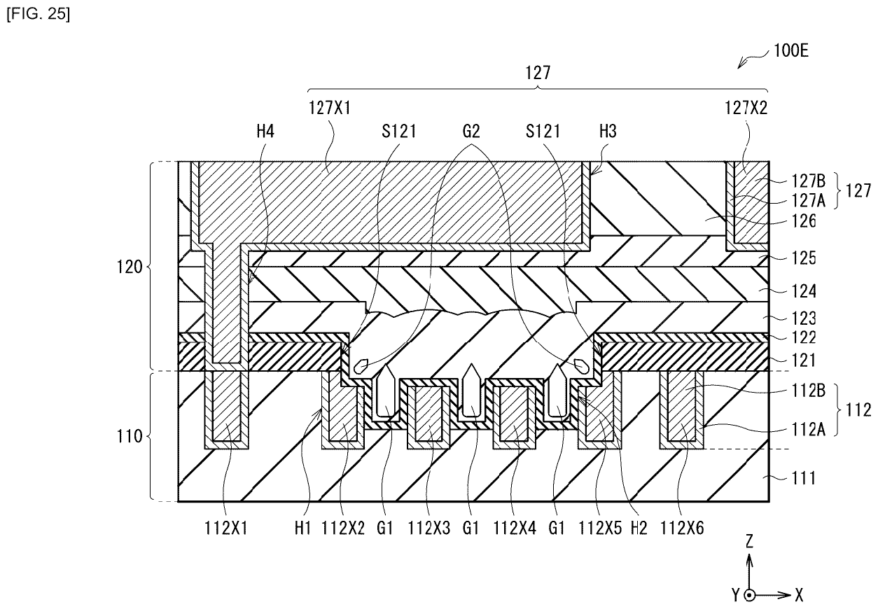

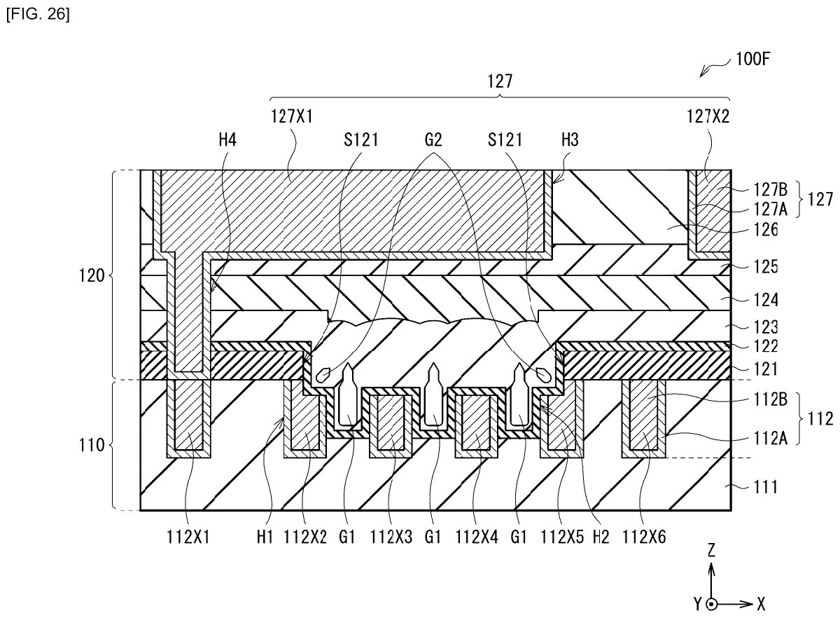

In addition thereto, for example, in a case where the flow rate of an O₂ gas upon film formation of carbon-containing silicon oxide (SiOC) is increased and the flow rate ratio between an OMCTS gas and the 02 gas is changed from about 20:1 to about 3:1 (changed into a composition close to that of an oxide film) to form the insulating film 123, the air gap G1 becomes planar in the lower shape facing the bottom surface of the opening H2, for example, as in a wiring structure 100F illustrated in FIG. 25. In addition, in a case where the insulating film 123 is formed using an Si-rich oxide film such as an SiH₄ gas, the air gap G1 is shaped like a gourd under the influence of step coverage of the insulating film 122, as in a wiring structure 100G illustrated in FIG. 26.

### (2-4. Modification Example 4)

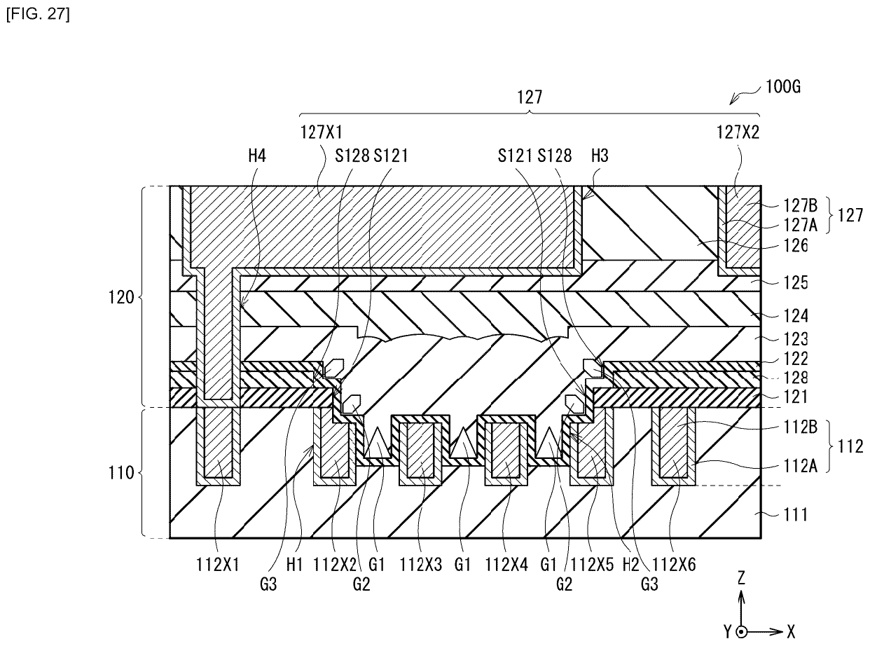

FIG. 27 schematically illustrates an example of a cross-sectional configuration of a wiring structure (wiring structure 100G) according to a modification example (Modification Example 4) of the present disclosure in the vertical direction. The wiring structure 100G of the present modification example differs from the embodiment in that the barrier film 121 and a barrier film 128 are stacked on the wiring layer 112, and an air gap G3 is further formed near an edge surface S128 of the barrier film 128. The barrier film 128 corresponds to a specific example of a “second barrier film” of the present disclosure.

The barrier film 128 is to prevent diffusion of copper (Cu) and infiltration of moisture in a case where the wiring line 112X1 to the wiring line 112X6 are formed using, for example, copper (Cu), in the same manner as the barrier film 121. The barrier film 128 extends on the barrier film 121 except a portion thereof. Specifically, the barrier film 128 extends on the barrier film 121, and has the edge surface S128, for example, outside the edge surface S121 of the barrier film 121. Examples of a material of the barrier film 128 include silicon oxide (SiOₓ), silicon nitride (SiNₓ), SiC_{X}N_{y}, silicon carbide (SiC), silicon oxynitride (SiON, SiNO), aluminum oxynitride (AlNO), and aluminum nitride (AlN), and a material having an etching rate different from that of the barrier film 121 is selected.

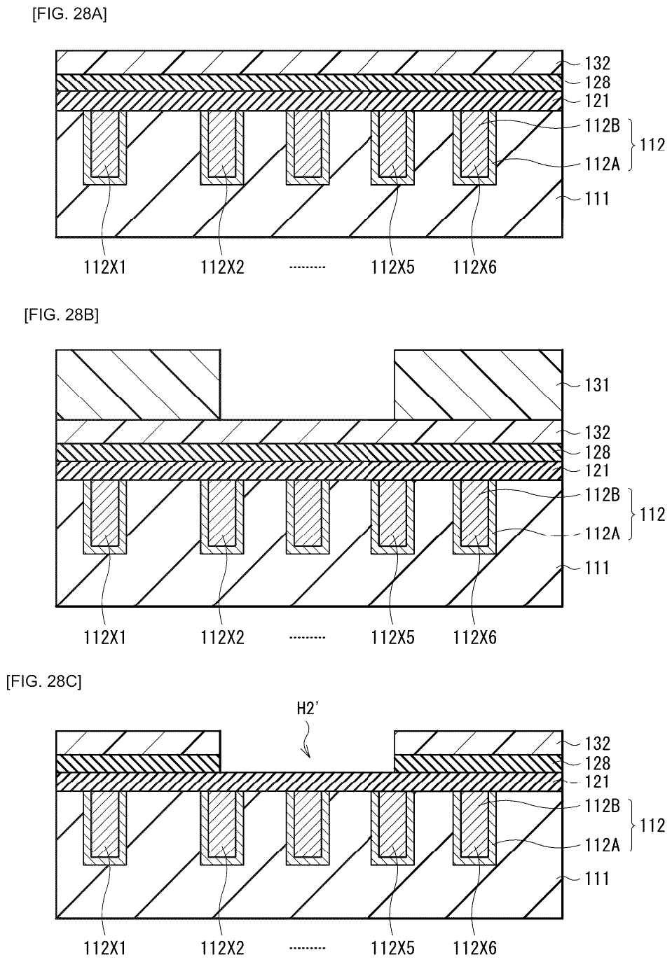

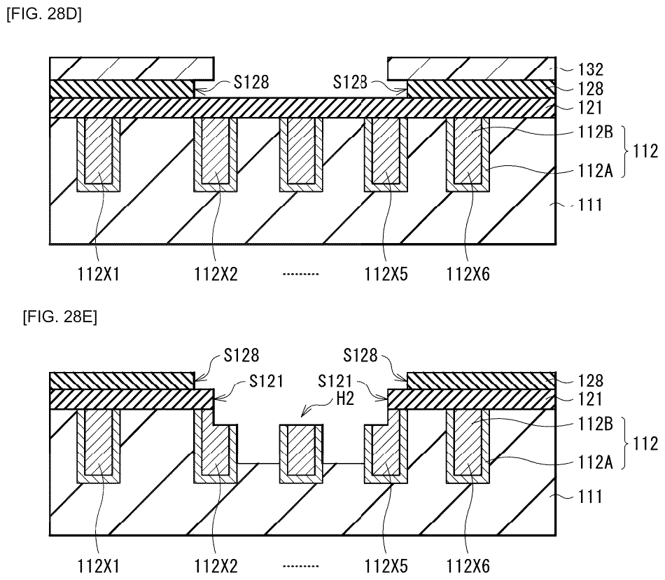

FIGS. 28A to 28E each illustrate an example of a manufacturing step of the wiring structure 100G illustrated in FIG. 27.

First, components up to the first layer 110 are formed in the same manner as the foregoing embodiment, and thereafter, as illustrated in FIG. 28A, the barrier film 121 is formed to have a thickness of, for example, 50 nm to 150 nm on the first layer 110 using, for example, a PVD method or a CVD method. Next, the barrier film 128 is formed to have a thickness of, for example, 100 nm to 200 nm on the barrier film 121 using, for example, a PVD method or a CVD method. Further, for example, a silicon nitride film is formed, as a protective film 132, to have a thickness of, for example, 50 nm to 100 nm. It is to be noted that, in the present modification example, the barrier film 121 may be formed using tantalum (Ta), tantalum nitride (TaN), titanium (Ti), titanium nitride (TiN), or the like. Subsequently, as illustrated in FIG. 28B, the resist film 131 having an opening at a position corresponding to the wiring line 121X2 to the wiring line 112X5 is patterned on the protective film 132 using a photolithography technique.

Next, as illustrated in FIG. 28C, the protective film 132 and the barrier film 128 exposed from the resist film 131 are dry-etched, for example, to form an opening H2′, and then the resist film 131 is removed. Subsequently, as illustrated in FIG. 28D, the edge surface S128 of the barrier film 128 exposed by, for example, dry etching or wet etching is retracted by, for example, about 30 nm to about 50 nm. The barrier film 128 can be isotropically etched by dry etching using a fluorine-based gas, for example.

Next, as illustrated in FIG. 28E, the barrier film 121, a portion of the wiring line 112X2 to the wiring line 112X5, and the insulating film 111 are dry-etched, for example, to form the opening H2. At this time, the protective film 132 is also etched together with the barrier film 121 or the like, and removed.

Thereafter, in the same manner as the embodiment, or the like, the insulating film 122 to coat the top surfaces of the barrier films 121 and 128 and the side surface and the bottom surface of the opening H2 is formed using, for example, a CVD method, and then the insulating film 123 having a film thickness of, for example, 100 nm to 500 nm including, for example, SiOC or silicon nitride is formed using, for example, a CVD method. This allows the opening H2 to be closed, and allows for formation of the air gaps G1, G2, and G3 at respective locations between the wiring line 112X2 and the wiring line 112X3, between the wiring line 112X3 and the wiring line 112X4 and between the wiring line 112X4 and the wiring line 112V5, above the wiring line 112X2 and the wiring line 112X5 and near the edge surfaces S121 of the barrier film 121, and near the edge surfaces S128 of the barrier film 128.

In this manner, in the present modification example, for example, the barrier film includes stacked films (barrier films 121 and 128), and the barrier film 121 and the barrier film 128 are further provided with step differences. Thus, for example, when forming the insulating film 123 using a method of forming a film having lower step coverage, such as a CVD method, the insulating film 123 is unable to follow the step differences by the barrier film 121 and the barrier film 128, thus allowing for formation of the air gaps G2 and G3 at respective locations near the edge surface S121 of the barrier film 121 and the edge surface S128 of the barrier film 128. It is therefore possible for the wiring structure 100G of the present modification example to further reduce wiring capacitance between and near the wiring lines, as compared with the wiring structure 100 of the foregoing embodiment.

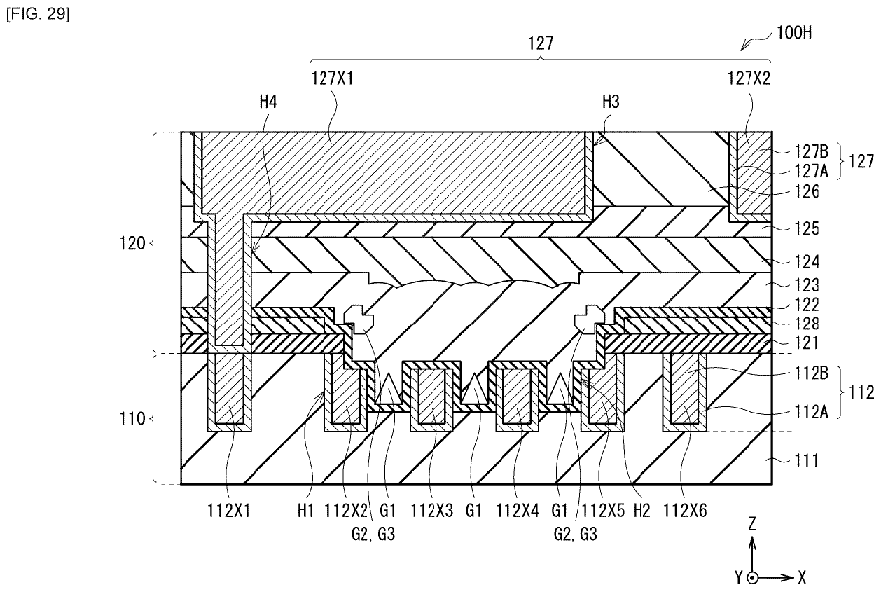

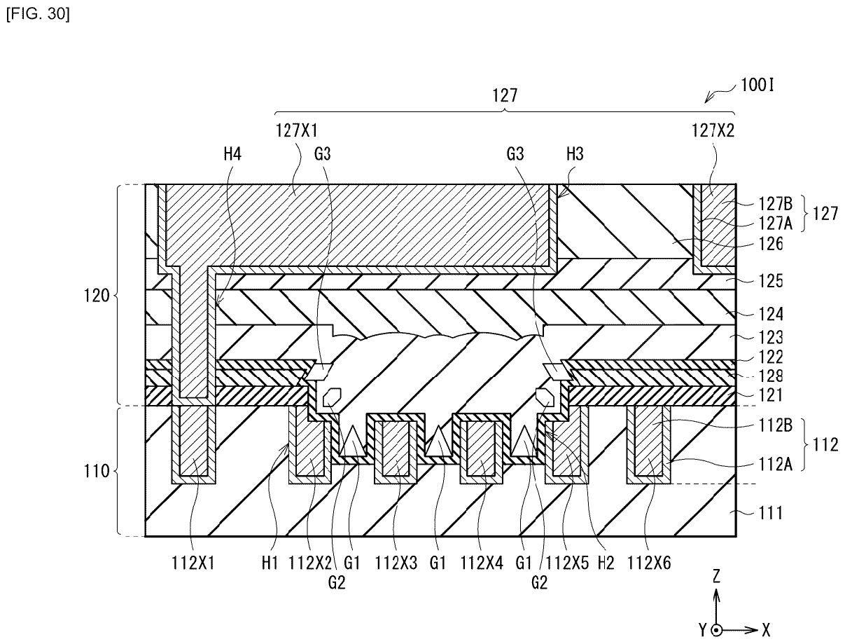

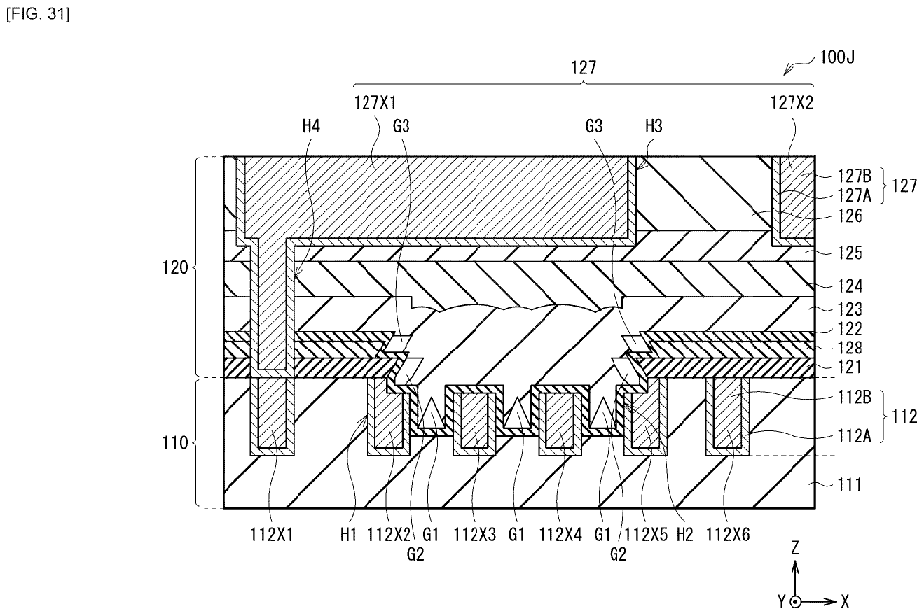

In addition, FIG. 27 exemplifies the formation of the air gaps G2 and G3, which are independent of each other, at respective locations near the edge surface S121 of the barrier film 121 and the edge surface S128 of the barrier film 128. However, the air gaps G2 and G3 may be integrated as in a wiring structure 10H illustrated in FIG. 29, for example. Further, as in a wiring structure 10I illustrated in FIG. 30, for example, the edge surface S128 of the barrier film 28 may have a reverse tapered shape as mentioned in Modification Example 2 described above. Alternatively, as in a wiring structure 10J illustrated in FIG. 31, the edge surfaces S121 and S128 of the barrier films 121 and 128 may have a reverse tapered shape. This enables formation of the air gaps G2 and G3 which are larger.

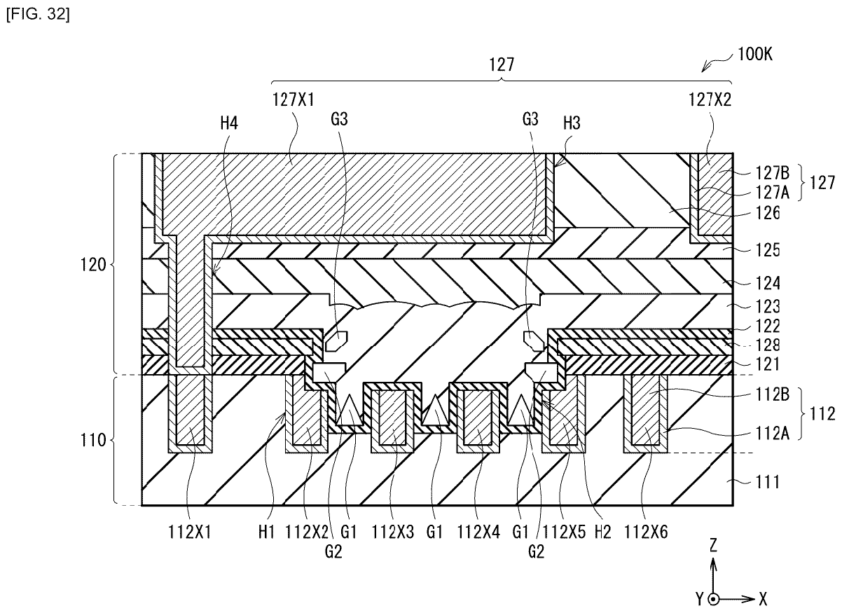

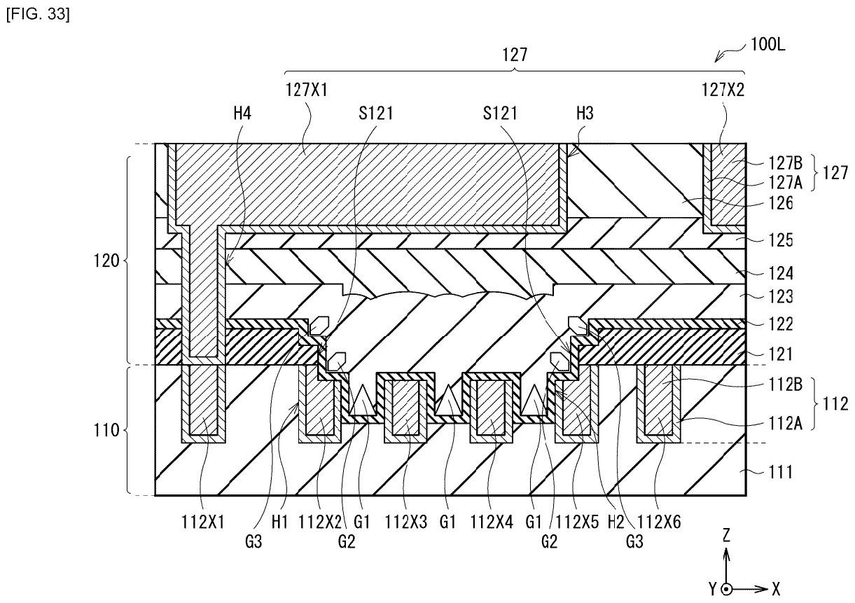

Furthermore, as in a wiring structure 10K illustrated in FIG. 32, for example, the barrier film 121 may be more retracted than the barrier film 128. In addition, the present modification example exemplifies a step difference provided by stacking the barrier film 121 and the barrier film 128. However, as in a wiring structure 10L illustrated in FIG. 33, for example, a step difference may be provided on the edge surface S121 using a single layer of the barrier film 121.

### 2-5. Modification Example 5

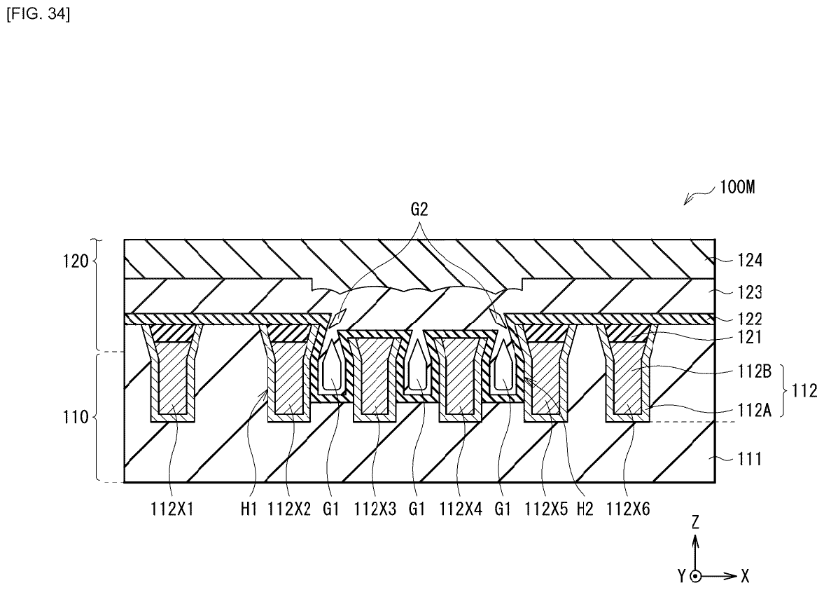

FIG. 34 schematically illustrating an example of a cross-sectional configuration of a wiring structure (a wiring structure 100M) according to a modification example (Modification Example 5) of the present disclosure in the vertical direction. The foregoing embodiment and Modification Examples 1 to 4 exemplify the formation of the barrier film 121 using an insulating material, but this is not limitative. For example, the barrier film 121 may be formed using a metal material for each of a plurality of wiring lines extending in the Y-axis direction.

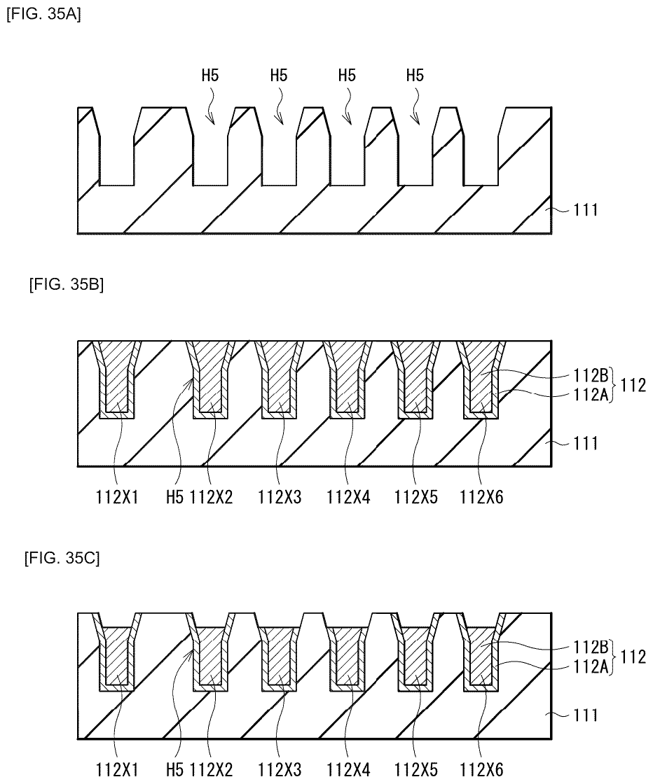

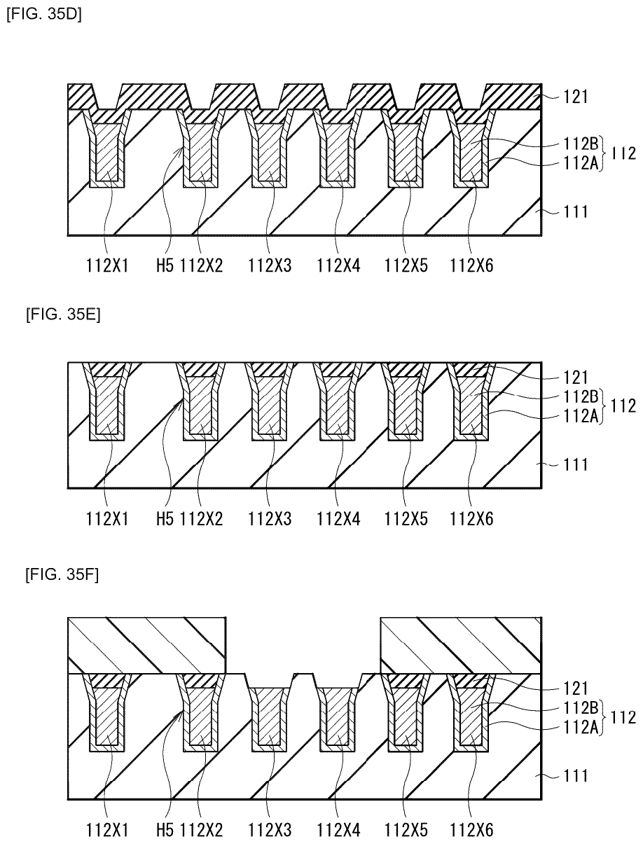

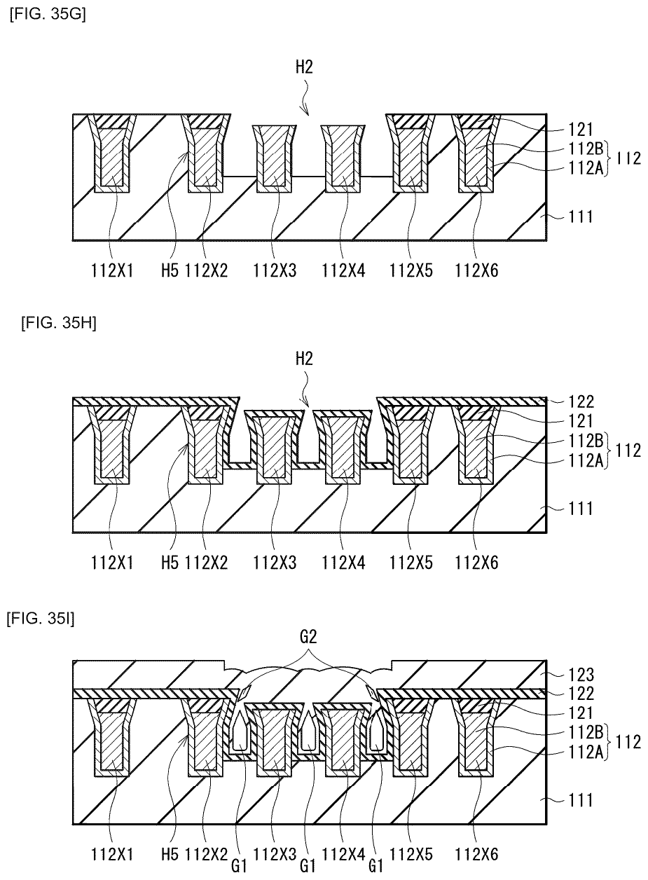

FIGS. 35A to 35I each illustrate an example of a manufacturing step of the wiring structure 100M illustrated in FIG. 34.

First, openings H5 each having an expanded upper part are formed in the insulating film 111. As for the openings H5, for example, the openings H1 having a uniform width are formed, and then an upper part of each opening H1 can be expanded as illustrated in FIG. 35A, for example, by etching using an oxygen (O₂) gas. Subsequently, for example, as illustrated in FIG. 35B, the barrier metal 112A is formed on side surfaces and bottom surfaces of the openings H5, and then the metal film 112B is formed. Thereafter, a surface thereof is polished using a CMP method, for example, to form the wiring layer 112 embedded and formed in the insulating film 111.

Next, as illustrated in FIG. 35C, the metal film 112B is retracted by, for example, about 10 nm to about 50 nm, using wet etching, for example. Subsequently, as illustrated in FIG. 35D, the barrier film 121 is formed to have a thickness of, for example, 10 nm to 50 nm on the wiring layer 112 using a CVD method, for example. Here, examples of a material of the barrier film 121 include metal materials such as tantalum (Ta), tantalum nitride (TaN), titanium (Ti), and titanium nitride (TiN).

Next, as illustrated in FIG. 35E, the barrier film 121 provided on the insulating film 111 is removed using a CMP method, for example, to planarize a surface thereof. Subsequently, as illustrated in FIG. 35F, the resist film 131 having an opening at a position corresponding to the wiring line 121X2 to the wiring line 112X5 is patterned using a photolithography technique. Subsequently, as illustrated in FIGS. 35F and 35G, the barrier film 121 and the insulating film 111 exposed from the resist film 131 are sequentially worked by, for example, dry etching or wet etching to form the opening H2.

Next, after removal of the resist film 131, the insulating film 122 to coat the top of the barrier film 121 and the side surface and the bottom surface of the opening H2 is formed to have a thickness of, for example, 5 nm to 50 nm using, for example, a CVD method, as illustrated in FIG. 35H. Subsequently, as illustrated in FIG. 35I, the insulating film 123 having a film thickness of, for example, 100 nm to 500 nm including, for example, SiOC or silicon nitride is formed using, for example, a CVD method. This allows the opening H2 to be closed, and allows for formation of the air gaps G1 and G2 at respective locations between the wiring line 112X2 and the wiring line 112X3, between the wiring line 112X3 and the wiring line 112X4 and between the wiring line 112X4 and the wiring line 112V5, and above the wiring line 112X2 and the wiring line 112X5 and near the edge surfaces S121 of the barrier film 121.

Thereafter, the insulating films 124, 125, and 126 and the electrically-conductive film 127 are sequentially formed in the same manner as the foregoing embodiment. The above-described steps allow the wiring structure 100M illustrated in FIG. 34 to be completed.

As described above, also in a case where the barrier film 121 is formed using a metal material, it is possible to form the air gaps G1 and G2, for example, at respective locations between the plurality of wiring lines extending in the Y-axis direction (e.g., between the wiring line 112X2 and the wiring line 112X3 adjacent to each other, between the wiring line 112X3 and the wiring line 112X4 adjacent to each other, and between the wiring line 112X4 and the wiring line 112X5 adjacent to each other), and near the edge surfaces of the barrier film 121 formed above the wiring line 112X2 and the wiring line 112X5. This makes it possible to achieve effects similar to those of the foregoing embodiment.

In addition, also in the present modification example, the size of the air gap G2 can be controlled by adjusting the thickness of the barrier film 121 or changing the shape of the end thereof.

### 2-6. Modification Example 6

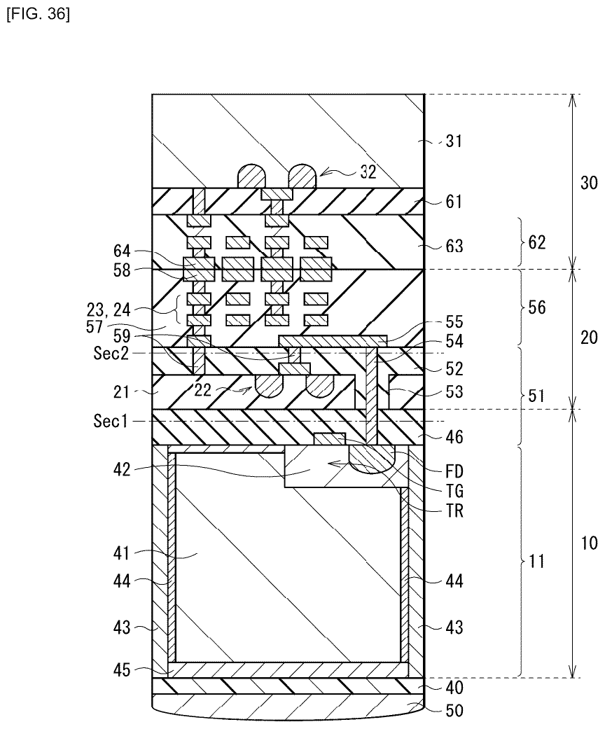

FIG. 36 illustrates an example of a cross-sectional configuration of an imaging element (imaging element 1) according to a modification example (Modification Example 6) of the foregoing embodiment in the vertical direction. In the present modification example, the transfer transistor TR includes a planar transfer gate TG. Therefore, the transfer gate TG does not penetrate the p-well layer 42, and is formed only on the front surface of the semiconductor substrate 11. Even in a case where the planar transfer gate TG is used for the transfer transistor TR, the imaging element 1 has effects similar to those of the foregoing embodiment.

### 2-7. Modification Example 7

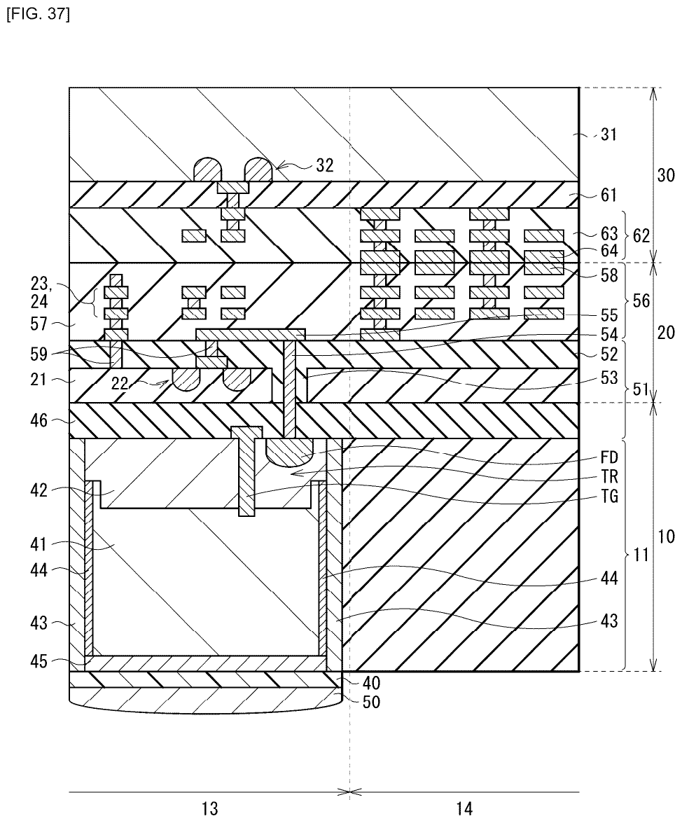

FIG. 37 illustrates an example of a cross-sectional configuration of an imaging element (imaging element 1) according to a modification example (Modification Example 7) of the foregoing embodiment in the vertical direction. In the present modification example, electric coupling between the second substrate 20 and the third substrate 30 is made in a region facing a peripheral region 14 in the first substrate 10. The peripheral region 14 corresponds to a frame region of the first substrate 10, and is provided on the periphery of the pixel region 13. In the present modification example, the second substrate 20 includes the plurality of pad electrodes 58 in the region facing the peripheral region 14, and the third substrate 30 includes the plurality of pad electrodes 64 in the region facing the peripheral region 14. The second substrate 20 and the third substrate 30 are electrically coupled to each other by bondings between the pad electrodes 58 and 64 provided in the region facing the peripheral region 14.

In this manner, in the present modification example, the second substrate 20 and the third substrate 30 are electrically coupled to each other by the bondings between the pad electrodes 58 and 64 provided in the region facing the peripheral region 14. This makes it possible to reduce the possibility of inhibiting the miniaturization of an area per pixel, as compared with the case of bonding the pad electrodes 58 and 64 to each other in a region facing the pixel region 13. Thus, in addition to the effects of the foregoing embodiment, it is possible to provide the imaging element 1 having a three-layered structure that does not inhibit the miniaturization of an area per pixel, while having a chip size equivalent to an existing chip size.

### 2-8. Modification Example 8

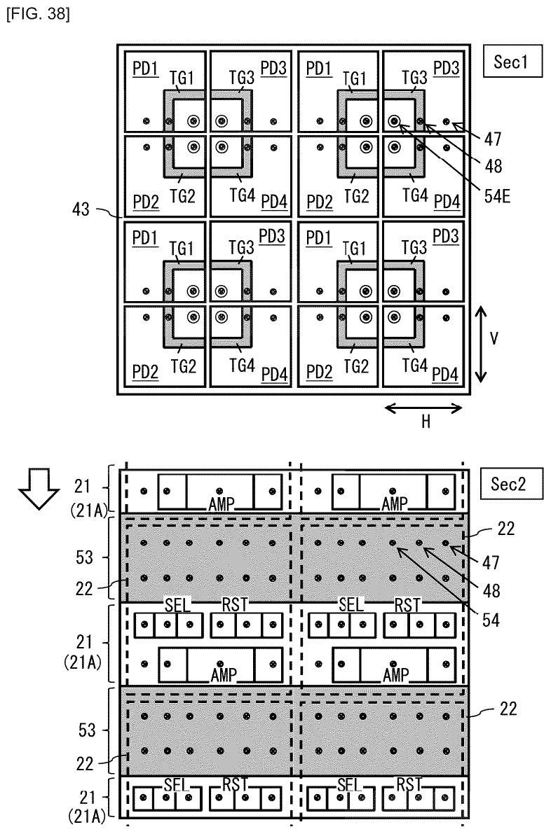

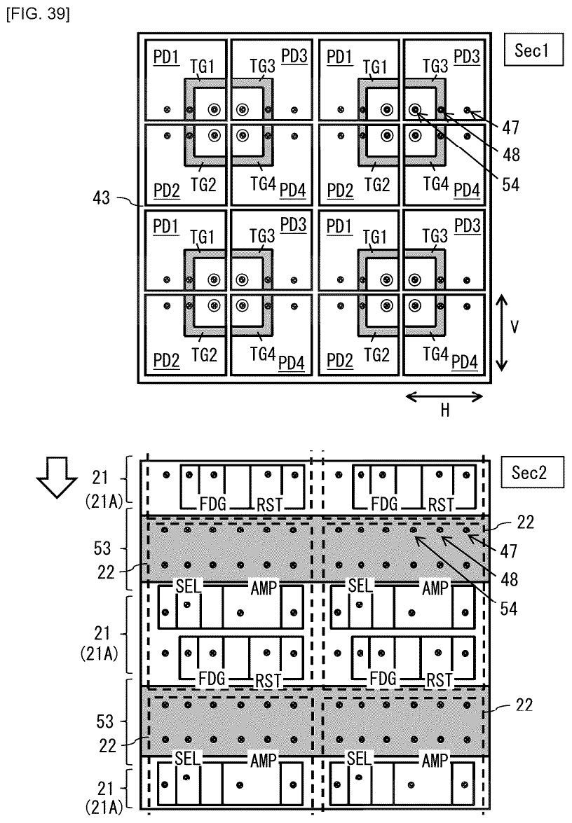

FIG. 38 illustrates an example of a cross-sectional configuration of an imaging element (imaging element 1) according to a modification example (Modification Example 8) of the foregoing embodiment in the vertical direction. FIG. 39 illustrates another example of the cross-sectional configuration of the imaging element (imaging element 1) according to the modification example (Modification Example 8) of the foregoing embodiment in the vertical direction. Each diagram on upper sides of FIGS. 38 and 39 is a modification example of the cross-sectional configuration along the cross-section Sec1 in FIG. 1, and a diagram on a lower side in FIG. 38 is a modification example of the cross-sectional configuration along the cross-section Sec2 in FIG. 1. It is to be noted that, in each cross-sectional view on the upper side of FIGS. 38 and 39, a diagram illustrating a modification example of the front surface configuration of the semiconductor substrate 11 in FIG. 1 is superimposed on the diagram illustrating the modification example of the cross-sectional configuration along the cross-section Sec1 in FIG. 1, with the insulating layer 46 being omitted. In addition, in each cross-sectional view on the lower side of FIGS. 38 and 39, a diagram illustrating a modification example of the front surface configuration of the semiconductor substrate 21 is superimposed on the diagram illustrating the modification example of the cross-sectional configuration along the cross-section Sec2 in FIG. 1.

As illustrated in FIGS. 38 and 39, the plurality of through-wiring lines 54, the plurality of through-wiring lines 48, and the plurality of through-wiring lines 47 (a plurality of dots arranged in matrix in the drawing) are arranged side by side in a strip shape in the first direction V (horizontal direction in FIGS. 38 and 39) in a plane of the first substrate 10. It is to be noted that FIGS. 38 and 39 each exemplify the case where the plurality of through-wiring lines 54, the plurality of through-wiring lines 48, and the plurality of through-wiring lines 47 are arranged side by side in two rows in the first direction V. In the four sensor pixels 12 sharing the readout circuit 22, four floating diffusions FD are arranged close to each other with the element separation section 43 interposed therebetween, for example. In the four sensor pixels 12 sharing the readout circuit 22, the four transfer gates TG (TG1, TG2, TG3, and TG4) are arranged to surround the four floating diffusions FD, and the four transfer gates TG form an annular shape, for example.

The insulating layer 53 is configured by a plurality of blocks extending in the first direction V. The semiconductor substrate 21 extends in the first direction V, and is configured by the plurality of island-shaped blocks 21A arranged side by side in the second direction H orthogonal to the first direction V, with the insulating layer 53 interposed therebetween. Each block 21A includes, for example, the reset transistor RST, the amplification transistor AMP, and the selection transistor SEL. One readout circuit 22 shared by the four sensor pixels 12 is not arranged to squarely face the four sensor pixels 12, for example, and is arranged to be shifted in the second direction H.

In FIG. 38, the one readout circuit 22 shared by the four sensor pixels 12 is configured by the reset transistor RST, the amplification transistor AMP, and the selection transistor SEL, which are inside a region, of the second substrate 20, shifted in the second direction H from the region facing the four sensor pixels 12. The one readout circuit 22 shared by the four sensor pixels 12 is configured by, for example, the amplification transistor AMP, the reset transistor RST, and the selection transistor SEL inside one block 21A.

In FIG. 39, the one readout circuit 22 shared by the four sensor pixels 12 is configured by the reset transistor RST, the amplification transistor AMP, the selection transistor SEL, and the FD transfer transistor FDG, which are inside a region, of the second substrate 20, shifted in the second direction H from the region facing the four sensor pixels 12. The one readout circuit 22 shared by the four sensor pixels 12 is configured by, for example, the amplification transistor AMP, the reset transistor RST, the selection transistor SEL, and the FD transfer transistor FDG inside the one block 21A.

In the present modification example, the one readout circuit 22 shared by the four sensor pixels 12 is not arranged to squarely face the four sensor pixels 12, for example, and is arranged to be shifted in the second direction H from a position squarely facing the four sensor pixels 12. In such a case, it may be possible to shorten the wiring line 25, or it may be possible to omit the wiring line 25 and to configure a source of the amplification transistor AMP and a drain of the selection transistor SEL using an impurity region in common. As a result, it is possible to reduce a size of the readout circuit 22 or to increase a size of another location inside the readout circuit 22.

### 2-9. Modification Example 9

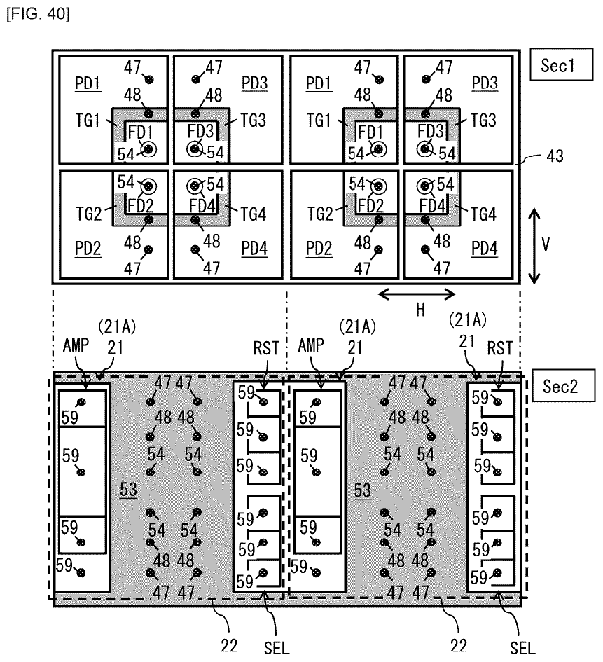

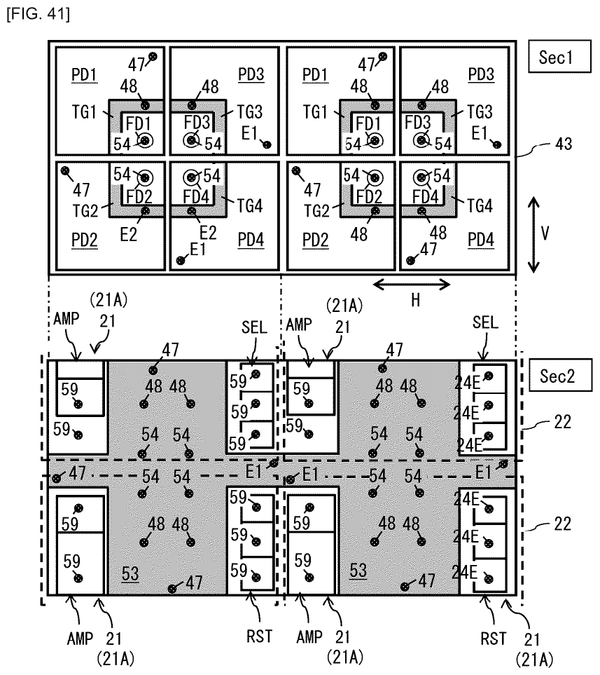

FIG. 40 illustrates an example of a cross-sectional configuration of an imaging element (imaging element 1) according to a modification example (Modification Example 9) of the foregoing embodiment in the horizontal direction. FIG. 40 illustrates a modification example of the cross-sectional configuration in FIG. 15.

In the present modification example, the semiconductor substrate 21 is configured by the plurality of island-shaped blocks 21A arranged side by side in the first direction V and the second direction H, with the insulating layer 53 interposed therebetween. Each block 21A includes, for example, a set of the reset transistor RST, the amplification transistor AMP, and the selection transistor SEL. In such a case, it is possible to cause the insulating layer 53 to suppress a crosstalk between the readout circuits 22 adjacent to each other, thus making it possible to suppress image quality degradation due to a decrease in resolution and color mixture on a reproduced image.

### 2-10. Modification Example 10

FIG. 41 illustrates an example of a cross-sectional configuration of an imaging element (imaging element 1) according to a modification example (Modification Example 10) of the foregoing embodiment in the horizontal direction. FIG. 41 illustrates a modification example of the cross-sectional configuration in FIG. 40.

In the present modification example, the one readout circuit 22 shared by the four sensor pixels 12 is not arranged to squarely face the four sensor pixels 12, for example, and is arranged to be shifted in the first direction V. In the present modification example, in the same manner as Modification Example 9, the semiconductor substrate 21 is further configured by the plurality of island-shaped blocks 21A arranged side by side in the first direction V and the second direction H, with the insulating layer 53 interposed therebetween. Each block 21A includes, for example, a set of the reset transistor RST, the amplification transistor AMP, and the selection transistor SEL. In the present modification example, the plurality of through-wiring lines 47 and the plurality of through-wiring lines 54 are further arranged also in the second direction H. Specifically, the plurality of through-wiring lines 47 is disposed between the four through-wiring lines 54 sharing a certain readout circuit 22 and the four through-wiring lines 54 sharing another readout circuit 22 adjacent to the certain readout circuit 22 in the second direction H. In such a case, it is possible to cause the insulating layer 53 and the through-wiring line 47 to suppress a crosstalk between the readout circuits 22 adjacent to each other, thus making it possible to suppress image quality degradation due to a decrease in resolution and color mixture on a reproduced image.

### 2-11. Modification Example 11

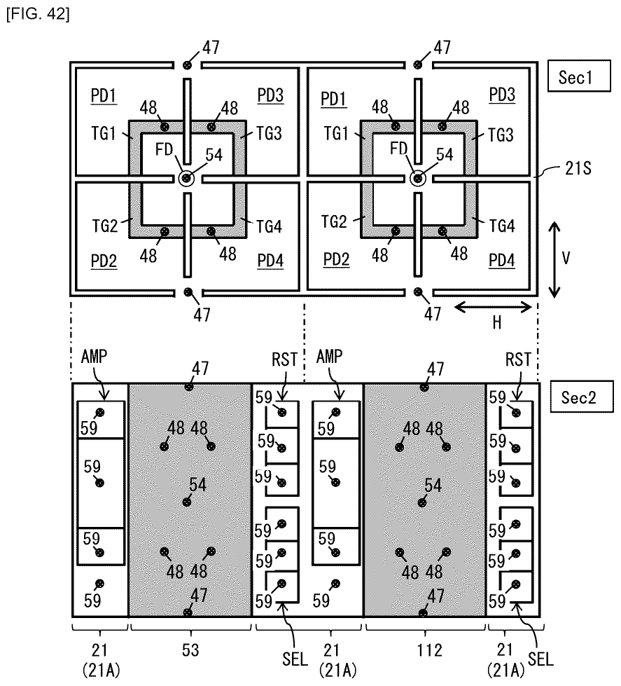

FIG. 42 illustrates an example of a cross-sectional configuration of an imaging element (imaging element 11) according to a modification example (Modification Example 11) of the foregoing embodiment in the horizontal direction. FIG. 42 illustrates a modification example of the cross-sectional configuration in FIG. 13.

In the present modification example, the first substrate 10 includes the photodiode PD and the transfer transistor TR for each sensor pixel 12, and includes the floating diffusion FD shared by every four sensor pixels 12. Accordingly, in the present modification example, one through-wiring line 54 is provided for every four sensor pixels 12.

In the plurality of sensor pixels 12 arranged in matrix, four sensor pixels 12 corresponding to a region, which is obtained by shifting a unit region corresponding to four sensor pixels 12 sharing one floating diffusion FD by one sensor pixel 12 in the first direction V, is referred to as four sensor pixels 12A, for the sake of convenience. At this time, in the present modification example, the first substrate 10 includes the through-wiring line 47 shared by every four sensor pixels 12A. Accordingly, in the present modification example, one through-wiring line 47 is provided for every four sensor pixels 12A.

In the present modification example, the first substrate 10 includes the element separation section 43 that separates the photodiodes PD and the transfer transistors TR for the respective sensor pixels 12. When viewed from the normal direction of the semiconductor substrate 11, the element separation section 43 does not completely surround the sensor pixel 12, and has a gap (unformed region) near the floating diffusion FD (through-wiring line 54) and near the through-wiring line 47. In addition, the gap enables sharing of the one through-wiring line 54 by the four sensor pixels 12 as well as sharing of the one through-wiring line 47 by the four sensor pixels 12A. In the present modification example, the second substrate 20 includes the readout circuit 22 for every four sensor pixels 12 sharing the floating diffusion FD.

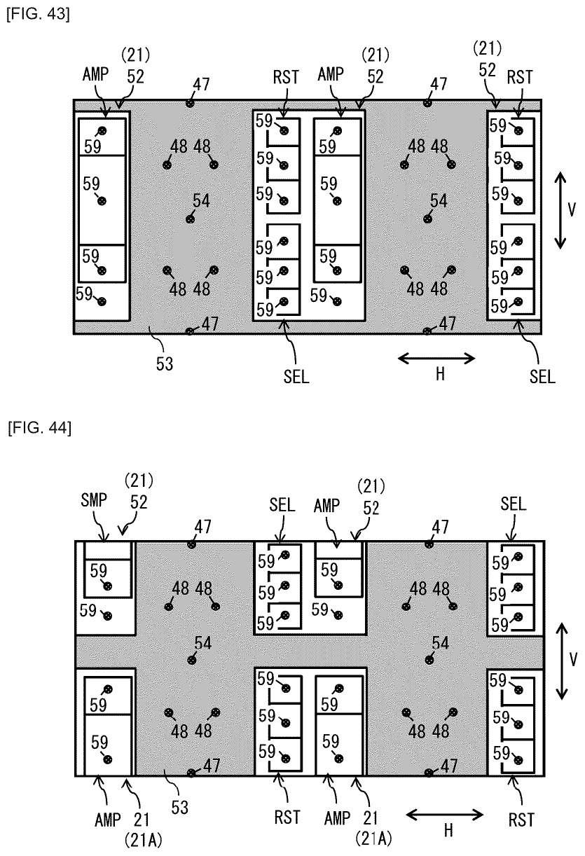

FIG. 43 illustrates another example of the cross-sectional configuration of the imaging element 1 according to the present modification example in the horizontal direction. FIG. 43 illustrates a modification example of the cross-sectional configuration in FIG. 40. In the present modification example, the first substrate 10 includes the photodiode PD and the transfer transistor TR for each sensor pixel 12, and includes the floating diffusion FD shared by every four sensor pixels 12. Further, the first substrate 10 includes the element separation section 43 that separates the photodiodes PD and the transfer transistors TR for the respective sensor pixels 12.

FIG. 44 illustrates another example of the cross-sectional configuration of the imaging element 1 according to the present modification example in the horizontal direction. FIG. 44 illustrates a modification example of the cross-sectional configuration in FIG. 41. In the present modification example, the first substrate 10 includes the photodiode PD and the transfer transistor TR for each sensor pixel 12, and includes the floating diffusion FD shared by every four sensor pixels 12. Further, the first substrate 10 includes the element separation section 43 that separates the photodiodes PD and the transfer transistors TR for the respective sensor pixels 12.

### 2-12. Modification Example 12

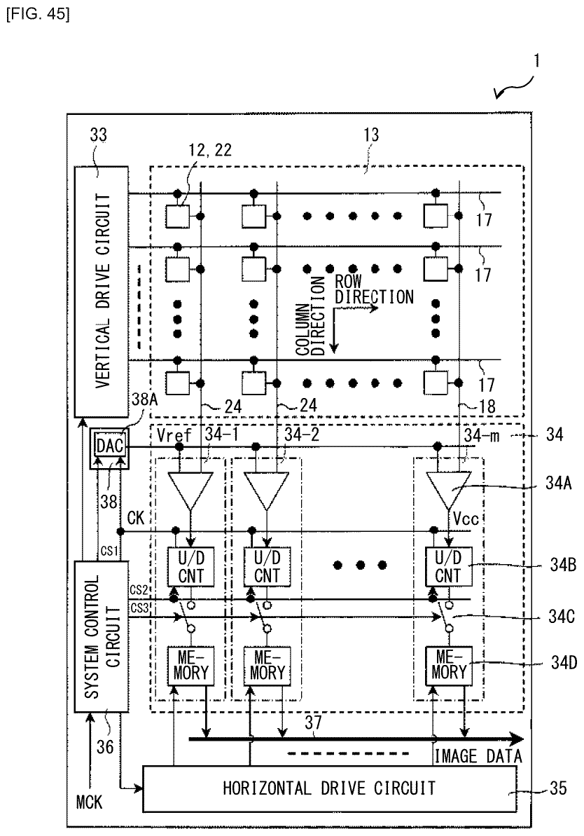

FIG. 45 illustrates an example of a circuit configuration of an imaging element (imaging element 1) according to a modification example (Modification Example 12) of the foregoing embodiment and Modification Examples 6 to 6. The imaging element 1 according to the present modification example is a CMOS image sensor mounted with a column-parallel ADC.

As illustrated in FIG. 45, the imaging element 1 according to the present modification example includes the vertical drive circuit 33, the column signal processing circuit 34, a reference voltage supply section 38, the horizontal drive circuit 35, a horizontal output line 37, and the system control circuit 36, in addition to the pixel region 13 in which the plurality of sensor pixels 12 each including a photoelectric conversion section are two-dimensionally arranged in matrix (matrix shape).

In this system configuration, on the basis of a master clock MCK, the system control circuit 36 generates a clock signal, a control signal, or the like that serves as a criterion for operation of the vertical drive circuit 33, the column signal processing circuit 34, the reference voltage supply section 38, the horizontal drive circuit 35, and the like, and provides the clock signal, the control signal, or the like to the vertical drive circuit 33, the column signal processing circuit 34, the reference voltage supply section 38, the horizontal drive circuit 35, and the like.

In addition, the vertical drive circuit 33 is formed in the first substrate 10 together with each of the sensor pixels 12 of the pixel region 13, and is further formed in the second substrate 20, as well, in which the readout circuit 22 is formed. The column signal processing circuit 34, the reference voltage supply section 38, the horizontal drive circuit 35, the horizontal output line 37 and the system control circuit 36 are formed in the third substrate 30.

It may be possible to use, as the sensor pixel 12, for example, a configuration including, in addition to the photodiode PD, the transfer transistor TR that transfers electric charge obtained by photoelectric conversion at the photodiode PD to the floating diffusion FD, although illustration is omitted here. In addition, it may be possible to use, as the readout circuit 22, for example, a three-transistor configuration including the reset transistor RST that controls a potential of the floating diffusion FD, the amplification transistor AMP that outputs a signal corresponding to a potential of the floating diffusion FD, and the selection transistor SEL for selecting a pixel, although illustration is omitted here.

In the pixel region 13, the sensor pixels 12 are two-dimensionally arranged; with respect to this pixel arrangement of m-row and n-column, the pixel drive lines 23 are wired for respective rows, and the vertical signal lines 24 are wired for respective columns. Each one end of the plurality of pixel drive lines 23 is coupled to a corresponding output end of the rows of the vertical drive circuit 33. The vertical drive circuit 33 is configured by a shift register or the like, and controls row address and row scanning of the pixel region 13 via the plurality of pixel drive lines 23.

The column signal processing circuit 34 includes, for example, ADCs (analog-to-digital conversion circuits) 34-1 to 34-m provided for respective pixel columns, i.e., for the respective vertical signal lines 24 of the pixel region 13, and converts analog signals outputted for respective columns from the sensor pixels 12 of the pixel region 13 into digital signals for outputting.

The reference voltage supply section 38 includes, for example, a DAC (digital-to-analog conversion circuit) 38A as a means to generate a reference voltage Vref of a so-called ramp (RAMP) waveform having a level that changes in an inclined manner as time elapses. It is to be noted that the means to generate the reference voltage Vref of the ramp waveform is not limited to the DAC 38A.

Under the control of a control signal CS1 provided from the system control circuit 36, the DAC 38A generates the reference voltage Vref of the ramp waveform on the basis of a clock CK provided from this system control circuit 36 to supply the generated reference voltage Vref to the ADCs 34-1 to 34-m of the column signal processing circuit 34.

It is to be noted that each of the ADCs 34-1 to 34-m is configured to selectively perform an AD conversion operation corresponding to each operation mode of a normal frame rate mode in a progressive scanning system for reading information on all of the sensor pixels 12, and a high-speed frame rate mode for setting exposure time of the sensor pixel 12 to 1/N to increase a frame rate by N times, e.g., by twice, as compared with the time of the normal frame rate mode. The switching between the operation modes is executed by controls performed by control signals CS2 and CS3 provided from the system control circuit 36. In addition, instruction information for switching between the operation modes of the normal frame rate mode and the high-speed frame rate mode is provided from an external system controller (unillustrated) to the system control circuit 36.

All of the ADCs 34-1 to 34-m have the same configuration; a description is given here by referring to the example of the ADC 34-m. The ADC 34-m includes a comparator 34A, an up/down counter (referred to as U/D CNT in the drawing) 34B, e.g., as a number-counting means, a transfer switch 34C, and a memory 34D.

The comparator 34A compares a signal voltage Vx of the vertical signal line 24 corresponding to a signal outputted from each sensor pixel 12 of an n-th column of the pixel region 13 and the reference voltage Vref of the ramp waveform supplied from the reference voltage supply section 38 with each other. For example, when the reference voltage Vref is larger than the signal voltage Vx, an output Vco becomes an “H” level, whereas, when the reference voltage Vref is equal to or less than the signal voltage Vx, the output Vco becomes an “L” level.

The up/down counter 34B is an asynchronous counter; under the control of the control signal CS2 provided from the system control circuit 36, the up/down counter 34B is provided with the clock CK from the system control circuit 36 simultaneously with the DAC 18A, and performs down (DOWN)-counting or up (UP)-counting in synchronization with the clock CK to thereby measure a comparison period from the start of a comparison operation to the end of the comparison operation in the comparator 34A.

Specifically, in the normal frame rate mode, when performing a reading operation of signals from one sensor pixel 12, the down-counting is performed upon a first reading operation to thereby measure comparison time upon the first reading, whereas the up-counting is performed upon a second reading operation to measure comparison time upon the second reading.

Meanwhile, in the high-speed frame rate mode, while holding a count result for the sensor pixel 12 of a certain row as it is, the down-counting is subsequently performed for the sensor pixel 12 of the next row upon a first reading operation from the previous count result to thereby measure comparison time upon the first reading, and the up-counting is performed upon a second reading operation to thereby measure comparison time upon the second reading.

Under the control of the control signal CS3 provided from the system control circuit 36, the transfer switch 34C, in the normal frame rate mode, is brought into an ON (closed) state upon completion of the counting operation of the up/down counter 34B for the sensor pixel 12 of the certain row to transfer, to the memory 34D, the count results of the up/down counter 34B.

Meanwhile, for example, in the high-speed frame rate of N=2, an OFF (open) state remains upon completion of the counting operation of the up/down counter 34B for the sensor pixel 12 of the certain row, and subsequently an ON state is obtained upon completion of the counting operation of the up/down counter 34B for the sensor pixel 12 of the next row to transfer, to the memory 34D, the count results of the up/down counter 34B for the vertical two pixels.

In this manner, analog signals supplied for respective columns from the respective sensor pixels 12 of the pixel region 13 via the vertical signal lines 24 are converted into N-bit digital signals by respective operations of the comparators 34A and the up/down counters 34B in the ADCs 34-1 to 34-m, and are stored in the memories 34D.

The horizontal drive circuit 35 is configured by a shift register or the like, and controls column address and column scanning of the ADCs 34-1 to 34-m in the column signal processing circuit 34. Under the control of the horizontal drive circuit 35, the N-bit digital signals having been subjected to the AD conversion in the respective ADCs 34-1 to 34-m are read to the horizontal output line 37 in order, and are outputted as imaging data via the horizontal output line 37.

It is to be noted that it may also be possible to provide, in addition to the above-described components, a circuit, etc. that performs various types of signal processing on the imaging data outputted via the horizontal output line 37, although no particular illustration is given because there is no direct relationship with the present disclosure.

In the imaging element 1 mounted with the column-parallel ADC according to the present modification example having the above configuration, the count results of the up/down counter 34B are able to be selectively transferred to the memory 34D via the transfer switch 34C. This makes it possible to control the counting operation of the up/down counter 34B and the reading operation of the count results of the up/down counter 34B to the horizontal output line 37 independently of each other.

### 2-13. Modification Example 13

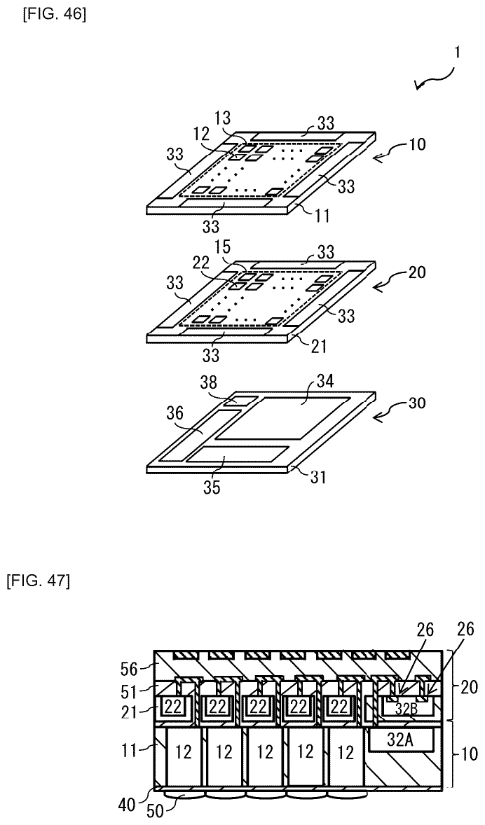

FIG. 46 illustrates an example of a configuration of the imaging element in FIG. 45, in which the three substrates (first substrate 10, second substrate 20, and third substrate 30) are stacked. In the present modification example, the first substrate 10 has a middle part where the pixel region 13 including the plurality of sensor pixels 12 is formed, with the vertical drive circuit 33 being formed around the pixel region 13. In addition, the second substrate 20 has a middle part where a readout circuit region 15 including the plurality of readout circuits 22 is formed, with the vertical drive circuit 33 being formed around the readout circuit region 15. In the third substrate 30, the column signal processing circuit 34, the horizontal drive circuit 35, the system control circuit 36, the horizontal output line 37, and the reference voltage supply section 38 are formed. This eliminates an increase in a chip size and inhibition of miniaturization of an area per pixel due to the structure of electrically coupling substrates to each other, in the same manner as the foregoing embodiment and modification examples thereof. As a result, it is possible to provide the imaging element 1 having a three-layered structure not inhibiting the miniaturization of an area per pixel, while having a chip size equivalent to an existing chip size. It is to be noted that the vertical drive circuit 33 may be formed only in the first substrate 10 or may be formed only in the second substrate 20.

### 2-14. Modification Example 14

FIG. 47 illustrates an example of a cross-sectional configuration of an imaging element (imaging element 1) according to a modification example (Modification Example 14) of the foregoing embodiment and Modification Examples 6 to 12 thereof. In the foregoing embodiment and Modification Examples 6 to 12 thereof, etc., the imaging element 1 is configured by stacking the three substrates (first substrate 10, second substrate 20, and third substrate 30). However, as in the imaging elements 5 and 6 in the foregoing fifth embodiment, two substrates (first substrate 10 and second substrate 20) may be configured to be stacked. At this time, the logic circuits 32 may be formed separately in the first substrate 10 and the second substrate 20, for example, as illustrated in FIG. 47. Here, a circuit 32A, of the logic circuit 32, provided on a side of the first substrate 10 is provided with a transistor having a gate structure, in which a high permittivity film including a material (e.g., high-k) that is able to withstand a high-temperature process and a metal gate electrode are stacked. Meanwhile, in a circuit 32B provided on a side of the second substrate 20, a low-resistance region 26 is formed, which includes a silicide formed using a Salicide (Self Aligned Silicide) process such as CoSi₂ and NiSi, on a surface of an impurity diffusion region in contact with a source electrode and a drain electrode. The low-resistance region including a silicide is formed by a compound of a semiconductor substrate material and a metal. This makes it possible to use a high-temperature process such as thermal oxidation when forming the sensor pixel 12. In addition, it is possible to reduce contact resistance in a case of providing the low-resistance region 26 including a silicide on the surface of the impurity diffusion region in contact with a source electrode and a drain electrode in the circuit 32B, of the logic circuit 32, provided on the side of the second substrate 20. As a result, it is possible to increase the speed of an arithmetic operation in the logic circuit 32.

### 2-15. Modification Example 15

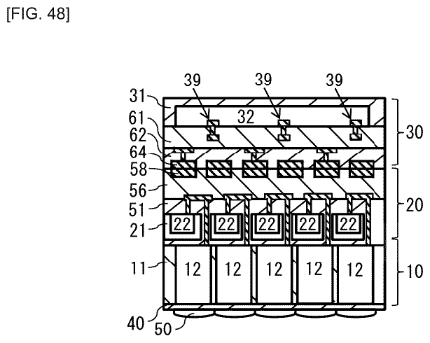

FIG. 48 illustrates a modification example of the cross-sectional configuration of the imaging element 1 according to a modification example (Modification Example 15) of the foregoing embodiment and Modification Examples 6 to 12 thereof. In the logic circuit 32 of the third substrate 30 according to the foregoing embodiment and Modification Examples 6 to 12 thereof, a low-resistance region 39 including a silicide formed by using the Salicide (Self Aligned Silicide) process such as CoSi₂ and NiSi may be formed on the surface of the impurity diffusion region in contact with the source electrode and the drain electrode. This makes it possible to use a high-temperature process such as thermal oxidation when forming the sensor pixel 12. In addition, it is possible, in the logic circuit 32, to reduce contact resistance in a case of providing the low-resistance region 39 including a silicide on the surface of the impurity diffusion region in contact with the source electrode and the drain electrode. As a result, it is possible to increase the speed of an arithmetic operation in the logic circuit 32.

It is to be noted that, in the foregoing embodiment and Modification Examples 6 to 17 thereof, the electric conductivity type may be opposite. For example, in the descriptions of the foregoing embodiment and Modification Examples 6 to 17 thereof, the p-type may be read as the n-type, and the n-type may be read as the p-type. Also in such a case, it is possible to obtain effects similar to those of the foregoing embodiment and Modification Examples 6 to 17 thereof.

### 3. Application Example

FIG. 49 illustrates an example of a schematic configuration of an imaging system 7 including the imaging element (imaging element 1) according to any of the foregoing embodiment and Modification Examples 6 to 17 thereof.

The imaging system 7 is an electronic apparatus including, for example, an imaging device such as a digital still camera or a video camera, or a portable terminal apparatus such as a smartphone or a tablet-type terminal. The imaging system 7 includes, for example, an optical system 241, a shutter device 242, the imaging element 1, a DSP circuit 243, a frame memory 244, a display unit 245, a storage unit 246, an operation unit 247, and a power supply unit 248. In the imaging system 7, the shutter device 242, the imaging element 1, the DSP circuit 243, the frame memory 244, the display unit 245, the storage unit 246, the operation unit 247, and the power supply unit 248 are coupled to one another via a bus line 249.

The imaging element 1 outputs image data corresponding to incident light. The optical system 241 includes one or a plurality of lenses, and guides light (incident light) from a subject to the imaging element 1 to form an image on a light-receiving surface of the imaging element 1. The shutter device 242 is disposed between the optical system 241 and the imaging element 1, and controls periods of light irradiation and light shielding with respect to the imaging element 1 under the control of the operation unit 247. The DSP circuit 243 is a signal processing circuit that processes a signal (image data) outputted from the imaging element 1. The frame memory 244 temporarily holds the image data processed by the DSP circuit 243 in a frame unit. The display unit 245 includes, for example, a panel-type display device such as a liquid crystal panel or an organic EL (Electro Luminescence) panel, and displays a moving image or a still image captured by the imaging element 1. The storage unit 246 records image data of a moving image or a still image captured by the imaging element 1 in a recording medium such as a semiconductor memory or a hard disk. The operation unit 247 issues an operation command for various functions of the imaging system 7 in accordance with an operation by a user. The power supply unit 248 appropriately supplies various types of power for operation to the imaging element 1, the DSP circuit 243, the frame memory 244, the display unit 245, the storage unit 246, and the operation unit 247 which are supply targets.

Next, a description is given of an imaging procedure in the imaging system 7.

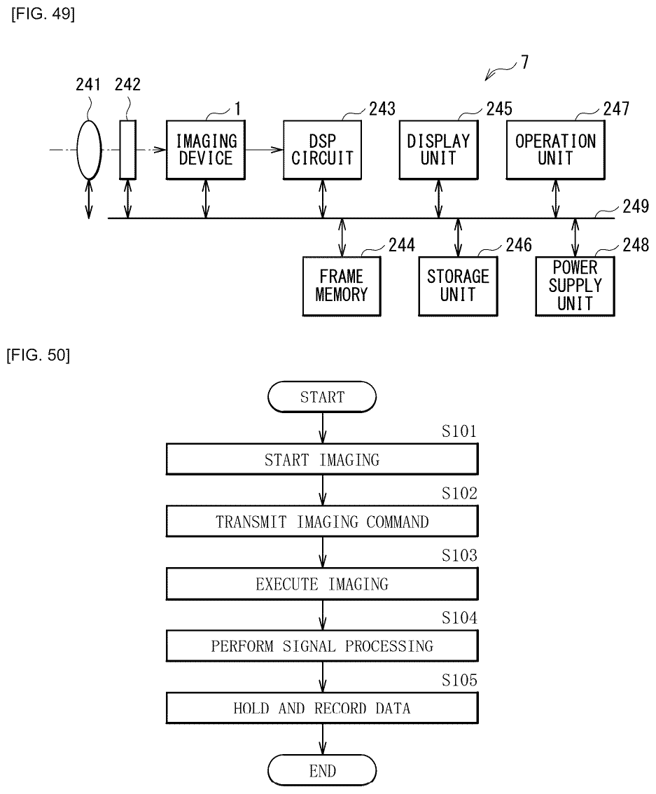

FIG. 50 illustrates an example of a flowchart of an imaging operation in the imaging system 7. A user instructs start of imaging by operating the operation unit 247 (step S101). Then, the operation unit 247 transmits an imaging command to the imaging element 1 (step S102). The imaging element 1 (specifically, the system control circuit 36) executes imaging in a predetermined imaging method upon receiving the imaging command (step S103).

The imaging element 1 outputs light (image data) formed on the light-receiving surface via the optical system 241 and the shutter device 242 to the DSP circuit 243. As used herein, the image data refers to data for all pixels of pixel signals generated on the basis of electric charge temporarily held in the floating diffusion FD. The DSP circuit 243 performs predetermined signal processing (e.g., noise reduction processing, etc.) on the basis of the image data inputted from the imaging element 1 (step S104). The DSP circuit 243 causes the frame memory 244 to hold the image data having been subjected to the predetermined signal processing, and the frame memory 244 causes the storage unit 246 to store the image data (step S105). In this manner, the imaging in the imaging system 7 is performed.

In the present application example, the imaging element 1 is applied to the imaging system 7. This enables smaller size or higher definition of the imaging element 1, thus making it possible to provide a small or high-definition imaging system 7.

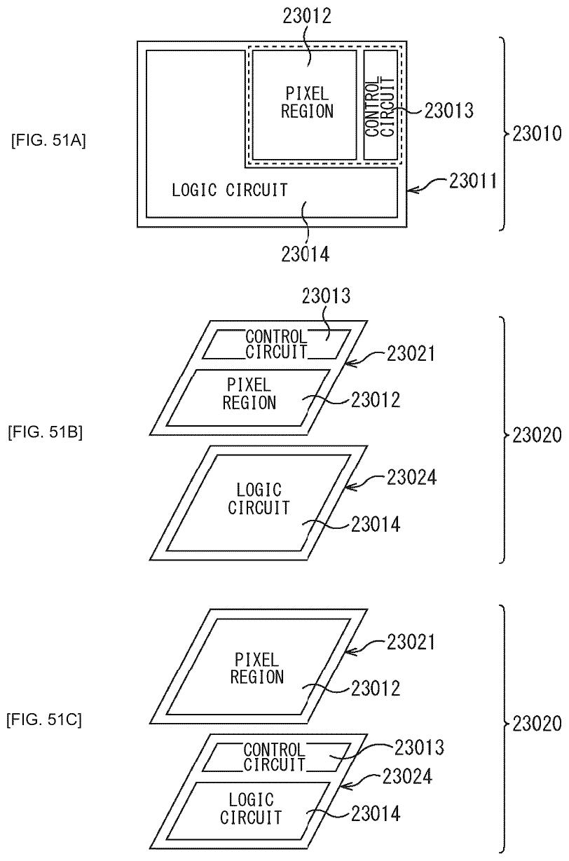

FIG. 51 is a diagram illustrating an overview of configuration examples of a non-stacked solid-state imaging element (a solid-state imaging element 23210) and a stacked solid-state imaging element (a solid-state imaging element 23020) to which the technology according to the present disclosure is applicable.

A of FIG. 51 illustrates a schematic configuration example of the non-stacked solid-state imaging element. As illustrated in A of FIG. 51, a solid-state imaging element 23010 includes one die (semiconductor substrate) 23011. The die 23011 includes a pixel region 23012 in which pixels are arranged in array, a control circuit 23013 that performs various types of control such as driving of a pixel, and a logic circuit 23014 to perform signal processing.

B and C of FIG. 51 illustrate schematic configuration examples of the stacked solid-state imaging element. As illustrated in B and C of FIG. 51, the solid-state imaging element 23020 is configured as one semiconductor chip in which two dies of a sensor die 23021 and a logic die 23024 are stacked and electrically coupled to each other. The sensor die 23021 and the logic die 23024 correspond, respectively, to specific examples of a “first substrate” and a “second substrate” of the present disclosure.

In B of FIG. 51, the sensor die 23021 is mounted with the pixel region 23012 and the control circuit 23013, and the logic die 23024 is mounted with the logic circuit 23014 including a signal processing circuit that performs signal processing. Further, a sensor die 20321 may be mounted with, for example, the above-described readout circuit 22, or the like.

In C of FIG. 51, the sensor die 23021 is mounted with the pixel region 23012, and the logic die 23024 is mounted with the control circuit 23013 and the logic circuit 23014.

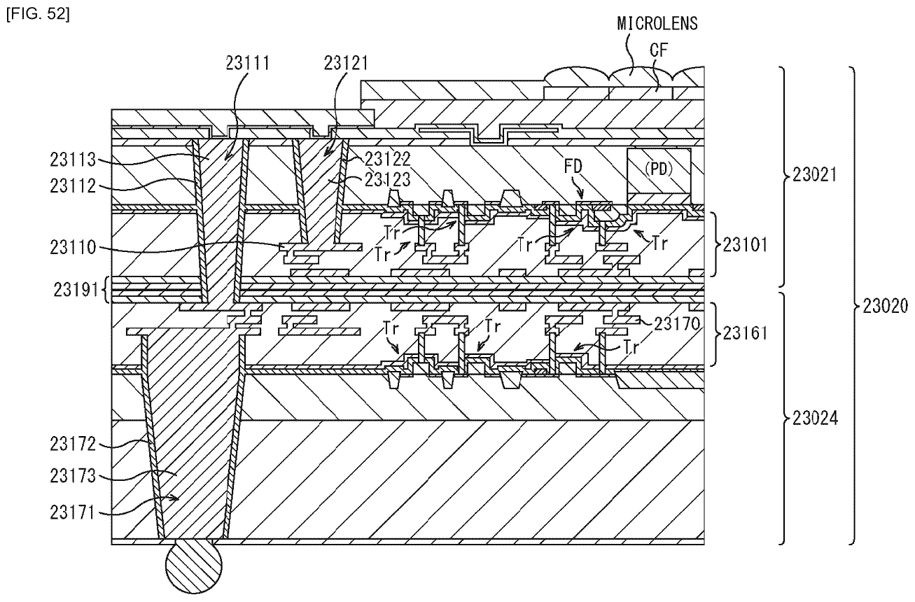

FIG. 52 is a cross-sectional view of a first configuration example of the stacked solid-state imaging element 23020.

In the sensor die 23021, there are formed a PD (photodiode) constituting a pixel serving as the pixel region 23012, an FD (floating diffusion), a Tr (MOS FET), a TR serving as the control circuit 23013, and the like. Further, in the sensor die 23021, there is formed a wiring layer 23101 including a wiring line 23110 in a plurality of layers, in this example, in three layers. It is to be noted that the control circuit 23013 (Tr serving as control circuit 23013) may be configured in the logic die 23024 instead of the sensor die 23021.

In the logic die 23024, there is formed a Tr constituting the logic circuit 23014. Further, in the logic die 23024, there is formed a wiring layer 23161 including a wiring line 23170 in a plurality of layers, in this example, in three layers. In addition, in the logic die 23024, there is formed a coupling hole 23171 with an inner wall surface on which an insulating film 23172 is formed, and a coupling conductor 23173 to be coupled to the wiring line 23170 or the like is embedded in the coupling hole 23171.

The sensor die 23021 and the logic die 23024 are attached to each other to allow the wiring layers 23101 and 23161 thereof to face each other, thereby allowing for configuration of the stacked solid-state imaging element 23020 in which the sensor die 23021 and the logic die 23024 are stacked. A film 23191 such as a protective film is formed on a surface on which the sensor die 23021 and the logic die 23024 are attached.

In the sensor die 23021, there is formed a coupling hole 23111 that penetrates the sensor die 23021 from a side of a back surface of the sensor die 23021 (a side on which light is incident on the PD) (top side) to reach the wiring line 23170 of the top layer of the logic die 23024. Further, in the sensor die 23021, there is formed a coupling hole 23121 being in proximity to the coupling hole 23111 and reaching the wiring line 23110 as the first layer from the side of the back surface of the sensor die 23021. An insulating film 23112 is formed on an inner wall surface of the coupling hole 23111, and an insulating film 23122 is formed on an inner wall surface of the coupling hole 23121. Then, coupling conductors 23113 and 23123 are embedded in the coupling holes 23111 and 23121, respectively. The coupling conductor 23113 and the coupling conductor 23123 are electrically coupled to each other on the side of the back surface of the sensor die 23021. This allows the sensor die 23021 and the logic die 23024 to be electrically coupled to each other via the wiring layer 23101, the coupling hole 23121, the coupling hole 23111, and the wiring layer 23161.

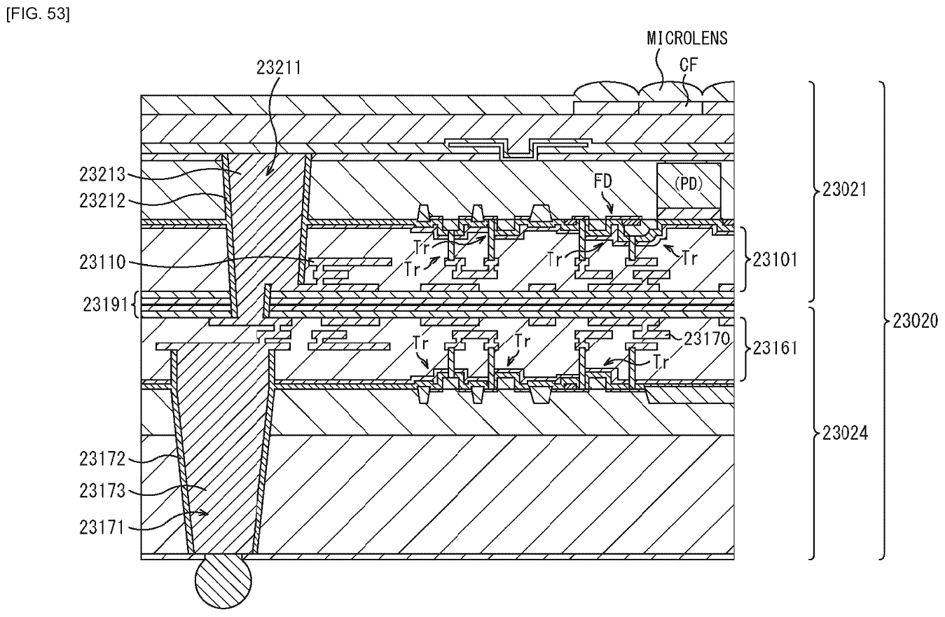

FIG. 53 is a cross-sectional view of a second configuration example of the stacked solid-state imaging element 23020.

In the second configuration example of the solid-state imaging element 23020, one coupling hole 23211 formed in the sensor die 23021 allows ((the wiring line 23110 of) the wiring layer 23101 of) the sensor die 23021 and ((the wiring line 23170 of) the wiring layer 23161) of the logic die 23024 to be electrically coupled to each other.

That is, in FIG. 53, the coupling hole 23211 is formed to penetrate the sensor die 23021 from the side of the back surface of the sensor die 23021, reach the wiring line 23170 of the top layer of the logic die 23024, and reach the wiring line 23110 of the top layer of the sensor die 23021. An insulating film 23212 is formed on an inner wall surface of the coupling hole 23211, and a coupling conductor 23213 is embedded in the coupling hole 23211. In FIG. 52 mentioned above, the two coupling holes 23111 and 23121 allow the sensor die 23021 and the logic die 23024 to be electrically coupled to each other, whereas, in FIG. 53, the one coupling hole 23211 allows the sensor die 23021 and the logic die 23024 to be electrically coupled to each other.

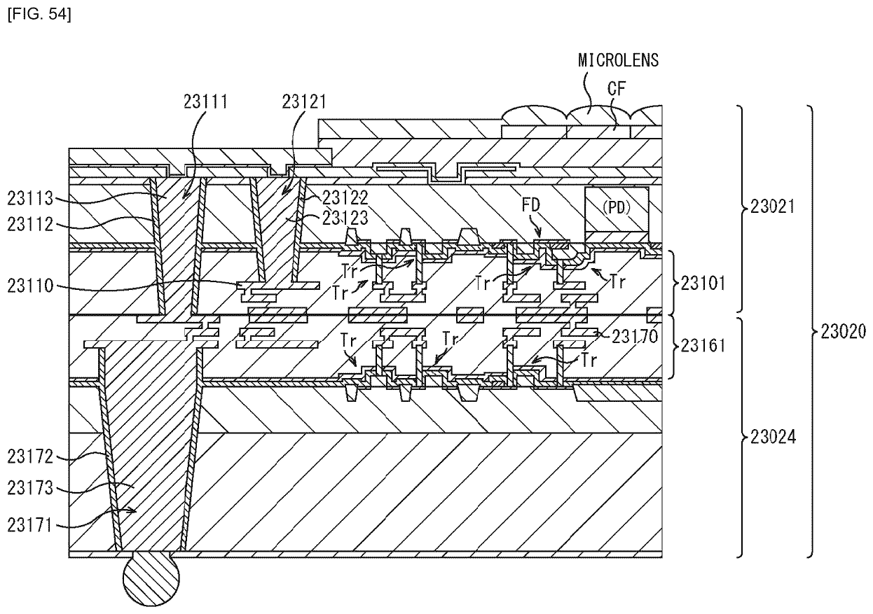

FIG. 54 is a cross-sectional view of a third configuration example of the stacked solid-state imaging element 23020.

The solid-state imaging element 23020 in FIG. 54 differs from the case of FIG. 52 in that the film 23191 such as a protective film is not formed on a surface on which the sensor die 23021 and the logic die 23024 are attached; in the case of FIG. 52, the film 23191 such as a protective film is formed on the surface on which the sensor die 23021 and the logic die 23024 are attached.

The solid-state imaging element 23020 in FIG. 54 is configured by overlapping the sensor die 23021 and the logic die 23024 each other to allow the wiring line 23110 and 23170 to be in direct contact, heating them while applying a predetermined weight, and directly bonding the wiring lines 23110 and 23170 to each other.

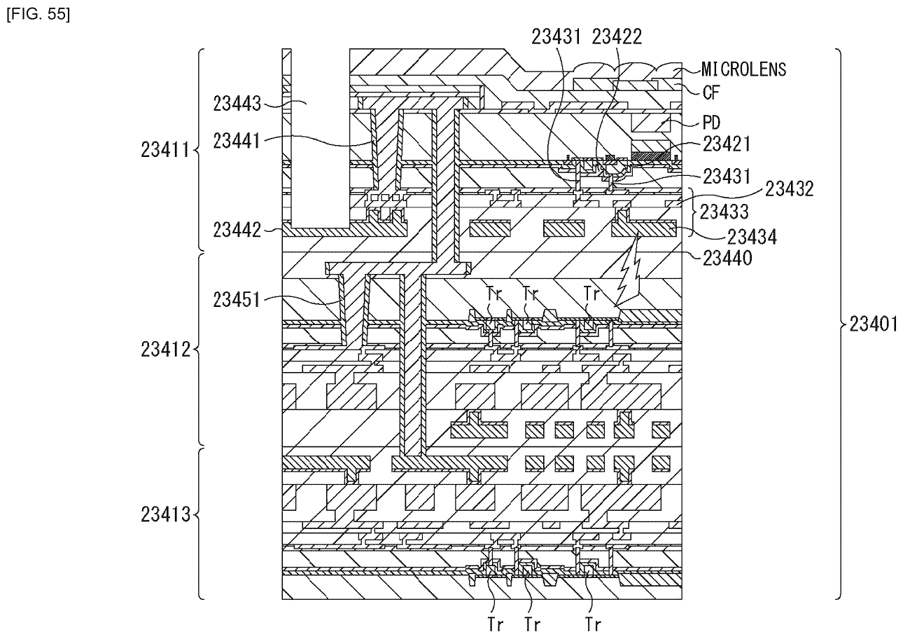

FIG. 55 is a cross-sectional view of another configuration example of the stacked solid-state imaging element to which the technology according to the present disclosure is applicable.

In FIG. 55, a solid-state imaging element 23401 has a three-layer stacked structure in which three dies of a sensor die 23411, a logic die 23412, and a memory die 23413 are stacked.

The memory die 23413 includes, for example, a memory circuit that stores data temporarily necessary in signal processing to be performed by the logic die 23412.

In FIG. 55, below the sensor die 23411, there are stacked the logic die 23412 and the memory die 23413 in this order. However, the logic die 23412 and the memory die 23413 can be stacked in reverse order, i.e., in the order of the memory die 23413 and the logic die 23412 below the sensor die 23411.

It is to be noted that, in FIG. 55, in the sensor die 23411, there are formed a PD serving as a photoelectric conversion section of a pixel and a source/drain region of a pixel Tr.

A gate electrode is formed around the PD with a gate insulating film interposed therebetween, and a pixel Tr23421 and a pixel Tr23422 are each formed by a source/drain region paired with the gate electrode.

The pixel Tr23421 adjacent to the PD serves as a transfer Tr, and one of the pair of source/drain region constituting the pixel Tr23421 serves as the FD.

In addition, an interlayer insulating film is formed in the sensor die 23411, and a coupling hole is formed in the interlayer insulating film. In the coupling hole, there are formed the pixel Tr23421 and a coupling conductor 23431 coupled to the pixel Tr23422.

Further, in the sensor die 23411, there is formed a wiring layer 23433 including a wiring line 23432 in a plurality of layers coupled to each coupling conductor 23431.

In addition, an aluminum pad 23434 serving as an external coupling electrode is formed in the lowermost layer of the wiring layer 23433 of the sensor die 23411. That is, in the sensor die 23411, the aluminum pad 23434 is formed at a position closer to an adhesive surface 23440 with the logic die 23412 than the wiring line 23432. The aluminum pad 23434 is used as one end of a wiring line associated with input/output of signals to and from the outside.

Further, in the sensor die 23411, there is formed a contact 23441 to be used for electric coupling to the logic die 23412. The contact 23441 is coupled to a contact 23451 of the logic die 23412 and also to an aluminum pad 23442 of the sensor die 23411.

Then, in the sensor die 23411, there is formed a pad hole 23443 to reach the aluminum pad 23442 from a side of a back surface (upper side) of the sensor die 23411.

The technology according to the present disclosure is applicable to the solid-state imaging element as described above. For example, the wiring line 23110 or the wiring layer 23161 may be provided with, for example, the plurality of pixel drive lines 23 and the plurality of vertical signal lines 24 described above. In that case, forming the air gap G as illustrated in FIG. 1 between wiring lines of the plurality of vertical signal lines 24 makes it possible to reduce capacitance between the wiring lines. In addition, suppressing an increase in the capacitance between the wiring lines makes it possible to reduce dispersion of wiring capacitance.

### 4. Examples of Practical Applications

### Practical Application Example 1

The technology according to an embodiment of the present disclosure (present technology) is applicable to various products. For example, the technology according to an embodiment of the present disclosure may be achieved in the form of an apparatus to be mounted to a mobile body of any kind. Non-limiting examples of the mobile body may include an automobile, an electric vehicle, a hybrid electric vehicle, a motorcycle, a bicycle, any personal mobility device, an airplane, an unmanned aerial vehicle (drone), a vessel, and a robot.

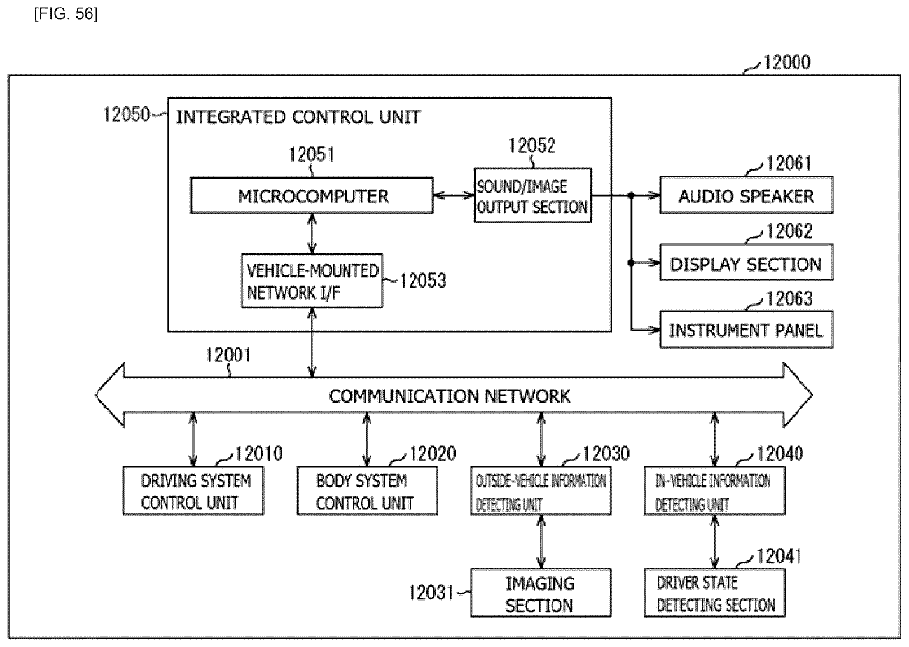

FIG. 56 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 56, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 56, an audio speaker 12061, a display section 12062, and an instrument panel 12063 are illustrated as the output device. The display section 12062 may, for example, include at least one of an on-board display and a head-up display.

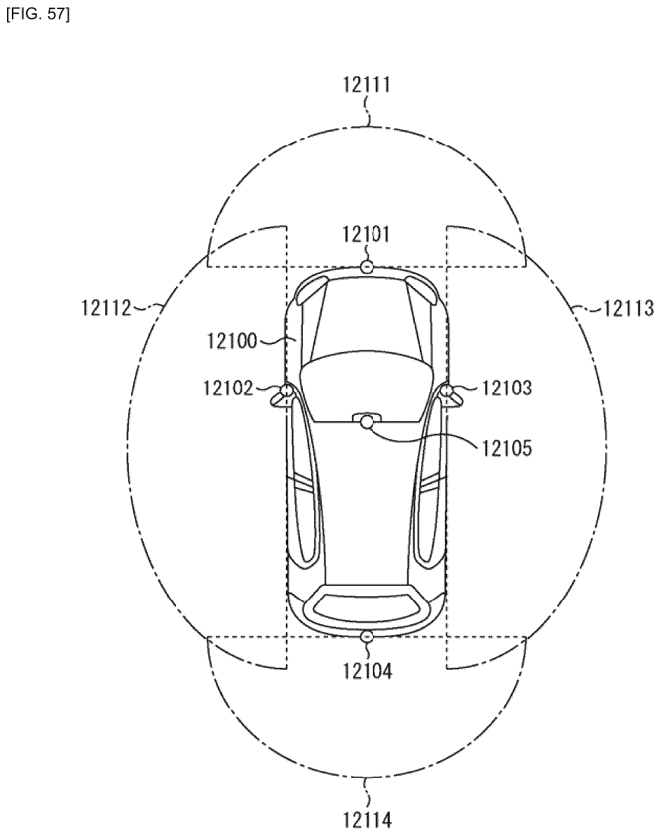

FIG. 57 is a diagram depicting an example of the installation position of the imaging section 12031.

In FIG. 57, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 57 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of one example of the mobile body control system, to which the technology according to an embodiment of the present disclosure may be applied. The technology according to an embodiment of the present disclosure may be applied to the imaging section 12031 among components of the configuration described above. Specifically, the imaging element 1 according to any of the foregoing embodiment and modification examples thereof is applicable to the imaging section 12031. The application of the technology according to an embodiment of the present disclosure to the imaging section 12031 allows for a high-definition captured image with less noise, thus making it possible to perform highly accurate control utilizing the captured image in the mobile body control system.

### Practical Application Example 2

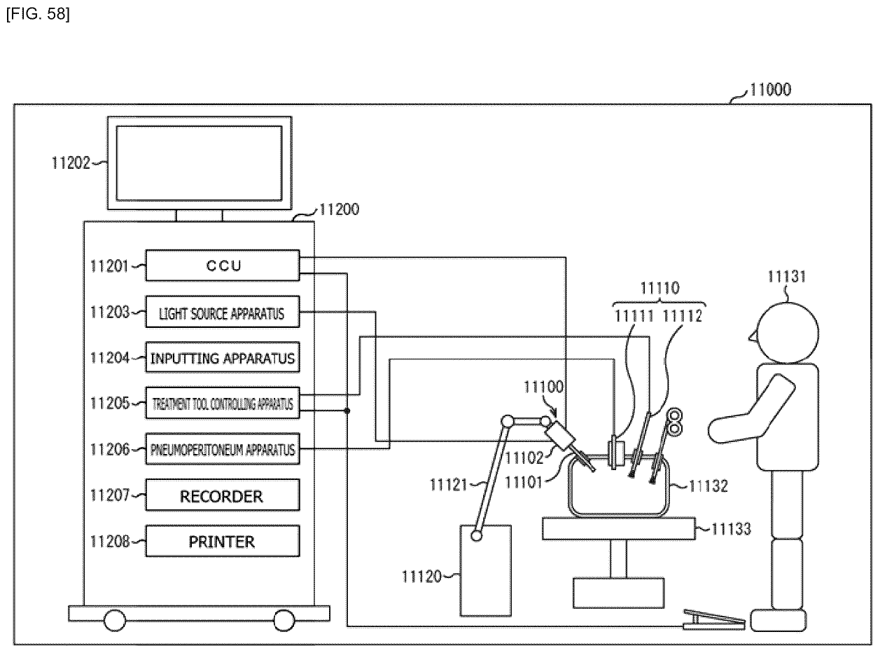

FIG. 58 is a view depicting an example of a schematic configuration of an endoscopic surgery system to which the technology according to an embodiment of the present disclosure (present technology) can be applied.

In FIG. 58, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

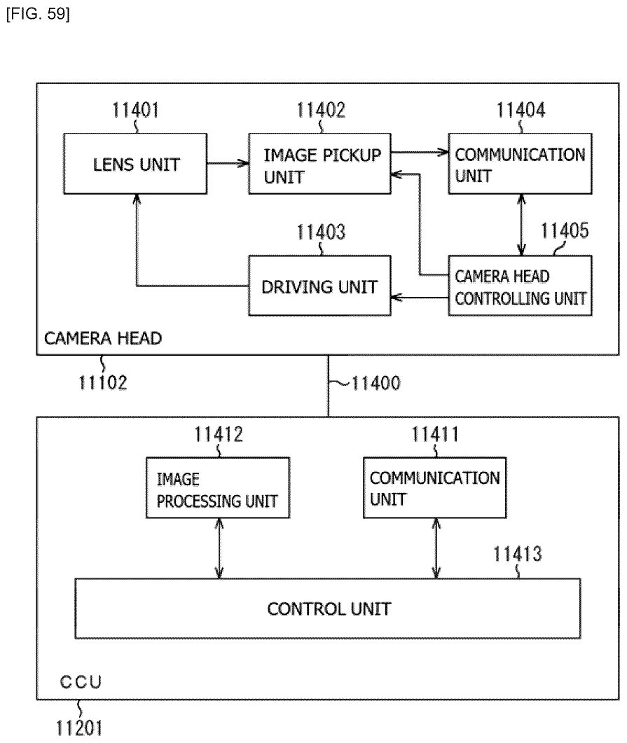

FIG. 59 is a block diagram depicting an example of a functional configuration of the camera head 11102 and the CCU 11201 depicted in FIG. 58.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given above of one example of the endoscopic surgery system, to which the technology according to an embodiment of the present disclosure is applicable. The technology according to an embodiment of the present disclosure is suitably applicable to, for example, the image pickup unit 11402 provided in the camera head 11102 of the endoscope 11100, among the configurations described above. Applying the technology according to an embodiment of the present disclosure to the image pickup unit 11402 enables miniaturization or higher definition of the image pickup unit 11402, thus making it possible to provide the miniaturized or high-definition endoscope 11100.

Although the description has been given hereinabove of the present disclosure with reference to the embodiment and Modification Examples 1 to 15 thereof, the application example, and the practical application examples, the present disclosure is not limited to the foregoing embodiment, etc., and may be modified in a wide variety of ways. For example, the foregoing embodiment and the like have exemplified the plurality of pixel drive lines 23 extending in the row direction and the plurality of vertical signal lines extending in the column direction, but they may extend in the same direction. In addition, a direction in which the pixel drive lines 23 extend can be changed, as appropriate, for example, into the vertical direction.

In addition, the foregoing embodiment and the like have described the present technology by exemplifying the imaging element having a three-dimensional structure, but this is not limitative. The present technology is applicable to any three-dimensional stacked large-scale integrated (LSI) semiconductor device.

It is to be noted that the effects described herein are merely illustrative. The effects of the present disclosure are not limited to those described herein. The present disclosure may have other effects than those described herein.

It is to be noted that the present disclosure may also have the following configurations. According to the present technology of the following configurations, a first barrier film having a first edge surface above any wiring line of a plurality of wiring lines is formed on a wiring layer including the plurality of wiring lines extending in one direction. Further, a first insulating film covering the wiring layer and the first barrier film is formed. A first air gap is provided between the wiring lines adjacent to each other, and a second air gap is provided above the wiring line above which the first edge surface of the first barrier film is provided and near the first edge surface. This allows for a reduction in capacitance between the wiring lines extending in one direction. It is therefore possible to reduce the entire wiring capacitance.

(1)

An imaging element including:
a wiring layer including a plurality of wiring lines extending in one direction;
a first barrier film stacked on the wiring layer and having a first edge surface above any wiring line of the plurality of wiring lines;
a first insulating film stacked on the wiring layer and the first barrier film;
a first air gap provided between the wiring layer and the first insulating film, and provided between the plurality of wiring lines adjacent to each other; and
a second air gap provided above the wiring line above which the first edge surface is provided, the second air gap being provided near the first edge surface.
   (2)

The imaging element according to (1), in which the first edge surface has a reverse tapered shape in which an end on a side of the wiring line is more retracted.

(3)

The imaging element according to (1) or (2), further including a second insulating film provided between the first insulating film and the first barrier film and continuously coating the first edge surface and top surfaces and side surfaces of the plurality of wiring lines.

(4)

The imaging element according to (3), further including:
a second barrier film provided between the first barrier film and the second insulating film and having a second edge surface above the wiring line together with the first edge surface, the second barrier film having an etching rate different from the first barrier film; and
a third air gap provided near the second edge surface of the second barrier film.
   (5)

The imaging element according to (4), in which the first edge surface and the second edge surface are formed at positions different from each other.

(6)

The imaging element according to any one of (1) to (5), further including a third insulating film stacked on the first insulating film and having a planar surface.

(7)

The imaging element according to (6), further including a first electrically-conductive film squarely opposed to at least a portion of the plurality of wiring lines, with the first insulating film and the third insulating film interposed therebetween.

(8)

The imaging element according to (7), in which the first electrically-conductive film is electrically coupled to the portion of the plurality of wiring lines via a coupling section that penetrates the first insulating film and the third insulating film.

(9)

The imaging element according to any one of (1) to (8), in which the first insulating film has an irregularity above the plurality of wiring lines.

(10)

The imaging element according to any one of (1) to (9), in which the first insulating film is formed using a low-permittivity material having a relative permittivity k of 3.0 or less.

(11)

The imaging element according to any one of (1) to (10), in which the first barrier film is formed using an insulating material.

(12)

The imaging element according to any one of (1) to (11), in which the first barrier film is formed using a metal material for each of the plurality of wiring lines.

(13)

The imaging element according to any one of (6) to (12), in which the third insulating film is formed using a material having a polishing rate higher than the first insulating film.

(14)

The imaging element according to any one of (6) to (13), in which the third insulating film is formed using silicon oxide, carbon-containing silicon oxide, fluorine-doped silicon oxide, or silicon oxynitride.

(15)

The imaging element according to any one of (7) to (14), further including:
a first substrate including a first semiconductor substrate including a sensor pixel that performs photoelectric conversion, and a multilayer wiring layer in which the first electrically-conductive film is embedded and formed, the multilayer wiring layer including the third insulating film; and
a second substrate including a second semiconductor substrate including a logic circuit that processes a pixel signal based on electric charge outputted from the sensor pixel, and a multilayer wiring layer in which a second electrically-conductive film is embedded and formed, in which the first substrate and the second substrate are electrically coupled to each other by bonding between the first electrically-conductive film and the second electrically-conductive film.
   (16)

A method of manufacturing an imaging element, the method including:
forming a wiring layer including a plurality of wiring lines extending in one direction;
forming a first barrier film on the wiring layer;
forming a first opening in the first barrier film and between the plurality of wiring lines adjacent to each other in a predetermined region of the wiring layer; and
forming a first air gap between the plurality of wiring lines adjacent to each other and a second air gap near a first edge surface formed by the first opening of the first barrier film, by forming a first insulating film.
   (17)

The method of manufacturing the imaging element according to (16), in which, after the formation of the first opening, a third insulating film is formed that coats a top surface and the first edge surface of the first barrier film and top surfaces and side surfaces of the plurality of wiring lines.

(18)

The method of manufacturing the imaging element according to (16) or (17), the method further including:
forming, after the formation of the first barrier film, a second barrier film having an etching rate different from the first barrier film; and
forming, upon the formation of the first insulating film, a third air gap near a second edge surface formed by the first opening of the second barrier film, together with the first air gap and the second air gap.

This application claims the benefit of Japanese Priority Patent Application JP2021-088786 filed with the Japan Patent Office on May 26, 2021, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. An imaging element comprising:
a wiring layer including a plurality of wiring lines extending in one direction;
a first barrier film stacked on the wiring layer and having a first edge surface above any wiring line of the plurality of wiring lines;
a first insulating film stacked on the wiring layer and the first barrier film;
a first air gap provided between the wiring layer and the first insulating film, and provided between the plurality of wiring lines adjacent to each other; and
a second air gap provided above the wiring line above which the first edge surface is provided, the second air gap being provided near the first edge surface.

2. The imaging element according to claim 1, wherein the first edge surface has a reverse tapered shape in which an end on a side of the wiring line is more retracted.

3. The imaging element according to claim 1, further comprising a second insulating film provided between the first insulating film and the first barrier film and continuously coating the first edge surface and top surfaces and side surfaces of the plurality of wiring lines.

4. The imaging element according to claim 3, further comprising:
a second barrier film provided between the first barrier film and the second insulating film and having a second edge surface above the wiring line together with the first edge surface, the second barrier film having an etching rate different from the first barrier film; and
a third air gap provided near the second edge surface of the second barrier film.

5. The imaging element according to claim 4, wherein the first edge surface and the second edge surface are formed at positions different from each other.

6. The imaging element according to claim 1, further comprising a third insulating film stacked on the first insulating film and having a planar surface.

7. The imaging element according to claim 6, further comprising a first electrically-conductive film squarely opposed to at least a portion of the plurality of wiring lines, with the first insulating film and the third insulating film interposed therebetween.

8. The imaging element according to claim 7, wherein the first electrically-conductive film is electrically coupled to the portion of the plurality of wiring lines via a coupling section that penetrates the first insulating film and the third insulating film.

9. The imaging element according to claim 1, wherein the first insulating film has an irregularity above the plurality of wiring lines.

10. The imaging element according to claim 1, wherein the first insulating film is formed using a low-permittivity material having a relative permittivity k of 3.0 or less.

11. The imaging element according to claim 1, wherein the first barrier film is formed using an insulating material.

12. The imaging element according to claim 1, wherein the first barrier film is formed using a metal material for each of the plurality of wiring lines.

13. The imaging element according to claim 6, wherein the third insulating film is formed using a material having a polishing rate higher than the first insulating film.

14. The imaging element according to claim 6, wherein the third insulating film is formed using silicon oxide, carbon-containing silicon oxide, fluorine-doped silicon oxide, or silicon oxynitride.

15. The imaging element according to claim 7, further comprising:
a first substrate including a first semiconductor substrate including a sensor pixel that performs photoelectric conversion, and a multilayer wiring layer in which the first electrically-conductive film is embedded and formed, the multilayer wiring layer including the third insulating film; and
a second substrate including a second semiconductor substrate including a logic circuit that processes a pixel signal based on electric charge outputted from the sensor pixel, and a multilayer wiring layer in which a second electrically-conductive film is embedded and formed, wherein
the first substrate and the second substrate are electrically coupled to each other by bonding between the first electrically-conductive film and the second electrically-conductive film.

16. A method of manufacturing an imaging element, the method comprising:
forming a wiring layer including a plurality of wiring lines extending in one direction;
forming a first barrier film on the wiring layer;
forming a first opening in the first barrier film and between the plurality of wiring lines adjacent to each other in a predetermined region of the wiring layer; and
forming a first air gap between the plurality of wiring lines adjacent to each other and a second air gap near a first edge surface formed by the first opening of the first barrier film, by forming a first insulating film.

17. The method of manufacturing the imaging element according to claim 16, wherein, after the formation of the first opening, a third insulating film is formed that coats a top surface and the first edge surface of the first barrier film and top surfaces and side surfaces of the plurality of wiring lines.

18. The method of manufacturing the imaging element according to claim 16, the method further comprising:
forming, after the formation of the first barrier film, a second barrier film having an etching rate different from the first barrier film; and
forming, upon the formation of the first insulating film, a third air gap near a second edge surface formed by the first opening of the second barrier film, together with the first air gap and the second air gap.
